(19) United States
(12) Patent Application Publication
(10) Pub. No.: US 2023/0103655 A1
(43) Pub. Date: Apr. 6, 2023

(54) ELECTRONIC COMPONENT

(71) Applicant: ROHM CO., LTD., Kyoto-shi, Kyoto (JP)

(72) Inventors: Yuki NAKANO, Kyoto-shi, Kyoto (JP); Masaya UENO, Kyoto-shi, Kyoto (JP)

(73) Assignee: ROHM CO., LTD., Kyoto-shi, Kyoto (JP)

(21) Appl. No.: 17/909,766

(22) PCT Filed: May 12, 2021
(86) PCT No.: PCT/JP2021/018090

§ 371 Date: Sep. 7, 2022

(30) Foreign Application Priority Data
Jun. 26, 2020 (JP) 2020-110898

(51) Int. Cl. H01L 23/00; H01L 29/16; H01L 29/78; H01L 29/872; H01L 29/66

(52) U.S. Cl. CPC H01L 24/05; H01L 24/03; H01L 29/1608; H01L 29/7811; H01L 29/7813; H01L 29/872; H01L 29/6606; H01L 2224/02166; H01L 2224/02181; H01L 2224/03464; H01L 2224/05084; H01L 2224/05155; H01L 2224/05144; H01L 2224/05164; H01L 2924/10272; H01L 2924/12032; H01L 2924/13091; H01L 2924/35121

(57) ABSTRACT

An electronic component includes a covered object, an electrode that covers the covered object and has an electrode side wall on the covered object, an inorganic insulating film that has an inner covering portion covering the electrode such as to expose the electrode side wall, and an organic insulating film that covers the electrode side wall.

### TECHNICAL FIELD

The present application corresponds to Japanese Patent Application No. 2020-110898 filed on Jun. 26, 2020 in the Japan Patent Office, and the entire disclosure of this applications is incorporated herein by reference. The present invention relates to an electronic component.

### BACKGROUND ART

Patent Literature 1 discloses a semiconductor device that includes a semiconductor substrate, an interlayer insulating layer, an electrode, an inorganic protective layer, and an organic protective layer. The interlayer insulating layer is formed on the semiconductor substrate and has an opening portion that exposes the semiconductor substrate. The electrode enters into the opening portion from above the interlayer insulating layer and is electrically connected to the semiconductor substrate inside the opening portion. The inorganic protective layer has an inner edge portion that covers an edge portion of the electrode and an outer edge portion that covers the interlayer insulating layer. The organic protective layer covers the electrode and the interlayer insulating layer across the inorganic protective layer.

### CITATION LIST

### Patent Literature

Patent Literature 1: United States Patent Application Publication No. 2019/0080976 Specification

### SUMMARY OF INVENTION

### Technical Problem

A preferred embodiment of the present invention provides an electronic component that is capable of improving reliability.

### Solution to Problem

A preferred embodiment of the present invention provides an electronic component including a covered object, an electrode that covers the covered object and has an electrode side wall on the covered object, an inorganic insulating film that has an inner covering portion covering the electrode such as to expose the electrode side wall, and an organic insulating film that covers the electrode side wall.

A preferred embodiment of the present invention provides an electronic component including a covered object, an electrode that covers the covered object and has an electrode side wall on the covered object, an inorganic insulating film that covers the covered object such as to expose the electrode side wall, and an organic insulating film that covers the inorganic insulating film and the electrode and covers the electrode side wall between the inorganic insulating film and the electrode.

A preferred embodiment of the present invention provides an electronic component including an electrode that has an electrode side wall, an inorganic insulating film that covers the electrode such as to expose an inner portion of the electrode and the electrode side wall of the electrode, an organic insulating film that exposes the inner portion of the electrode and covers the electrode side wall of the electrode, and a pad electrode that is formed on the inner portion of the electrode.

The aforementioned as well as yet other objects, features, and effects of the present invention will be made clear by the following description of the preferred embodiments, with reference to the accompanying drawings.

### BRIEF DESCRIPTION OF DRAWINGS

FIG. 1 is a plan view of an SiC semiconductor device according to a first preferred embodiment of the present invention.

FIG. 2 is a plan view of the internal structure of the SiC semiconductor device shown together with a second inorganic insulating film according to a first configuration example.

FIG. 3 is a sectional view taken along line III-III shown in FIG. 1.

FIG. 4 is an enlarged sectional view of a principal portion of the structure shown in FIG. 3.

FIG. 5A is a plan view corresponding to FIG. 2 of the internal structure of the SiC semiconductor device shown together with the second inorganic insulating film according to a second configuration example.

FIG. 5B is a plan view corresponding to FIG. 2 of the internal structure of the SiC semiconductor device shown together with the second inorganic insulating film according to a third configuration example.

FIG. 5C is a plan view corresponding to FIG. 2 of the internal structure of the SiC semiconductor device shown together with the second inorganic insulating film according to a fourth configuration example.

FIG. 5D is a plan view corresponding to FIG. 2 of the internal structure of the SiC semiconductor device shown together with the second inorganic insulating film according to a fifth configuration example.

FIG. 5E is a plan view corresponding to FIG. 2 of the internal structure of the SiC semiconductor device shown together with the second inorganic insulating film according to a sixth configuration example.

FIG. 5F is a plan view corresponding to FIG. 2 of the internal structure of the SiC semiconductor device shown together with the second inorganic insulating film according to a seventh configuration example.

FIG. 6A is a sectional view for describing an example of a method for manufacturing the semiconductor device shown in FIG. 1.

FIG. 6B is a sectional view of a step subsequent to that of FIG. 6A.

FIG. 6C is a sectional view of a step subsequent to that of FIG. 6B.

FIG. 6D is a sectional view of a step subsequent to that of FIG. 6C.

FIG. 6E is a sectional view of a step subsequent to that of FIG. 6D.

FIG. 6F is a sectional view of a step subsequent to that of FIG. 6E.

FIG. 6G is a sectional view of a step subsequent to that of FIG. 6F.

FIG. 6H is a sectional view of a step subsequent to that of FIG. 6G.

FIG. 6I is a sectional view of a step subsequent to that of FIG. 6H.

FIG. 6J is a sectional view of a step subsequent to that of FIG. 6I.

FIG. 6K is a sectional view of a step subsequent to that of FIG. 6J.

FIG. 6L is a sectional view of a step subsequent to that of FIG. 6K.

FIG. 6M is a sectional view of a step subsequent to that of FIG. 6L.

FIG. 6N is a sectional view of a step subsequent to that of FIG. 6M.

FIG. 7 is a sectional view corresponding to FIG. 4 for describing an SiC semiconductor device according to a second preferred embodiment of the present invention.

FIG. 8 is a sectional view corresponding to FIG. 4 for describing an SiC semiconductor device according to a third preferred embodiment of the present invention.

FIG. 9 is a sectional view corresponding to FIG. 4 for describing an SiC semiconductor device according to a fourth preferred embodiment of the present invention.

FIG. 10 is a sectional view corresponding to FIG. 4 for describing an SiC semiconductor device according to a fifth preferred embodiment of the present invention.

FIG. 11 is a plan view of an SiC semiconductor device according to a sixth preferred embodiment of the present invention.

FIG. 12 is a plan view of the internal structure of the SiC semiconductor device shown in FIG. 11 and shown together with a second inorganic insulating film according to a first configuration example.

FIG. 13 is an enlarged view of a region XIII shown in FIG. 11.

FIG. 14 is a sectional view taken along line XIV-XIV shown in FIG. 13.

FIG. 15 is a sectional view taken along line XV-XV shown in FIG. 11.

FIG. 16 is a sectional view taken along line XVI-XVI shown in FIG. 11.

FIG. 17 is an enlarged sectional view of a principal portion of the structure shown in FIG. 15.

FIG. 18 is an enlarged sectional view of a principal portion of the structure shown in FIG. 16.

FIG. 19A is a plan view corresponding to FIG. 12 of the internal structure of the SiC semiconductor device shown together with the second inorganic insulating film according to a second configuration example.

FIG. 19B is a plan view corresponding to FIG. 12 of the internal structure of the SiC semiconductor device shown together with the second inorganic insulating film according to a third configuration example.

FIG. 19C is a plan view corresponding to FIG. 12 of the internal structure of the SiC semiconductor device shown together with the second inorganic insulating film according to a fourth configuration example.

FIG. 19D is a plan view corresponding to FIG. 12 of the internal structure of the SiC semiconductor device shown together with the second inorganic insulating film according to a fifth configuration example.

FIG. 19E is a plan view corresponding to FIG. 12 of the internal structure of the SiC semiconductor device shown together with the second inorganic insulating film according to a sixth configuration example.

FIG. 19F is a plan view corresponding to FIG. 12 of the internal structure of the SiC semiconductor device shown together with the second inorganic insulating film according to a seventh configuration example.

FIG. 20 is a sectional view corresponding to FIG. 17 for describing an SiC semiconductor device according to a seventh preferred embodiment of the present invention.

FIG. 21 is a sectional view corresponding to FIG. 18 for describing the SiC semiconductor device shown in FIG. 20.

FIG. 22 is a sectional view corresponding to FIG. 15 for describing an SiC semiconductor device according to an eighth preferred embodiment of the present invention.

FIG. 23 is a sectional view corresponding to FIG. 15 for describing an SiC semiconductor device according to a ninth preferred embodiment of the present invention.

FIG. 24 is an enlarged view corresponding to FIG. 13 for describing an SiC semiconductor device according to a tenth preferred embodiment of the present invention.

FIG. 25 is a sectional view taken along line XXV-XXV shown in FIG. 24.

FIG. 26 is a sectional view corresponding to FIG. 14 for describing an SiC semiconductor device according to an eleventh preferred embodiment of the present invention.

FIG. 27 is a plan view of a semiconductor package as viewed from one side.

FIG. 28 is a plan view of the semiconductor package shown in FIG. 27 as viewed from another side.

FIG. 29 is a perspective view of the semiconductor package shown in FIG. 27.

FIG. 30 is an exploded perspective view of the semiconductor package shown in FIG. 27.

FIG. 31 is a sectional view taken along line XXXI-XXXI shown in FIG. 27.

FIG. 32 is a circuit diagram of the semiconductor package shown in FIG. 27.

FIG. 33 is a sectional view corresponding to FIG. 3 for describing a modification example of the SiC semiconductor device according to the first preferred embodiment.

FIG. 34 is a sectional view corresponding to FIG. 17 for describing a modification example of the SiC semiconductor device according to the sixth preferred embodiment.

FIG. 35 is a sectional view corresponding to FIG. 18 for describing a modification example of the SiC semiconductor device according to the sixth preferred embodiment.

### DESCRIPTION OF EMBODIMENTS

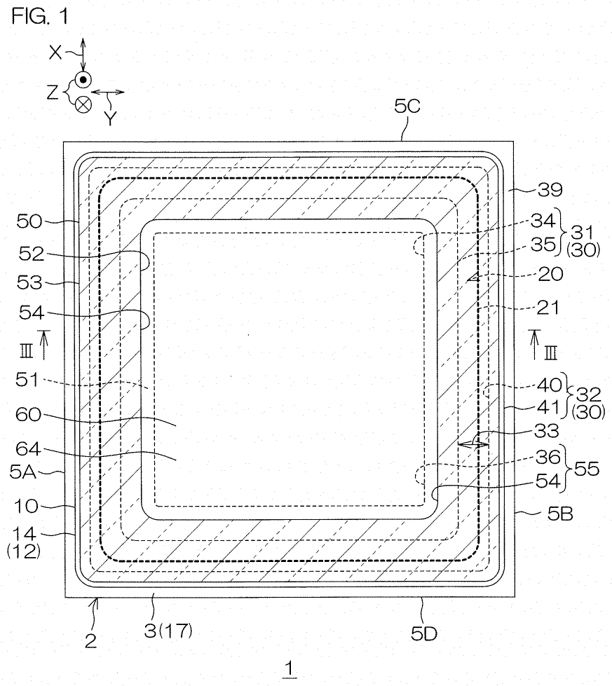

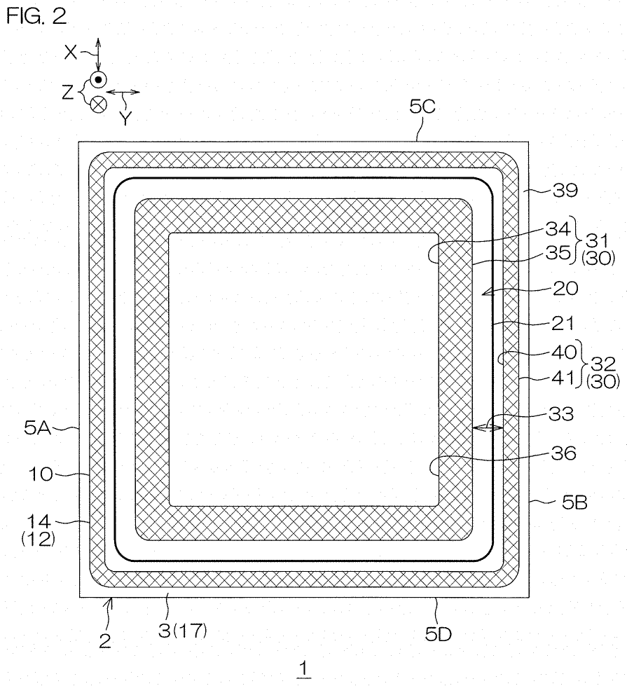

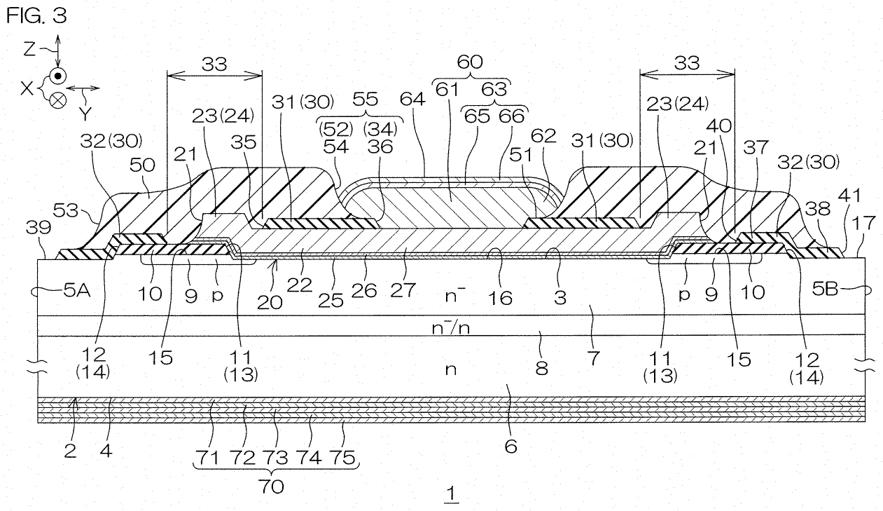

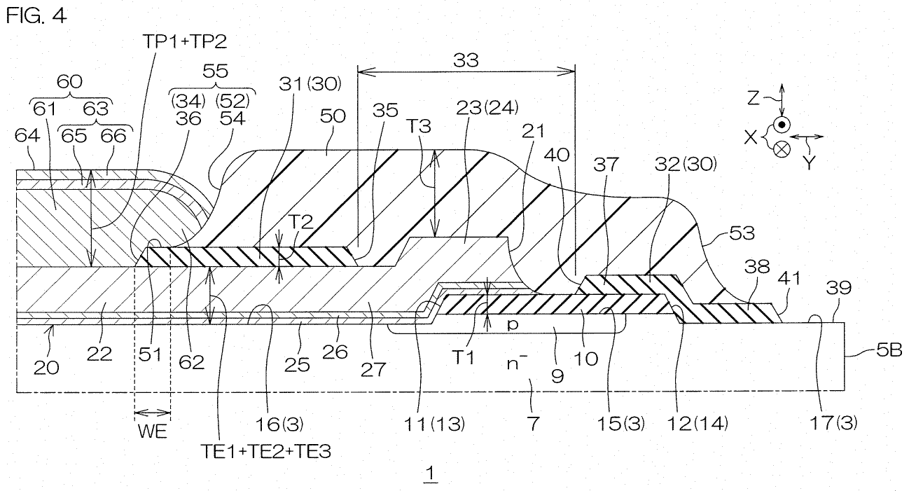

FIG. 1 is a plan view of an SiC semiconductor device 1 according to a first preferred embodiment of the present invention. FIG. 2 is a plan view of the internal structure of the SiC semiconductor device 1 shown together with a second inorganic insulating film 30 according to a first configuration example. FIG. 3 is a sectional view taken along line III-III shown in FIG. 1. FIG. 4 is an enlarged sectional view of a principal portion of the structure shown in FIG. 3.

In this embodiment, the SiC semiconductor device 1 is an electronic component that includes an SiC chip 2 (chip/semiconductor chip) constituted of an SiC monocrystal that is a hexagonal crystal. Also, in this embodiment, the SiC semiconductor device 1 is a semiconductor rectifying device that includes an SiC-SBD (Schottky barrier diode). The SiC monocrystal that is a hexagonal crystal has a plurality of polytypes including a 2H (hexagonal)-SiC monocrystal, a 4H-SiC monocrystal, a 6H-SiC monocrystal, etc. Although with this embodiment, an example where the SiC chip 2 is constituted of a 4H-SiC monocrystal is illustrated, this does not exclude other polytypes.

The SiC chip 2 is formed to a rectangular parallelepiped shape. The SiC chip 2 has a first main surface 3 at one side, a second main surface 4 at another side, and first to fourth side surfaces 5A to 5D connecting the first main surface 3 and the second main surface 4. The first main surface 3 is a device surface in which a functional device is formed. The second main surface 4 is a non-device surface in which a functional device is not formed. The first main surface 3 and the second main surface 4 are formed to quadrilateral shapes in a plan view as viewed in a normal direction Z thereto (hereinafter referred to simply as “plan view”).

The first main surface 3 and the second main surface 4 are arranged along c-planes of the SiC monocrystal. The c-planes include a silicon plane ((0001) plane) and a carbon plane ((000-1) plane) of the SiC monocrystal. Preferably, the first main surface 3 is arranged along the silicon plane and the second main surface 4 is arranged along the carbon plane. The first main surface 3 and the second main surface 4 may have an off angle inclined at a predetermined angle in an off direction with respect to the c-planes. The off direction is preferably an a-axis direction ([11-20] direction) of the SiC monocrystal. The off angle may exceed 0° and be not more than 10°. The off angle is preferably not more than 5°. The off angle is especially preferably not less than 2° and not more than 4.5°.

The second main surface 4 may be constituted of a rough surface having either or both of grinding marks and annealing marks (specifically, laser irradiation marks). The annealing marks may include amorphized SiC and/or SiC (specifically, Si) that has been silicided (alloyed) with a metal. The second main surface 4 is preferably constituted of an ohmic surface having at least annealing marks.

The first to fourth side surfaces 5A to 5D form a peripheral edge of the first main surface 3 and a peripheral edge of the second main surface 4. The first side surface 5A and the second side surface 5B extend in a first direction X along the first main surface 3 and face each other in a second direction Y intersecting (specifically, orthogonal to) the first direction X. The third side surface 5C and the fourth side surface 5D extend in the second direction Y and face each other in the first direction X. In this embodiment, the first direction X is an m-axis direction ([1-100] direction) of the SiC monocrystal and the second direction Y is the a-axis direction of the SiC monocrystal. That is, the first side surface 5A and the second side surface 5B are formed by a-planes of the SiC monocrystal and the third side surface 5C and the fourth side surface 5D are formed by m-planes of the SiC monocrystal.

The first to fourth side surfaces 5A to 5D may each be constituted of a ground surface that have grinding marks formed by dicing by a dicing blade or may each be constituted of a cleavage surface that has a modified layer formed by laser light irradiation. Specifically, the modified layer is constituted of a region in which a portion of a crystal structure of the SiC chip 2 has been modified to be of altered property. That is, the modified layer is constituted of a region in which density, refractive index, mechanical strength (crystal strength), or other physical characteristic has been modified to a property differing from that of the SiC chip 2.

The modified layer may include at least one layer among a noncrystalline layer (amorphous layer), a melt rehardened layer, a defect layer, a dielectric breakdown layer, or a refractive index change layer. The noncrystalline layer is a layer in which a portion of the SiC chip 2 is made noncrystalline. The melt rehardened layer is a layer in which a portion of the SiC chip 2 is rehardened after being melted. The defect layer is a layer that includes a hole, crack, etc., formed in the SiC chip 2. The dielectric breakdown layer is a layer in which a portion of the SiC chip 2 has undergone dielectric breakdown. The refractive index change layer is a layer in which a portion of the SiC chip 2 has changed to a refractive index differing from the SiC chip 2.

If the first to fourth side surfaces 5A to 5D are each constituted of a cleavage surface, the first side surface 5A and the second side surface 5B may each form an inclined surface having an inclination angle resulting from the off angle. The inclination angle resulting from the off angle is an angle with respect to the normal direction Z with the normal direction Z being set to 0°. The first side surface 5A and the second side surface 5B may form inclined surfaces that extend along a c-axis direction ([0001] direction) of the SiC monocrystal with respect to the normal direction Z.

The inclination angle resulting from the off angle is substantially equal to the off angle. The inclination angle resulting from the off angle may exceed 0° and be not more than 10° (preferably not less than 2° and not more than 4.5°). The third side surface 5C and the fourth side surface 5D extend along the off direction (a-axis direction) and therefore do not have an inclination angle resulting from the off angle. The third side surface 5C and the fourth side surface 5D extend planarly in the second direction Y (a-axis direction) and the normal direction Z. Specifically, the third side surface 5C and the fourth side surface 5D are formed substantially perpendicular to the first main surface 3 and the second main surface 4.

The SiC semiconductor device 1 includes a first semiconductor region 6 (high concentration region) of an n-type (first conductivity type) that is formed in a surface layer portion of the second main surface 4 of the SiC chip 2. The first semiconductor region 6 has an n-type impurity concentration that is substantially fixed in a thickness direction. The n-type impurity concentration of the first semiconductor region 6 may be not less than 1×10¹⁸ cm⁻³ and not more than 1×10²¹ cm⁻³. The first semiconductor region 6 forms a cathode of the SBD. The first semiconductor region 6 may be referred to as a cathode region.

The first semiconductor region 6 is formed across an entire area of the surface layer portion of the second main surface 4 and is exposed from the second main surface 4 and the first to fourth side surfaces 5A to 5D. That is, the first semiconductor region 6 has the second main surface 4 and portions of the first to fourth side surfaces 5A to 5D. A thickness of the first semiconductor region 6 may be not less than 5 μm and not more than 300 μm. The thickness of the first semiconductor region 6 is typically not less than 50 μm and not more than 250 μm. The thickness of the first semiconductor region 6 is adjusted by grinding of the second main surface 4. In this embodiment, the first semiconductor region 6 is formed of a semiconductor substrate (SiC substrate) of the n-type.

The SiC semiconductor device 1 includes a second semiconductor region 7 (low concentration region) of the n-type that is formed in a surface layer portion of the first main surface 3 of the SiC chip 2. The second semiconductor region 7 has an n-type impurity concentration that is less than the n-type impurity concentration of the first semiconductor region 6. The second semiconductor region 7 is electrically connected to the first semiconductor region 6 and forms the cathode of the SBD together with the first semiconductor region 6. The second semiconductor region 7 may be referred to as a drift region.

The second semiconductor region 7 is formed across an entire area of the surface layer portion of the first main surface 3 and is exposed from the first main surface 3 and the first to fourth side surfaces 5A to 5D. That is, the second semiconductor region 7 has the first main surface 3 and portions of the first to fourth side surfaces 5A to 5D. The n-type impurity concentration of the second semiconductor region 7 may be not less than 1×10¹⁵ cm⁻³ and not more than 1×10¹⁸ cm⁻³. A thickness of the second semiconductor region 7 may be not less than 5 μm and not more than 20 μm. In this embodiment, the second semiconductor region 7 is formed of an epitaxial layer (SiC epitaxial layer) of the n-type.

The SiC semiconductor device 1 includes a third semiconductor region 8 (concentration transition region) of the n-type that is interposed between the first semiconductor region 6 and the second semiconductor region 7 in the SiC chip 2. The third semiconductor region 8 has a concentration gradient with which an n-type impurity concentration decreases (specifically, decreases gradually) from the n-type impurity concentration of the first semiconductor region 6 toward the n-type impurity concentration of the second semiconductor region 7. The third semiconductor region 8 is interposed over an entire area between the first semiconductor region 6 and the second semiconductor region 7 and is exposed from the first to fourth side surfaces 5A to 5D. That is, the third semiconductor region 8 has portions of the first to fourth side surfaces 5A to 5D.

The third semiconductor region 8 is electrically connected to the first semiconductor region 6 and the second semiconductor region 7 and forms the cathode of the SBD together with the first semiconductor region 6 and the second semiconductor region 7. The third semiconductor region 8 may be referred to as a buffer region. A thickness of the third semiconductor region 8 may be not less than 1 μm and not more than 10 μm. In this embodiment, the third semiconductor region 8 is formed of an epitaxial layer (SiC epitaxial layer) of the n-type.

The SiC semiconductor device 1 includes a guard region 9 of a p-type (second conductivity type) that is formed in the surface layer portion of the first main surface 3. A p-type impurity of the guard region 9 may be activated or may not be activated. A p-type impurity concentration of the guard region 9 may be not less than 1×10¹⁵ cm⁻³ and not more than 1×10¹⁸ cm⁻³. The guard region 9 is formed in the first main surface 3 at an interval inward from the peripheral edge of the first main surface 3 (first to fourth side surfaces 5A to 5D) and exposes an inner portion of the first main surface 3. The guard region 9 extends as a band along the peripheral edge of the first main surface 3.

The guard region 9 is formed to an annular shape that surrounds the inner portion of the first main surface 3 in plan view. Specifically, the guard region 9 is formed to a quadrilateral annular shape that has four sides parallel to the peripheral edge of the first main surface 3 in plan view. The guard region 9 is thereby formed as a guard ring region. The guard region 9 has an inner edge portion at the inner portion side of the first main surface 3 and an outer edge portion at the peripheral edge side of the first main surface 3.

The SiC semiconductor device 1 includes a first inorganic insulating film 10 that is formed on the first main surface 3 as an example of a covered object. The first inorganic insulating film 10 may be referred to as an interlayer insulating film. The first inorganic insulating film 10 may have a laminated structure that includes a plurality of insulating films or may have a single layer structure constituted of a single insulating film. The first inorganic insulating film 10 preferably includes at least one among a silicon oxide film, a silicon nitride film, and a silicon oxynitride film. The first inorganic insulating film 10 may have a laminated structure that includes a plurality of silicon oxide films, a laminated structure that includes a plurality of silicon nitride films, or a laminated structure that includes a plurality of silicon oxynitride films.

The first inorganic insulating film 10 may have a laminated structure in which at least two types of films among a silicon oxide film, a silicon nitride film, and a silicon oxynitride film are laminated in any order. The first inorganic insulating film 10 may have a single layer structure constituted of a silicon oxide film, a silicon nitride film, or a silicon oxynitride film. In this embodiment, the first inorganic insulating film 10 has a single layer structure constituted of a silicon oxide film.

In this embodiment, the first inorganic insulating film 10 is constituted of a field oxide that includes an oxide of the SiC chip 2 (second semiconductor region 7). The first inorganic insulating film 10 thus includes the same type of n-type impurity as the n-type impurity of the second semiconductor region 7 in an insulator (silicon oxide). The first inorganic insulating film 10 has a first insulating thickness T1. The first insulating thickness T1 may be not less than 0.1 μm and not more than 5 μm. The first insulating thickness T1 is preferably not less than 0.5 μm and not more than 2 μm.

The first inorganic insulating film 10 exposes the inner portion of the first main surface 3. In this embodiment, the first inorganic insulating film 10 is formed to an annular shape that surrounds the inner portion of the first main surface 3 in plan view. Specifically, the first inorganic insulating film 10 is formed to a quadrilateral annular shape that has four sides parallel to the peripheral edge of the first main surface 3 in plan view. The first inorganic insulating film 10 covers the outer edge portion of the guard region 9 over entire periphery and exposes the inner edge portion of the guard region 9 over entire periphery.

Specifically, the first inorganic insulating film 10 has an inner wall portion 11 at the inner portion side of the first main surface 3 and an outer wall portion 12 at the peripheral edge side of the first main surface 3. The inner wall portion 11 is formed at an interval toward the outer edge portion side from the inner edge portion of the guard region 9 such as to expose the inner portion of the first main surface 3 (second semiconductor region 7) and the inner edge portion of the guard region 9. The inner wall portion 11 thereby demarcates a contact opening 13 that exposes the inner portion of the first main surface 3 (second semiconductor region 7) and the inner edge portion of the guard region 9. In this embodiment, the inner wall portion 11 (contact opening 13) is formed to a quadrilateral shape that has four sides parallel to the peripheral edge of the first main surface 3 (first to fourth side surfaces 5A to 5D) in plan view and surrounds the inner edge portion of the guard region 9.

The outer wall portion 12 is formed at an interval toward the inner portion side of the first main surface 3 from the peripheral edge of the first main surface 3 and exposes a peripheral edge portion of the first main surface 3 (second semiconductor region 7). The outer wall portion 12 is formed at an interval toward the peripheral edge side of the first main surface 3 from the outer edge portion of the guard region 9. The outer wall portion 12 thereby demarcates a notch opening 14 that exposes the peripheral edge portion of the first main surface 3 (second semiconductor region 7). In this embodiment, the outer wall portion 12 (notch opening 14) is formed to a quadrilateral shape that has four sides parallel to the peripheral edge of the first main surface 3 in plan view and surrounds the outer edge portion of the guard region 9.

The first inorganic insulating film 10 demarcates a hidden surface 15, an active surface 16, and an outer surface 17 in the first main surface 3. In other words, the first main surface 3 includes the hidden surface 15, the active surface 16, and the outer surface 17 that are demarcated by the first inorganic insulating film 10.

The hidden surface 15 is constituted of a portion of the first main surface 3 that is covered (hidden) by the first inorganic insulating film 10 and is formed to a quadrilateral annular shape in plan view. The active surface 16 is constituted of portion of the inner portion of the first main surface 3 that is exposed from the first inorganic insulating film 10 and is demarcated in a quadrilateral shape by the inner wall portion 11 (contact opening 13) in plan view. The outer surface 17 is constituted of a portion of the peripheral edge portion of the first main surface 3 that is exposed from the first inorganic insulating film 10 and is demarcated in a quadrilateral annular shape by the outer wall portion 12 (notch opening 14) in plan view.

In this embodiment, the active surface 16 is depressed toward a bottom portion side (second main surface 4 side) of the second semiconductor region 7 with respect to the hidden surface 15. Specifically, the active surface 16 is depressed by one step toward the bottom portion side of the second semiconductor region 7 with respect to the hidden surface 15 with the inner wall portion 11 (contact opening 13) as a starting point. In the normal direction Z, the active surface 16 is formed at a depth position between a bottom portion of the guard region 9 and the hidden surface 15.

The active surface 16 exposes the second semiconductor region 7 and the inner edge portion of the guard region 9. In the normal direction Z, the active surface 16 is preferably depressed within a range in excess of 0 μm and not more than 1 μm (preferably not more than 0.5 μm) with respect to the hidden surface 15. The n-type impurity concentration of the second semiconductor region 7 at a surface layer portion of the active surface 16 is higher than the n-type impurity concentration of the second semiconductor region 7 at a surface layer portion of the hidden surface 15.

In this embodiment, the outer surface 17 is depressed toward the bottom portion side (second main surface 4 side) of the second semiconductor region 7 with respect to the hidden surface 15. Specifically, the outer surface 17 is depressed by one step toward the bottom portion side of the second semiconductor region 7 with respect to the hidden surface 15 with the outer wall portion 12 (notch opening 14) as a starting point. In the normal direction Z, the outer surface 17 is formed at a depth position between the bottom portion of the guard region 9 and the hidden surface 15.

The outer surface 17 exposes the second semiconductor region 7. In the normal direction Z, the outer surface 17 is preferably depressed within a range of exceeding 0 μm and not more than 1 μm (preferably not more than 0.5 μm) with respect to the hidden surface 15. The outer surface 17 is preferably positioned on substantially the same plane as the active surface 16. The n-type impurity concentration of the second semiconductor region 7 at a surface layer portion of the outer surface 17 is higher than the n-type impurity concentration of the second semiconductor region 7 at the surface layer portion of the hidden surface 15.

The SiC semiconductor device 1 includes a first main surface electrode 20 that is formed on the first main surface 3. In this embodiment, the first main surface electrode 20 is formed to a quadrilateral shape having four sides parallel to the peripheral edge of the first main surface 3 in plan view. The first main surface electrode 20 is a Schottky electrode. The first main surface electrode 20 forms a Schottky junction with the first main surface 3. Specifically, the first main surface electrode 20 is electrically connected to the second semiconductor region 7 and the inner edge portion of the guard region 9 at the active surface 16 that is depressed toward the bottom portion side of the second semiconductor region 7 with respect to the hidden surface 15. The first main surface electrode 20 forms a Schottky junction with the second semiconductor region 7 at the active surface 16.

The SiC-SBD as an example of a functional device is thus formed at the active surface 16. The SiC-SBD includes the first main surface electrode 20 as an anode and the second semiconductor region 7 (first semiconductor region 6 and third semiconductor region 8) as a cathode.

The first main surface electrode 20 has an electrode side wall 21 positioned on the first inorganic insulating film 10. The electrode side wall 21 is formed at an interval toward the inner wall portion 11 side (active surface 16 side) of the first inorganic insulating film 10 from the peripheral edge of the first main surface 3 (first to fourth side surfaces 5A to 5D) in plan view. Specifically, on the first inorganic insulating film 10, the electrode side wall 21 is formed between the inner wall portion 11 and the outer wall portion 12 of the first inorganic insulating film 10.

In this embodiment, the electrode side wall 21 is formed at an interval toward the inner wall portion 11 side of the first inorganic insulating film 10 from the outer edge portion of the guard region 9 in plan view. The electrode side wall 21 faces the guard region 9 across the first inorganic insulating film 10. The electrode side wall 21 is formed to a tapered shape that is inclined obliquely downward from a main surface of the first main surface electrode 20. In this embodiment, the electrode side wall 21 is formed to a curved tapered shape that is curved toward the first inorganic insulating film 10.

More specifically, the first main surface electrode 20 includes a main body portion 22 that covers the active surface 16 and a lead-out portion 23 that covers the first inorganic insulating film 10. The main body portion 22 may be referred to as a Schottky electrode portion and the lead-out portion 23 may be referred to as a field electrode portion. The main body portion 22 is positioned inside the contact opening 13 and is electrically connected to the second semiconductor region 7 and the inner edge portion of the guard region 9. The main body portion 22 refills the contact opening 13 from the active surface 16 such as to project further upward than the first inorganic insulating film 10. The main body portion 22 extends substantially flatly along the active surface 16.

The lead-out portion 23 is led out from the main body portion 22 onto the first inorganic insulating film 10 and forms the electrode side wall 21 on the first inorganic insulating film 10. The lead-out portion 23 extends substantially flatly along the first inorganic insulating film 10. The lead-out portion 23 faces the guard region 9 across the first inorganic insulating film 10. In this embodiment, an entirety of the lead-out portion 23 faces the guard region 9.

At a peripheral edge portion of the first main surface electrode 20, the lead-out portion 23 forms a projecting portion 24 that projects further upward (in a direction away from the SiC chip 2) than the main body portion 22. In other words, the first main surface electrode 20 includes an inner portion (main body portion 22) that covers the first main surface 3 and a peripheral edge portion that covers the first inorganic insulating film 10 and has the projecting portion 24 (lead-out portion 23) that projects further upward than the inner portion (main body portion 22). That is, a slope (level difference) due to the projecting portion 24 is formed at the peripheral edge portion (region between the main body portion 22 and the lead-out portion 23) of the first main surface electrode 20.

The first main surface electrode 20 has a laminated structure that includes a first electrode film 25, a second electrode film 26, and a third electrode film 27 that are laminated in that order from the SiC chip 2 side. The first electrode film 25 is formed as a film along the active surface 16, the inner wall portion 11 of the first inorganic insulating film 10 (that is, the contact opening 13), and a main surface of the first inorganic insulating film 10. The first electrode film 25 is constituted of a Schottky barrier electrode film and forms a Schottky junction with the first main surface 3 (second semiconductor region 7). An electrode material of the first electrode film 25 is arbitrary as long as the Schottky junction with the first main surface 3 (second semiconductor region 7) is formed.

The first electrode film 25 may include at least one type of substance among magnesium (Mg), aluminum (Al), titanium (Ti), vanadium (V), chromium (Cr), manganese (Mn), cobalt (Co), nickel (Ni), copper (Cu), zirconium (Zr), niobium (Nb), molybdenum (Mo), palladium (Pd), silver (Ag), indium (In), tin (Sn), tantalum (Ta), tungsten (W), platinum (Pt), and gold (Au).

The first electrode film 25 may be constituted of an alloy film that includes at least one type of substance among the metal species mentioned above. In this embodiment, the first electrode film 25 is constituted of a titanium film. The first electrode film 25 has a first electrode thickness TE1. The first electrode thickness TE1 may be not less than 50 Å and not more than 1000 Å. The first electrode thickness TE1 is preferably not less than 250 Å and not more than 500 Å.

The second electrode film 26 is formed as a film along a main surface of the first electrode film 25. The second electrode film 26 is constituted of a metal barrier film. In this embodiment, the second electrode film 26 is constituted of a Ti-based metal film. The second electrode film 26 includes at least one type of film among a titanium film and a titanium nitride film. The second electrode film 26 may have a single layer structure that is constituted of a titanium film or a titanium nitride film or a laminated structure that includes a titanium film and a titanium nitride film in any order.

In this embodiment, the second electrode film 26 has a single layer structure constituted of a titanium nitride film. The second electrode film 26 has a second electrode thickness TE2. The second electrode thickness TE2 may be not less than 500 Å and not more than 5000 Å. The second electrode thickness TE2 is preferably not less than 1500 Å and not more than 4500 Å. The second electrode thickness TE2 preferably exceeds the first electrode thickness TE1 (TE1<TE2).

The third electrode film 27 is formed as a film along a main surface of the second electrode film 26. The third electrode film 27 is constituted of a Cu-based metal film or an Al-based metal film. The third electrode film 27 may include at least one type of film among a pure Cu film (a Cu film with a purity of not less than 99%), a pure Al film (an Al film with a purity of not less than 99%), an AlCu alloy film, an AlSi alloy film, and an AlSiCu alloy film. In this embodiment, the third electrode film 27 has a single layer structure constituted of an AlCu alloy film.

The third electrode film 27 has a third electrode thickness TE3. The third electrode thickness TE3 may be not less than 0.5 μm (=5000 Å) and not more than 10 μm (=10000 Å). The third electrode thickness TE3 is preferably not less than 2.5 μm and not more than 7.5 μm. The third electrode thickness TE3 preferably exceeds the first electrode thickness TE1 and the second electrode thickness TE2 (TE1<TE3 and TE2<TE3). The third electrode thickness TE3 especially preferably exceeds a sum of the first electrode thickness TE1 and the second electrode thickness TE2 (=TE1+TE2) (TE1+TE2<TE3).

The SiC semiconductor device 1 includes the second inorganic insulating film 30. The second inorganic insulating film 30 is constituted of an inorganic insulator having a comparatively high denseness and has a barrier property (blocking property) against water (moisture). For example, an oxide of the first main surface electrode 20 (in this embodiment, aluminum oxide) degrades electrical characteristics of the first main surface electrode 20. The oxide of the first main surface electrode 20 also becomes a factor that causes partial peeling, cracking, etc., of the first main surface electrode 20 and other structures through thermal expansion.

The second inorganic insulating film 30 covers either or both of the first inorganic insulating film 10 and the first main surface electrode 20 to block water (moisture) from the exterior and protects the SiC chip 2 and the first main surface electrode 20 from oxidation. The second inorganic insulating film 30 may be referred to as a passivation film.

The second inorganic insulating film 30 may have a laminated structure that includes a plurality of insulating films or may have a single layer structure constituted of a single insulating film. The second inorganic insulating film 30 preferably includes at least one among a silicon oxide film, a silicon nitride film, and a silicon oxynitride film. The second inorganic insulating film 30 may have a laminated structure that includes a plurality of silicon oxide films, a laminated structure that includes a plurality of silicon nitride films, or a laminated structure that includes a plurality of silicon oxynitride films.

The second inorganic insulating film 30 may have a laminated structure in which at least two types of films among a silicon oxide film, a silicon nitride film, and a silicon oxynitride film are laminated in any order. The second inorganic insulating film 30 may have a single layer structure constituted of a silicon oxide film, a silicon nitride film, or a silicon oxynitride film. In this embodiment, the second inorganic insulating film 30 has a single layer structure constituted of a silicon nitride film. That is, the second inorganic insulating film 30 is constituted of an insulator differing from the first inorganic insulating film 10.

The second inorganic insulating film 30 has a second insulating thickness T2. The second insulating thickness T2 may be not less than 0.05 μm and not more than 5 μm. The second insulating thickness T2 is preferably not less than 0.1 μm and not more than 2 μm. The second insulating thickness T2 may be not less than the first insulating thickness T1 (T1≤T2). The second insulating thickness T2 is preferably less than the first insulating thickness T1 (T1>T2).

The second insulating thickness T2 preferably exceeds the first electrode thickness TE1 of the first electrode film 25 and the second electrode thickness TE2 of the second electrode film 26 (TE1<T2 and TE2<T2). The second insulating thickness T2 especially preferably exceeds a sum of the first electrode thickness TE1 and the second electrode thickness TE2 (=TE1+TE2) (TE1+TE2<T2). The second insulating thickness T2 is preferably not more than the third electrode thickness TE3 of the third electrode film 27 (TE3≥T2). The second insulating thickness T2 is especially preferably less than the third electrode thickness TE3 (TE3>T2).

In this embodiment, the second inorganic insulating film 30 includes an inner covering portion 31 (electrode covering portion), an outer covering portion 32 (insulation covering portion), and a removed portion 33. The second inorganic insulating film 30 suffices to have at least one of either of the inner covering portion 31 and the outer covering portion 32 and is not necessarily required to include both the inner covering portion 31 and the outer covering portion 32. The second inorganic insulating film 30 preferably has at least the inner covering portion 31. The second inorganic insulating film 30 most preferably includes both the inner covering portion 31 and the outer covering portion 32.

The inner covering portion 31 of the second inorganic insulating film 30 covers the first main surface electrode 20 such as to expose the electrode side wall 21. The inner covering portion 31 also exposes the inner portion of the first main surface electrode 20. The inner covering portion 31 is formed as a band extending along the electrode side wall 21 in plan view. In this embodiment, the inner covering portion 31 is formed to an annular shape that surrounds the inner portion of the first main surface electrode 20 in plan view. Specifically, the inner covering portion 31 is formed to a quadrilateral annular shape that has four sides parallel to the electrode side wall 21 (peripheral edge of the first main surface 3) in plan view.

The inner covering portion 31 covers the first main surface electrode 20 at an interval from the electrode side wall 21 such as to expose the peripheral edge portion of the first main surface electrode 20. Specifically, the inner covering portion 31 is formed on the main body portion 22 of the first main surface electrode 20 such as to expose the lead-out portion 23 (projecting portion 24) of the first main surface electrode 20. In this case, the inner covering portion 31 is preferably formed at an interval toward an inner side of the first main surface electrode 20 from the inner wall portion 11 of the first inorganic insulating film 10 in plan view. Further, the inner covering portion 31 is preferably formed at an interval inward from the lead-out portion 23 (projecting portion 24) and exposes the entirety of the lead-out portion 23 (projecting portion 24).

In this embodiment, the inner covering portion 31 is formed as a flat film that extends along a main surface of the main body portion 22 such as to avoid the slope (level difference) of the first main surface electrode 20. In this embodiment, a main surface of the inner covering portion 31 is positioned at the main surface side of the main body portion 22 with respect to a main surface of the lead-out portion 23. Obviously, the main surface of the inner covering portion 31 may be positioned further upward than the main surface of the lead-out portion 23. That is, the inner covering portion 31 may have a thickness that exceeds a thickness of the projecting portion 24. The thickness of the projecting portion 24 is defined by a distance (thickness) in the normal direction Z between the main surface of the main body portion 22 and the main surface of the lead-out portion 23.

The inner covering portion 31 faces the active surface 16 across the first main surface electrode 20. In this embodiment, the inner covering portion 31 is formed at an interval inward from the inner wall portion 11 of the first inorganic insulating film 10 in plan view. The inner covering portion 31 thus does not face the first inorganic insulating film 10 across the first main surface electrode 20.

The inner covering portion 31 is formed at an interval inward from the inner edge portion of the guard region 9 in plan view. The inner covering portion 31 does not face the guard region 9 across the first main surface electrode 20. That is, the inner covering portion 31 faces just the second semiconductor region 7 across the first main surface electrode 20. Obviously, the inner covering portion 31 may also face either or both of the guard region 9 and the first inorganic insulating film 10 across the first main surface electrode 20 (lead-out portion 23).

The inner covering portion 31 has a first inner wall portion 34 at the inner portion side of the first main surface electrode 20 and a first outer wall portion 35 at the electrode side wall 21 side of the first main surface electrode 20. The first inner wall portion 34 demarcates a first opening 36 that exposes the inner portion of the first main surface electrode 20. In this embodiment, the first inner wall portion 34 (first opening 36) is formed to a quadrilateral shape that has four sides parallel to the electrode side wall 21 in plan view.

In this embodiment, the first inner wall portion 34 is formed on the main body portion 22 at an interval inward from the lead-out portion 23 (projecting portion 24). The first inner wall portion 34 thereby demarcates the first opening 36 that exposes an inner portion of the main body portion 22. The first inner wall portion 34 is formed to a tapered shape that is inclined obliquely downward from a main surface of the second inorganic insulating film 30 toward the inner side of the first main surface electrode 20.

The first outer wall portion 35 is formed on the first main surface electrode 20 at an interval from the electrode side wall 21 such as to expose the peripheral edge portion of the first main surface electrode 20. Specifically, the first outer wall portion 35 is formed on the main body portion 22 such as to expose the lead-out portion 23 (projecting portion 24). More specifically, the first outer wall portion 35 is formed at an interval inward from the lead-out portion 23 (projecting portion 24). The first outer wall portion 35 thereby exposes a portion of the main body portion 22 and the entirety of the lead-out portion 23 (projecting portion 24).

The first outer wall portion 35 is formed at an interval toward the inner side of the first main surface electrode 20 from the inner wall portion 11 of the first inorganic insulating film 10 in plan view. Further, the first outer wall portion 35 is formed at an interval inward from the inner edge portion of the guard region 9 in plan view. In this embodiment, the first outer wall portion 35 is formed to a quadrilateral shape that has four sides parallel to the electrode side wall 21 in plan view. The first outer wall portion 35 is formed to a tapered shape that is inclined obliquely downward from the main surface of the second inorganic insulating film 30 toward the lead-out portion 23 of the first main surface electrode 20.

The outer covering portion 32 of the second inorganic insulating film 30 covers the first inorganic insulating film 10 such as to expose the electrode side wall 21. The outer covering portion 32 is formed as a band extending along the electrode side wall 21 in plan view. The outer covering portion 32 is formed to an annular shape that surrounds the first main surface electrode 20 (electrode side wall 21) in plan view. Specifically, the outer covering portion 32 is formed to a quadrilateral annular shape having four sides parallel to the electrode side wall 21 (peripheral edge of the first main surface 3) in plan view.

The outer covering portion 32 covers the first inorganic insulating film 10 at an interval toward the peripheral edge side of the first main surface 3 from the electrode side wall 21 such as to expose a portion of the first inorganic insulating film 10. In this embodiment, the outer covering portion 32 faces the guard region 9 across the first inorganic insulating film 10. The outer covering portion 32 extends such as to traverse the outer edge portion of the guard region 9 in plan view and faces the second semiconductor region 7 outside the guard region 9 across the first inorganic insulating film 10. In this embodiment, the outer covering portion 32 is led out from above the first inorganic insulating film 10 to the outer surface 17.

Thereby, the outer covering portion 32 includes a first portion 37 that covers the first inorganic insulating film 10 and a second portion 38 that directly covers the outer surface 17. The first portion 37 extends as a film along the first inorganic insulating film 10 and faces the hidden surface 15 across the first inorganic insulating film 10. That is, the first portion 37 faces the second semiconductor region 7 and the guard region 9 across the first inorganic insulating film 10. A main surface of the first portion 37 is positioned at the first inorganic insulating film 10 side with respect to the main surface of the lead-out portion 23 of the first main surface electrode 20. In this embodiment, the main surface of the first portion 37 is positioned at the first inorganic insulating film 10 side with respect to the main surface of the main body portion 22 of the first main surface electrode 20.

The second portion 38 extends as a film along the outer surface 17 and directly covers the outer surface 17. That is, the second portion 38 directly covers the second semiconductor region 7. A main surface of the second portion 38 is positioned at the first main surface 3 (outer surface 17) side with respect to the main surface of the lead-out portion 23. The main surface of the second portion 38 is positioned at the first main surface 3 (outer surface 17) side with respect to the main surface of the main body portion 22. In this embodiment, the main surface of the second portion 38 is positioned between the main surface of the first inorganic insulating film 10 and the hidden surface 15.

In this embodiment, the second portion 38 is formed at an interval toward the first inorganic insulating film 10 side from the peripheral edge of the first main surface 3 (first to fourth side surfaces 5A to 5D) such as to expose the peripheral edge portion of the first main surface 3 (outer surface 17). The second portion 38 demarcates a dicing street 39 together with the peripheral edge of the first main surface 3 at which the peripheral edge portion of the first main surface 3 (outer surface 17) is exposed. The dicing street 39 is demarcated in a quadrilateral annular shape that extends along the peripheral edge of the first main surface 3. A width of the dicing street 39 may be not less than 5 μm and not more than 25 μm. The width of the dicing street 39 is a width in a direction orthogonal to a direction in which the dicing street 39 extends.

The outer covering portion 32 has a second inner wall portion 40 at the electrode side wall 21 side and a second outer wall portion 41 at the peripheral edge side of the first main surface 3 (outer surface 17). The second inner wall portion 40 is formed on the first inorganic insulating film 10 at an interval from the electrode side wall 21 such as to expose the first inorganic insulating film 10. That is, the second inner wall portion 40 is formed in a region between the inner wall portion 11 and the outer wall portion 12 of the first inorganic insulating film 10 in plan view.

In this embodiment, the second inner wall portion 40 is formed in a region between the electrode side wall 21 and the outer edge portion of the guard region 9 in plan view. Thereby, the second inner wall portion 40 exposes a portion of the first inorganic insulating film 10 that covers the guard region 9. In this embodiment, the second inner wall portion 40 is formed to a quadrilateral shape that has four sides parallel to the electrode side wall 21 in plan view and surrounds the first main surface electrode 20. The second inner wall portion 40 is formed to a tapered shape that is inclined obliquely downward from the main surface of the second inorganic insulating film 30 toward the inner side of the first main surface 3.

In this embodiment, the second outer wall portion 41 is formed on the outer surface 17. The second outer wall portion 41 is formed in a region between the outer wall portion 12 of the first inorganic insulating film 10 (notch opening 14) and the peripheral edge of the first main surface 3 in plan view and exposes the peripheral edge portion of the first main surface 3 (outer surface 17). The second outer wall portion 41 is formed to a tapered shape that is inclined obliquely downward from the main surface of the second inorganic insulating film 30 toward the peripheral edge of the first main surface 3 (outer surface 17). Together with the peripheral edge of the first main surface 3, the second outer wall portion 41 demarcates the dicing street 39.

The removed portion 33 of the second inorganic insulating film 30 is demarcated between the inner covering portion 31 (first outer wall portion 35) and the outer covering portion 32 (second inner wall portion 40) and exposes the electrode side wall 21 of the first main surface electrode 20. In this embodiment, the removed portion 33 is formed as a band extending along the electrode side wall 21 in plan view. Specifically, the removed portion 33 is formed to an annular shape (a quadrilateral annular shape in this embodiment) that extends along the electrode side wall 21 in plan view.

That is, the removed portion 33 exposes the electrode side wall 21, the lead-out portion 23 (projecting portion 24) of the first main surface electrode 20, and a portion of the first inorganic insulating film 10 along an entire periphery of the electrode side wall 21. With the second inorganic insulating film 30, the inner covering portion 31 is formed on the first main surface electrode 20 that is flat and the outer covering portion 32 is formed on the first inorganic insulating film 10 that is flat. Therefore, with the second inorganic insulating film 30, a level difference due to the electrode side wall 21 is eliminated by the removed portion 33.

The SiC semiconductor device 1 includes an organic insulating film 50 that covers the electrode side wall 21 of the first main surface electrode 20. The organic insulating film 50 has a lower hardness than a hardness of the second inorganic insulating film 30. In other words, the organic insulating film 50 has an elastic modulus that is lower than an elastic modulus of the second inorganic insulating film 30 and functions as a cushioning material (protective film) against an external force. The organic insulating film 50 protects the SiC chip 2, the first main surface electrode 20, the second inorganic insulating film 30, etc., from the external force.

The organic insulating film 50 preferably includes a photosensitive resin. The photosensitive resin may be of a negative type or a positive type. The organic insulating film 50 may include at least one among a polyimide film, a polyamide film, and a polybenzoxazole film. In this embodiment, the organic insulating film 50 includes a polyimide film.

The organic insulating film 50 has a third insulating thickness T3. The third insulating thickness T3 preferably exceeds the second insulating thickness T2 of the second inorganic insulating film 30 (T2<T3). The third insulating thickness T3 especially preferably exceeds a total thickness of the first main surface electrode 20 (=TE1+TE1+TE3) (TE1+TE1+TE3<T3). The third insulating thickness T3 may be not less than 1 μm and not more than 50 μm. The third insulating thickness T3 is preferably not less than 5 μm and not more than 30 μm.

The organic insulating film 50 covers the first electrode film 25, the second electrode film 26, and the third electrode film 27 at the electrode side wall 21. The organic insulating film 50 is formed as a band extending along the electrode side wall 21 in plan view. In this embodiment, the organic insulating film 50 is formed to an annular shape that surrounds the inner portion of the first main surface electrode 20 in plan view and covers the electrode side wall 21 over entire periphery. Specifically, the organic insulating film 50 is formed to a quadrilateral annular shape that has four sides parallel to the electrode side wall 21 (peripheral edge of the first main surface 3) in plan view.

The organic insulating film 50 covers an edge portion of the first main surface electrode 20. That is, the organic insulating film 50 extends from the electrode side wall 21 toward the inner covering portion 31 side of the second inorganic insulating film 30 and covers the peripheral edge portion of the first main surface electrode 20 that is exposed from between the electrode side wall 21 and the inner covering portion 31. Specifically, the organic insulating film 50 covers the lead-out portion 23 (projecting portion 24) of the first main surface electrode 20. The organic insulating film 50 further extends from above the lead-out portion 23 (projecting portion 24) toward the main body portion 22 side of the first main surface electrode 20 and covers a portion of the main body portion 22.

The organic insulating film 50 further extends from above the lead-out portion 23 (projecting portion 24) toward above the inner covering portion 31 of the second inorganic insulating film 30 and covers the inner covering portion 31. The organic insulating film 50 covers the inner covering portion 31 such as to expose the inner portion of the first main surface electrode 20. Specifically, the organic insulating film 50 covers the inner covering portion 31 such as to expose the first inner wall portion 34 of the inner covering portion 31. More specifically, the organic insulating film 50 covers the inner covering portion 31 at an interval toward the first outer wall portion 35 side from the first inner wall portion 34 and exposes the inner portion of the first main surface electrode 20 and an edge portion 51 of the inner covering portion 31 in plan view.

The organic insulating film 50 extends from the electrode side wall 21 toward the outer covering portion 32 of the second inorganic insulating film 30 and covers the portion of the first inorganic insulating film 10 that is exposed from between the electrode side wall 21 and the outer covering portion 32. The organic insulating film 50 faces the guard region 9 across the first inorganic insulating film 10 between the electrode side wall 21 and the outer covering portion 32. The organic insulating film 50 further extends from above the first inorganic insulating film 10 toward above the outer covering portion 32 and covers the outer covering portion 32. The organic insulating film 50 covers the outer covering portion 32 such as to expose the peripheral edge portion of the first main surface 3 (outer surface 17).

Specifically, the organic insulating film 50 covers the outer covering portion 32 such as to expose the second outer wall portion 41. More specifically, the organic insulating film 50 covers the outer covering portion 32 at an interval toward the second inner wall portion 40 side from the second outer wall portion 41 and exposes the peripheral edge portion of the first main surface 3 (outer surface 17) and a portion of the outer covering portion 32 in plan view. That is, the organic insulating film 50 covers the first portion 37 and the second portion 38 of the outer covering portion 32 such as to expose the outer surface 17.

The organic insulating film 50 has a third inner wall portion 52 at the electrode side wall 21 side and a third outer wall portion 53 at an opposite side to the third inner wall portion 52 (at the peripheral edge portion side of the first main surface 3). The third inner wall portion 52 demarcates a second opening 54 that exposes the inner portion of the first main surface electrode 20. The third inner wall portion 52 (second opening 54) extends along the first inner wall portion 34 of the inner covering portion 31 (first opening 36). In this embodiment, the third inner wall portion 52 is formed to a quadrilateral shape that has four sides parallel to the first inner wall portion 34 of the inner covering portion 31 in plan view.

The third inner wall portion 52 is formed on the inner covering portion 31 at an interval toward the first outer wall portion 35 side from the first inner wall portion 34 and exposes the inner portion of the first main surface electrode 20 and the edge portion 51 of the inner covering portion 31. That is, the second opening 54 exposes the inner portion of the first main surface electrode 20 and the edge portion 51 of the inner covering portion 31. An exposed width WE of the edge portion 51 may exceed 0 μm and be not more than 10 μm. The exposed width WE is preferably not less than 1 μm and not more than 5 μm.

The third inner wall portion 52 (second opening 54) is in communication with the first inner wall portion 34 (first opening 36) and forms a single pad opening 55 with the first inner wall portion 34 (first opening 36). The third inner wall portion 52 is formed to a tapered shape that is inclined obliquely downward from a main surface of the organic insulating film 50 toward the first inner wall portion 34. In this embodiment, the third inner wall portion 52 is formed to a curved tapered shape that is curved toward the inner covering portion 31.

The third outer wall portion 53 is formed at an interval toward the outer covering portion 32 from the peripheral edge of the first main surface 3 (first to fourth side surfaces 5A to 5D) such as to expose the outer surface 17. The third outer wall portion 53 exposes the second outer wall portion 41 of the outer covering portion 32. Specifically, the third outer wall portion 53 is formed at an interval toward the second inner wall portion 40 side from the second outer wall portion 41 such as to expose a peripheral edge portion of the outer covering portion 32. The third outer wall portion 53 is positioned on the second portion 38 of the outer covering portion 32 and faces the outer surface 17 across the outer covering portion 32.

That is, the third outer wall portion 53 is positioned between the outer wall portion 12 of the first inorganic insulating film 10 (notch opening 14) and the peripheral edge of the first main surface 3. The third outer wall portion 53 demarcates the dicing street 39 together with the second outer wall portion 41. In this embodiment, the third outer wall portion 53 is formed to a quadrilateral shape that has four sides parallel to the electrode side wall 21 in plan view. The third outer wall portion 53 is formed to a tapered shape that is inclined obliquely downward from the main surface of the organic insulating film 50 toward the second outer wall portion 41 of the outer covering portion 32. In this embodiment, the third outer wall portion 53 is formed to a curved tapered shape that is curved toward the outer covering portion 32.

The organic insulating film 50 is thus formed across the inner covering portion 31 and the outer covering portion 32 of the second inorganic insulating film 30 and covers the electrode side wall 21 of the first main surface electrode 20 inside the removed portion 33 between the inner covering portion 31 and the outer covering portion 32. Specifically, inside the removed portion 33, the organic insulating film 50 covers the electrode side wall 21 of the first main surface electrode 20, a portion of the main body portion 22 of the first main surface electrode 20, the lead-out portion 23 (projecting portion 24) of the first main surface electrode 20, and a portion of the first inorganic insulating film 10. That is, the organic insulating film 50 fills an unevenness formed by the first inorganic insulating film 10, the first main surface electrode 20, and the second inorganic insulating film 30 inside the removed portion 33.

The SiC semiconductor device 1 includes a pad electrode 60 that is formed on the inner portion of the first main surface electrode 20. The pad electrode 60 is a terminal electrode for external connection and is constituted of a plating film in this embodiment. The pad electrode 60 includes an Ni plating film 61 that is formed on the inner portion of the first main surface electrode 20 inside the pad opening 55. In the normal direction Z, the Ni plating film 61 is formed at an interval toward the first main surface electrode 20 side from the main surface of the organic insulating film 50. Inside the first opening 36, the Ni plating film 61 covers the main body portion 22 of the first main surface electrode 20 and the first inner wall portion 34 of the inner covering portion 31.

The Ni plating film 61 is led out from above the main body portion 22 of the first main surface electrode 20 onto the edge portion 51 of the inner covering portion 31. The Ni plating film 61 thereby has a plating covering portion 62 that covers the edge portion 51 of the inner covering portion 31 inside the second opening 54. On the edge portion 51, the plating covering portion 62 is formed to an arcuate shape directed toward the organic insulating film 50 (third inner wall portion 52) with the first inner wall portion 34 as a starting point.

In this embodiment, the plating covering portion 62 covers the organic insulating film 50 (third inner wall portion 52) inside the second opening 54. The plating covering portion 62 covers a region of the organic insulating film 50 at the second inorganic insulating film 30 side with respect to an intermediate portion of the third inner wall portion 52. In other words, the plating covering portion 62 covers the organic insulating film 50 such that an exposed area of the third inner wall portion 52 exceeds a hidden area of the third inner wall portion 52. The plating covering portion 62 thus fills an entirety of the first opening 36 and a portion of the second opening 54.

The Ni plating film 61 has a first plating thickness TP1. The first plating thickness TP1 is a thickness of the Ni plating film 61 on the basis of the main surface of the first main surface electrode 20 (main body portion 22). The first plating thickness TP1 exceeds the second insulating thickness T2 of the second inorganic insulating film 30 (T2<TP1). The first plating thickness TP1 is less than the third insulating thickness T3 of the organic insulating film 50 (TP1<T3).

The first plating thickness TP1 exceeds a sum of the second insulating thickness T2 of the second inorganic insulating film 30 and the exposed width WE of the second inorganic insulating film 30 (=T2+WE) (T2+WE<T4). This is one condition for the Ni plating film 61 to be in contact with the third inner wall portion 52. The first plating thickness TP1 may be not less than 0.1 μm and not more than 15 μm. The first plating thickness TP1 is preferably not less than 2 μm and not more than 8 μm.

The pad electrode 60 includes an outer plating film 63 that is constituted of a metal material differing from the Ni plating film 61 and covers an outer surface of the Ni plating film 61. The outer plating film 63 is formed as a film along the outer surface of the Ni plating film 61. The outer plating film 63 covers the third inner wall portion 52 of the organic insulating film 50 inside the second opening 54.

The outer plating film 63 has a terminal surface 64 for external connection. In the normal direction Z, the terminal surface 64 is positioned at the Ni plating film 61 side with respect to the main surface of the organic insulating film 50 (opening end of the second opening 54). The outer plating film 63 thereby exposes a portion of the third inner wall portion 52 of the organic insulating film 50. The outer plating film 63 has a second plating thickness TP2. The second plating thickness TP2 is less than the first plating thickness TP1 of the Ni plating film 61 (TP2<TP1).

In this embodiment, the outer plating film 63 has a laminated structure that includes a Pd plating film 65 and an Au plating film 66 that are laminated in that order from the Ni plating film 61 side. The Pd plating film 65 is formed as a film along the outer surface of the Ni plating film 61. In the normal direction Z, the Pd plating film 65 covers the Ni plating film 61 at an interval toward the second inorganic insulating film 30 side from the opening end of the second opening 54. The Pd plating film 65 covers the third inner wall portion 52 of the organic insulating film 50 inside the second opening 54. A thickness of the Pd plating film 65 may be not less than 0.01 μm and not more than 1 μm.

The Au plating film 66 is formed as a film along an outer surface of the Pd plating film 65. In the normal direction Z, the Au plating film 66 covers the Pd plating film 65 at an interval toward the second inorganic insulating film 30 side from the opening end of the second opening 54. The Au plating film 66 covers the third inner wall portion 52 of the organic insulating film 50 inside the second opening 54. A thickness of the Au plating film 66 may be not less than 0.01 μm and not more than 1 μm. The Au plating film 66 preferably has a thickness less than the thickness of the Pd plating film 65.

The SiC semiconductor device 1 includes a second main surface electrode 70 that covers the second main surface 4. The second main surface electrode 70 covers an entire area of the second main surface 4 and is continuous to the first to fourth side surfaces 5A to 5D. The second main surface electrode 70 is electrically connected to the first semiconductor region 6 (second main surface 4). Specifically, the second main surface electrode 70 forms an ohmic contact with the first semiconductor region 6 (second main surface 4).

In this embodiment, the second main surface electrode 70 includes a Ti film 71, an Ni film 72, a Pd film 73, an Au film 74, and an Ag film 75 that are laminated in that order from the second main surface 4 side. The second main surface electrode 70 suffices to include at least the Ti film 71 and presence/absences of the Ni film 72, the Pd film 73, the Au film 74, and the Ag film 75 are respectively arbitrary. As an example, the second main surface electrode 70 may have a laminated structure that includes the Ti film 71, the Ni film 72, and the Au film 74.

As described above, the SiC semiconductor device 1 (electronic component) includes the first inorganic insulating film 10 (covered object), the first main surface electrode 20 (electrode), the second inorganic insulating film 30, and the organic insulating film 50. The first main surface electrode 20 covers the first inorganic insulating film 10 and has the electrode sidewall 21 on the first inorganic insulating film 10. The second inorganic insulating film 30 has the inner covering portion 31 that covers the first main surface electrode 20 such as to expose the electrode side wall 21. The organic insulating film 50 covers the electrode side wall 21.

An electronic component is used under various environments in accordance with application and is thus required to have durability adapted to various usage environmental conditions. In particular, the SiC semiconductor device 1 as an example of an electronic component is installed into hybrid vehicles, electric automobiles, fuel cell automobiles, and other vehicles, etc., having a motor as a driving source due to the physical properties (electrical characteristics) of SiC. Thus, with the SiC semiconductor device 1, excellent durability adapted to severe usage environmental conditions is required. The durability of an electronic component is evaluated, for example, by a high temperature/high humidity bias test. In the high temperature/high humidity bias test, electrical operation of the electronic component is evaluated in a state of being exposed to a high temperature/high humidity environment.

Under a high temperature environment, stress due to thermal expansion of the first main surface electrode 20 concentrates at a vicinity of the electrode side wall 21 of the first main surface electrode 20. If the second inorganic insulating film 30 covers the electrode side wall 21 of the first main surface electrode 20, there is a possibility for the second inorganic insulating film 30 to peel from the electrode side wall 21 due to the stress of the first main surface electrode 20 and reliability to degrade. If peeling of the second inorganic insulating film 30 occurs, then, under a high humidity environment, there is a possibility for the first main surface electrode 20, etc., to become oxidized due to water (moisture) entering into a peeled portion of the second inorganic insulating film 30 and reliability to degrade further.

Thus, with the SiC semiconductor device 1, the second inorganic insulating film 30 is formed such as to expose the electrode side wall 21. Peeling starting points of the second inorganic insulating film 30 due to the stress of the first main surface electrode 20 can thereby be reduced. Consequently, peeling of the second inorganic insulating film 30 due to the stress of the first main surface electrode 20 can be suppressed. The first main surface electrode 20 can thus be protected appropriately by the second inorganic insulating film 30.

On the other hand, the organic insulating film 50 covers the electrode side wall 21. The organic insulating film 50 has a low hardness in comparison to the second inorganic insulating film 30. Therefore, even if a stress arises in the first main surface electrode 20, the stress can be absorbed elastically. Peeling of the organic insulating film 50 from the electrode side wall 21 can thereby be suppressed. Consequently, the electrode side wall 21 can be protected by the organic insulating film 50. The SiC semiconductor device 1 that can be improved in reliability can thus be provided. With the SiC semiconductor device 1, reliability of the first main surface electrode 20 and a periphery thereof is especially improved.

The organic insulating film 50 preferably covers the inner covering portion 31. According to this structure, peeling of the second inorganic insulating film 30 from the first main surface electrode 20 can be suppressed and therefore, peeling of the organic insulating film 50 due to peeling of the second inorganic insulating film 30 can be suppressed. Therefore, by forming the organic insulating film 50 that covers the inner covering portion 31, the first main surface electrode 20 can be protected by both the second inorganic insulating film 30 and the organic insulating film 50.

The inner covering portion 31 preferably covers the first main surface electrode 20 at an interval from the electrode side wall 21 such as to expose the peripheral edge portion of the first main surface electrode 20. According to this structure, influence of the stress of the first main surface electrode 20 on the inner covering portion 31 can be reduced. In this case, the inner covering portion 31 preferably exposes the lead-out portion 23 (projecting portion 24). According to this structure, influence of stress of the lead-out portion 23 (projecting portion 24) on the inner covering portion 31 can be reduced.

In these cases, the organic insulating film 50 preferably covers the portion of the first main surface electrode 20 that is exposed from between the electrode side wall 21 and the inner covering portion 31. According to this structure, the portion of the first main surface electrode 20 that is exposed from the second inorganic insulating film 30 can be protected by the organic insulating film 50. The inner covering portion 31 preferably exposes the inner portion of the first main surface electrode 20. According to this structure, a contact portion of the first main surface electrode 20 can be secured. In this case, the inner covering portion 31 preferably surrounds the inner portion of the first main surface electrode 20.

The second inorganic insulating film 30 preferably has the outer covering portion 32 that covers the first inorganic insulating film 10 such as to expose the electrode side wall 21 of the first main surface electrode 20. According to this structure, peeling of the second inorganic insulating film 30 from the first inorganic insulating film 10 due to the stress of the first main surface electrode 20 can be suppressed in a region outside the first main surface electrode 20. The first main surface electrode 20 can thereby be protected by the second inorganic insulating film 30 from the region outside the first main surface electrode 20.

The organic insulating film 50 preferably covers the outer covering portion 32. According to this structure, peeling of the second inorganic insulating film 30 from the first inorganic insulating film 10 can be suppressed and therefore, peeling of the organic insulating film 50 due to peeling of the second inorganic insulating film 30 can be suppressed. Therefore, by forming the organic insulating film 50 that covers the outer covering portion 32, the first main surface electrode 20 can be protected by both the second inorganic insulating film 30 and the organic insulating film 50.

The outer covering portion 32 preferably covers the first inorganic insulating film 10 at an interval from the electrode side wall 21 of the first main surface electrode 20. According to this structure, influence of the stress of the first main surface electrode 20 on the outer covering portion 32 can be reduced. The organic insulating film 50 preferably covers the portion of the first inorganic insulating film 10 that is exposed from between the electrode side wall 21 and the outer covering portion 32. According to this structure, the portion of the first inorganic insulating film 10 that is exposed from between the electrode side wall 21 and the outer covering portion 32 can be protected by the organic insulating film 50. The outer covering portion 32 preferably surrounds the first main surface electrode 20 in plan view. According to this structure, the first main surface electrode 20 can be protected appropriately by the second inorganic insulating film 30 from the region outside the first main surface electrode 20.

The SiC semiconductor device 1 (electronic component) includes the first main surface electrode 20 (electrode), the second inorganic insulating film 30, the organic insulating film 50, and the pad electrode 60. The first main surface electrode 20 has the electrode side wall 21. The second inorganic insulating film 30 covers the first main surface electrode 20 such as to expose the inner portion of the first main surface electrode 20 and the electrode side wall 21 of the first main surface electrode 20.

The organic insulating film 50 covers the electrode side wall 21 of the first main surface electrode 20 and exposes the inner portion of the first main surface electrode 20. The pad electrode 60 is formed on the inner portion of the first main surface electrode 20. According to this structure, peeling of the second inorganic insulating film 30 can be suppressed. Therefore, peeling of the pad electrode 60 due to peeling of the second inorganic insulating film 30 can also be suppressed. The SiC semiconductor device 1 that can be improved in reliability can thus be provided. With the SiC semiconductor device 1, reliability of the first main surface electrode 20 and the periphery thereof is especially improved.

The second inorganic insulating film 30 preferably extends as a band along the electrode side wall 21 in plan view. In this case, the second inorganic insulating film 30 especially preferably surrounds the inner portion of the first main surface electrode 20 in plan view. According to this structure, the first main surface electrode 20 can be protected appropriately by the second inorganic insulating film 30.

The pad electrode 60 is preferably in contact with the second inorganic insulating film 30. According to this structure, peeling of the second inorganic insulating film 30 can be suppressed and therefore, the pad electrode 60 that is in contact with the second inorganic insulating film 30 can be formed appropriately. A connection area of the pad electrode 60 with respect to a base can thereby be increased appropriately and therefore, peeling of the pad electrode 60 can be suppressed appropriately.

The organic insulating film 50 preferably covers the second inorganic insulating film 30 on the first main surface electrode 20. According to this structure, peeling of the second inorganic insulating film 30 from the first main surface electrode 20 can be suppressed and therefore, peeling of the organic insulating film 50 due to peeling of the second inorganic insulating film 30 can be suppressed. Therefore, by forming the organic insulating film 50 that covers the inner covering portion 31, the first main surface electrode 20 and the pad electrode 60 can be protected by both the second inorganic insulating film 30 and the organic insulating film 50.

In this structure, the pad electrode 60 is preferably in contact with the organic insulating film 50. According to this structure, peeling of the organic insulating film 50 can be suppressed and therefore, peeling of the pad electrode 60 due to peeling of the organic insulating film 50 can be suppressed. Also, the connection area of the pad electrode 60 with respect to the base can be increased and therefore, peeling of the pad electrode 60 can be suppressed.

The organic insulating film 50 preferably covers the second inorganic insulating film 30 such as to expose the edge portion 51 of the second inorganic insulating film 30 at the inner portion side of the first main surface electrode 20. In this case, the pad electrode 60 preferably covers the edge portion 51 of the second inorganic insulating film 30. According to this structure, the connection area of the pad electrode 60 with respect to the base can be increased and therefore, peeling of the pad electrode 60 can be suppressed appropriately.

In this case, the pad electrode 60 preferably includes the Ni plating film 61. The Ni plating film 61 has satisfactory adhesion to the second inorganic insulating film 30. Therefore, by forming the Ni plating film 61 that covers the edge portion 51 of the second inorganic insulating film 30, peeling of the pad electrode 60 can be suppressed appropriately.

The Ni plating film 61 preferably covers the region of the organic insulating film 50 at the second inorganic insulating film 30 side with respect to the intermediate portion of the third inner wall portion 52. That is, the Ni plating film 61 preferably covers the organic insulating film 50 such that the hidden area of the third inner wall portion 52 is less than the exposed area of the third inner wall portion 52.

The pad electrode 60 may include the outer plating film 63 that covers the outer surface of the Ni plating film 61. According to this structure, peeling of the Ni plating film 61 can be suppressed and therefore, peeling of the outer plating film 63 due to peeling of the Ni plating film 61 can be suppressed. The Ni plating film 61 can thus be covered appropriately by the outer plating film 63. The outer plating film 63 may include at least one among the Pd plating film 65 and the Au plating film 66.

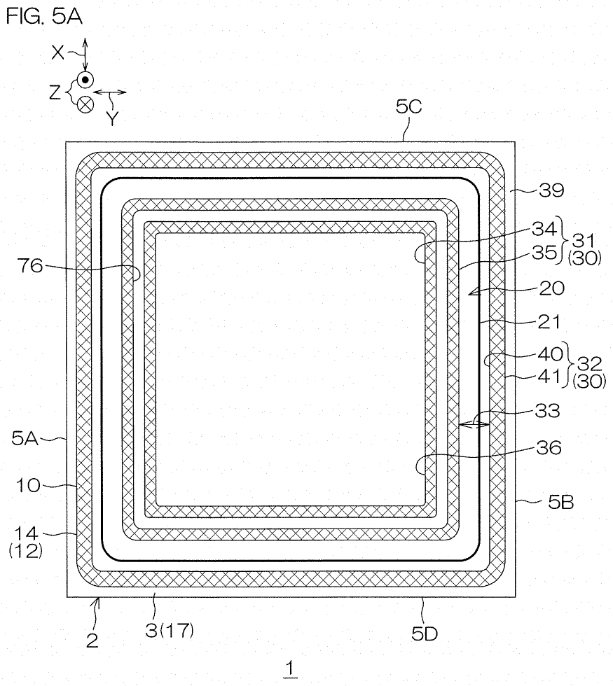

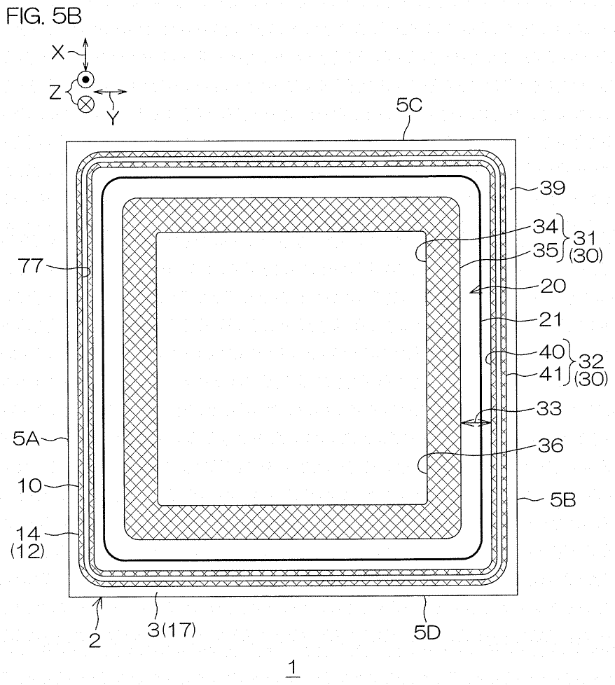

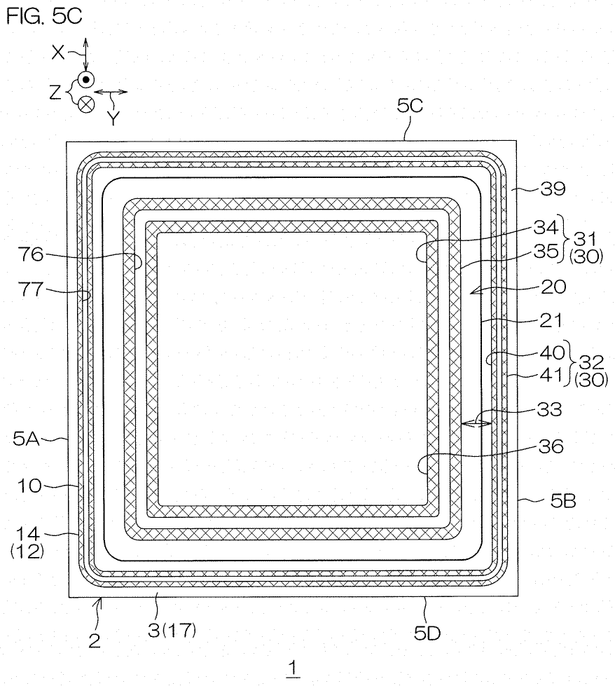

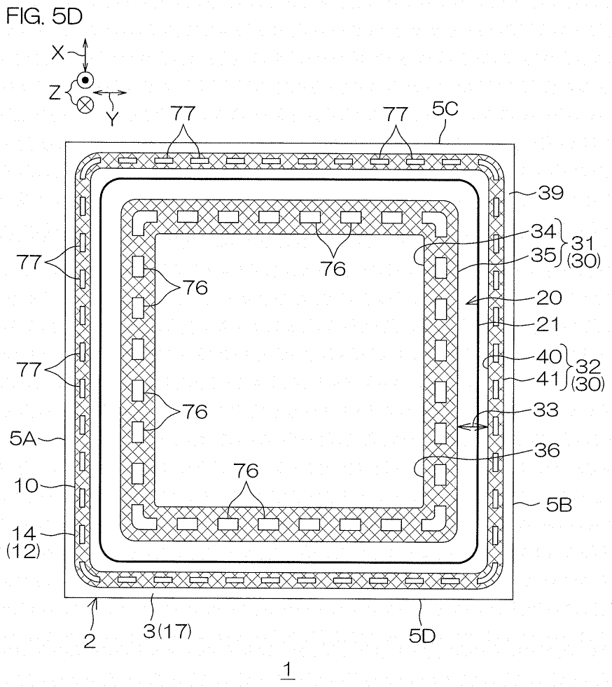

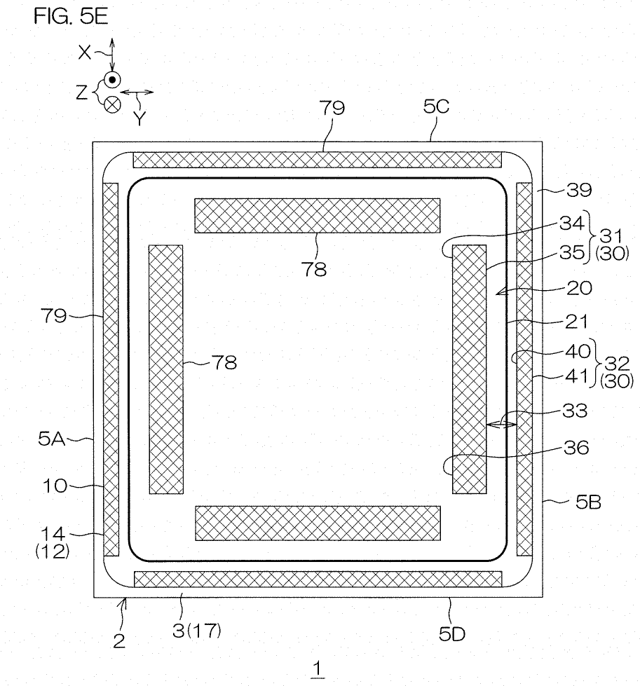

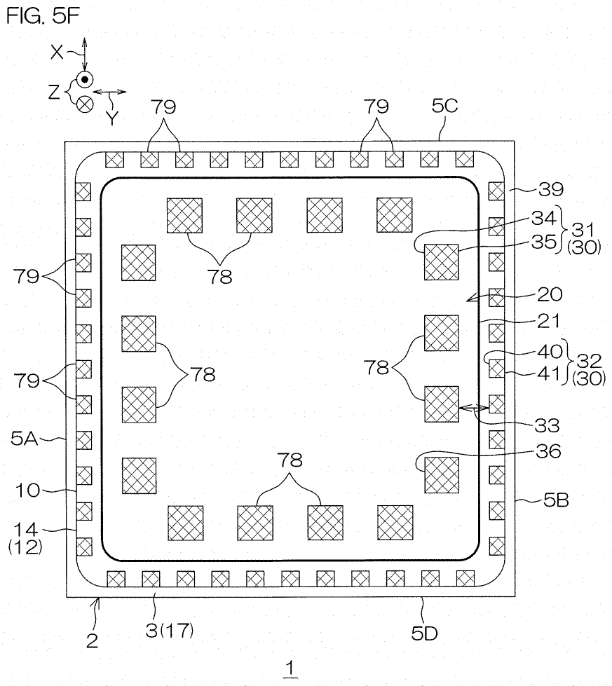

The second inorganic insulating film 30 can take on any of the various forms shown in FIG. 5A to FIG. 5F. FIG. 5A is a plan view corresponding to FIG. 2 of the internal structure of the SiC semiconductor device 1 shown together with the second inorganic insulating film 30 according to a second configuration example. In the following, structures corresponding to the structures shown in FIG. 1 to FIG. 4 are provided with the same reference symbols and description thereof is omitted.

Referring to FIG. 5A, the inner covering portion 31 of the second inorganic insulating film 30 has an inner opening portion 76 that exposes the first main surface electrode 20. The inner opening portion 76 is formed in an inner portion of the inner covering portion 31 at intervals from the first inner wall portion 34 and the first outer wall portion 35. The inner opening portion 76 is formed as a band extending along the first inner wall portion 34 and the first outer wall portion 35. In this embodiment, the inner opening portion 76 is formed to an annular shape (specifically, a quadrilateral annular shape) that extends along the first inner wall portion 34 and the first outer wall portion 35. The inner opening portion 76 exposes the main body portion 22 of the first main surface electrode 20 at an interval from the lead-out portion 23 (projecting portion 24) of the first main surface electrode 20.

The organic insulating film 50 enters into the inner opening portion 76 from above the inner covering portion 31 and covers a portion of the first main surface electrode 20 that is exposed from the inner opening portion 76. A portion of the organic insulating film 50 that is positioned inside the inner opening portion 76 of the second inorganic insulating film 30 forms an anchor portion. A contact area of the organic insulating film 50 with respect to the second inorganic insulating film 30 is thereby increased and peeling of the organic insulating film 50 from the second inorganic insulating film 30 can be suppressed.

FIG. 5B is a plan view corresponding to FIG. 2 of the internal structure of the SiC semiconductor device 1 shown together with the second inorganic insulating film 30 according to a third configuration example. In the following, structures corresponding to the structures shown in FIG. 1 to FIG. 4 are provided with the same reference symbols and description thereof is omitted.

Referring to FIG. 5B, the outer covering portion 32 of the second inorganic insulating film 30 has an outer opening portion 77 that exposes the first inorganic insulating film 10. The outer opening portion 77 is formed in an inner portion of the outer covering portion 32 at intervals from the second inner wall portion 40 and the second outer wall portion 41. The outer opening portion 77 is formed as a band extending along the second inner wall portion 40 and the second outer wall portion 41. In this embodiment, the outer opening portion 77 is formed to an annular shape (specifically, a quadrilateral annular shape) that extends along the second inner wall portion 40 and the second outer wall portion 41.

The organic insulating film 50 enters into the outer opening portion 77 from above the outer covering portion 32 and covers a portion of the first inorganic insulating film 10 that is exposed from the outer opening portion 77. A portion of the organic insulating film 50 that is positioned inside the outer opening portion 77 forms an anchor portion. The contact area of the organic insulating film 50 with respect to the second inorganic insulating film 30 is thereby increased and peeling of the organic insulating film 50 from the second inorganic insulating film 30 can be suppressed.

FIG. 5C is a plan view corresponding to FIG. 2 of the internal structure of the SiC semiconductor device 1 shown together with the second inorganic insulating film 30 according to a fourth configuration example. In the following, structures corresponding to the structures shown in FIG. 1 to FIG. 4 are provided with the same reference symbols and description thereof is omitted.

Referring to FIG. 5C, the inner covering portion 31 of the second inorganic insulating film 30 has the inner opening portion 76 that exposes the first main surface electrode 20 (see also FIG. 5A). The outer covering portion 32 of the second inorganic insulating film 30 has the outer opening portion 77 that exposes the first inorganic insulating film 10 (see also FIG. 5B). Of the organic insulating film 50, a portion that is positioned inside the inner opening portion 76 and a portion that is positioned inside the outer opening portion 77 respectively form anchor portions. Peeling of the organic insulating film 50 from the second inorganic insulating film 30 can thereby be suppressed at the inner portion and an outer portion of the first main surface electrode 20.

FIG. 5D is a plan view corresponding to FIG. 2 of the internal structure of the SiC semiconductor device 1 shown together with the second inorganic insulating film 30 according to a fifth configuration example. In the following, structures corresponding to the structures shown in FIG. 1 to FIG. 4 are provided with the same reference symbols and description thereof is omitted.

Referring to FIG. 5D, the inner covering portion 31 of the second inorganic insulating film 30 has a plurality of the inner opening portions 76 that expose the first main surface electrode 20. The plurality of inner opening portions 76 are respectively formed in the inner portion of the inner covering portion 31 at intervals from the first inner wall portion 34 and the first outer wall portion 35. The plurality of inner opening portions 76 are formed at intervals along the first inner wall portion 34 (first outer wall portion 35).

In this embodiment, each inner opening portion 76 is formed as a band extending along the first inner wall portion 34 in plan view. A planar shape of each inner opening portion 76 is arbitrary. Each inner opening portion 76 may be formed to a polygonal shape or a circular shape in plan view. Each inner opening portion 76 exposes the main body portion 22 of the first main surface electrode 20 at an interval from the lead-out portion 23 (projecting portion 24) of the first main surface electrode 20.

The outer covering portion 32 of the second inorganic insulating film 30 has a plurality of the outer opening portions 77 that expose the first inorganic insulating film 10. The plurality of outer opening portions 77 are respectively formed in the inner portion of the outer covering portion 32 at intervals from the second inner wall portion 40 and the second outer wall portion 41. The plurality of outer opening portions 77 are formed at intervals along the second inner wall portion 40 (second outer wall portion 41). In this embodiment, each outer opening portion 77 is formed as a band extending along the second inner wall portion 40 in plan view. A planar shape of each outer opening portion 77 is arbitrary. Each outer opening portion 77 may be formed to a polygonal shape or a circular shape in plan view.

Of the organic insulating film 50, portions that are positioned inside the plurality of inner opening portions 76 and portions that are positioned inside the plurality of outer opening portions 77 respectively form anchor portions. The contact area of the organic insulating film 50 with respect to the second inorganic insulating film 30 is thereby increased and peeling of the organic insulating film 50 from the second inorganic insulating film 30 can be suppressed.

With this embodiment, an example where the inner covering portion 31 has the plurality of inner opening portions 76 and the outer covering portion 32 has the plurality of outer opening portions 77 was described. However, the inner covering portion 31 may have just one inner opening portion 76 that is formed to a shape with ends. Also, the outer covering portion 32 may have just one outer opening portion 77 that is formed to a shape with ends. Also, the inner covering portion 31 may have at least one inner opening portion 76 while the outer covering portion 32 does not have the outer opening portion 77. Also, the outer covering portion 32 may have at least one outer opening portion 77 while the inner covering portion 31 does not have the inner opening portion 76.

FIG. 5E is a plan view corresponding to FIG. 2 of the internal structure of the SiC semiconductor device 1 shown together with the second inorganic insulating film 30 according to a sixth configuration example. In the following, structures corresponding to the structures shown in FIG. 1 to FIG. 4 are provided with the same reference symbols and description thereof is omitted.

Referring to FIG. 5E, the inner covering portion 31 of the second inorganic insulating film 30 is formed on the first main surface electrode 20 such as to expose corner portions (four corners) of the first main surface electrode 20. Specifically, the inner covering portion 31 has a form where corner portions (four corners) of the inner covering portion 31 according to the first configuration example (see FIG. 2) are eliminated and exposes the corner portions (four corners) of the first main surface electrode 20. That is, the inner covering portion 31 includes a plurality of inner segment portions 78 that are formed at intervals on the first main surface electrode 20. The respective inner segment portions 78 are formed in a one-to-one correspondence relationship with respect to respective sides of the electrode side wall 21 and extend as bands along the respective sides of the electrode side wall 21.

The outer covering portion 32 of the second inorganic insulating film 30 is formed on the first inorganic insulating film 10 such as to expose portions of the first inorganic insulating film 10 along the corner portions of the first main surface electrode 20. Specifically, the outer covering portion 32 has a form where corner portions (four corners) of the outer covering portion 32 according to the first configuration example (see FIG. 2) are eliminated and exposes the portions of the first inorganic insulating film 10 along the corner portions (four corners) of the first main surface electrode 20. That is, the outer covering portion 32 includes a plurality of outer segment portions 79 that are formed on the first inorganic insulating film 10. The respective outer segment portions 79 are formed in a one-to-one correspondence relationship with respect to the respective sides of the electrode side wall 21 and extend as bands along the respective sides of the electrode side wall 21.

The organic insulating film 50 covers the plurality of inner segment portions 78 of the inner covering portion 31 on the first main surface electrode 20. Also, the organic insulating film 50 covers the corner portions (four corners) of the first main surface electrode 20. The organic insulating film 50 covers the plurality of outer segment portions 79 of the outer covering portion 32 on the first inorganic insulating film 10. Also, the organic insulating film 50 covers the portions of the first inorganic insulating film 10 along the corner portions of the first main surface electrode 20.

Even according to such a structure, the contact area of the organic insulating film 50 with respect to the second inorganic insulating film 30 can be increased. Peeling of the organic insulating film 50 from the second inorganic insulating film 30 can thus be suppressed. Stress due to thermal expansion tends to concentrate at the corner portions (four corners) of the first main surface electrode 20. Therefore, by forming the second inorganic insulating film 30 such as to expose the corner portions (four corners) of the first main surface electrode 20, influence of the stress of the first main surface electrode 20 on the second inorganic insulating film 30 can be reduced.

With this embodiment, an example where the inner covering portion 31 has four inner segment portions 78 and the outer covering portion 32 has four outer segment portions 79 was described. However, the inner covering portion 31 may have just one inner segment portion 78 that is formed to a shape with ends. Also, the outer covering portion 32 may have just one outer segment portion 79 that is formed to a shape with ends. Also, the inner covering portion 31 may have at least one inner segment portion 78 while the outer covering portion 32 does not have the outer segment portion 79. Also, the outer covering portion 32 may have at least one outer segment portion 79 while the inner covering portion 31 does not have the inner segment portion 78.

FIG. 5F is a plan view corresponding to FIG. 2 of the internal structure of the SiC semiconductor device 1 shown together with the second inorganic insulating film 30 according to a seventh configuration example. In the following, structures corresponding to the structures shown in FIG. 1 to FIG. 4 are provided with the same reference symbols and description thereof is omitted.

Referring to FIG. 5F, as with the second inorganic insulating film 30 according to the sixth configuration example, the inner covering portion 31 of the second inorganic insulating film 30 includes a plurality of the inner segment portions 78 that expose the corner portions (four corners) of the first main surface electrode 20. In this embodiment, the plurality of inner segment portions 78 are formed in a multiple-to-one correspondence relationship with respect to each side of the electrode side wall 21 and are formed at intervals along each side of the electrode side wall 21. A planar shape of each inner segment portion 78 is arbitrary. Each inner segment portion 78 may be formed to a quadrilateral shape, a polygonal shape, a circular shape, etc., in plan view.

As with the second inorganic insulating film 30 according to the sixth configuration example, the outer covering portion 32 of the second inorganic insulating film 30 includes a plurality of the outer segment portions 79 that expose the portions of the first inorganic insulating film 10 along the corner portions of the first main surface electrode 20. In this embodiment, the plurality of outer segment portions 79 are formed in a multiple-to-one correspondence relationship with respect to each side of the electrode side wall 21 and are formed at intervals along each side of the electrode side wall 21. A planar shape of each outer segment portion 79 is arbitrary. Each outer segment portion 79 may be formed to a quadrilateral shape, a polygonal shape, a circular shape, etc., in plan view.

With this embodiment, an example where the inner covering portion 31 has the plurality of inner segment portions 78 and the outer covering portion 32 has the plurality of outer segment portions 79 was described. However, the inner covering portion 31 may have the plurality of inner segment portions 78 while the outer covering portion 32 does not have the outer segment portion 79. Also, the outer covering portion 32 may have the plurality of outer segment portion 79 while the inner covering portion 31 does not have the inner segment portion 78.

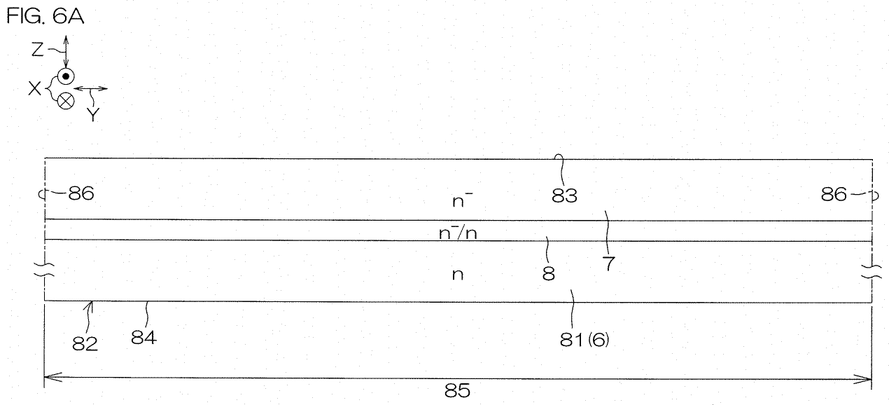

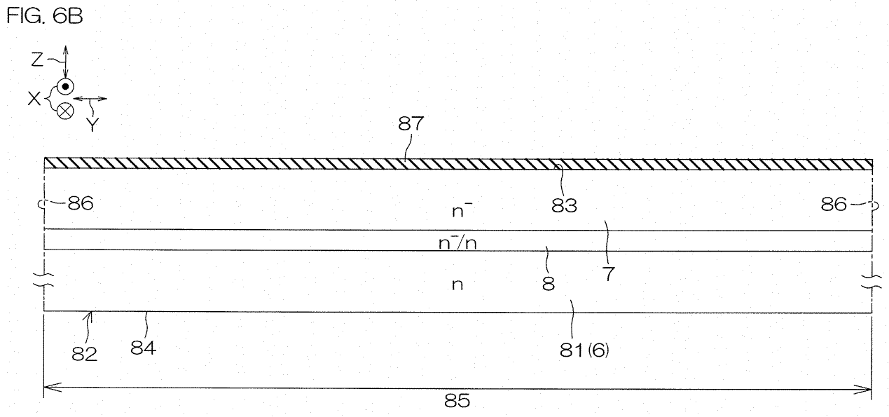

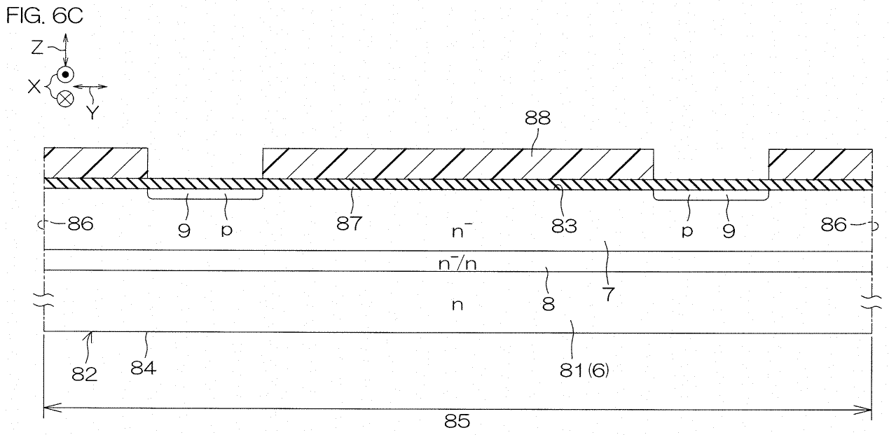

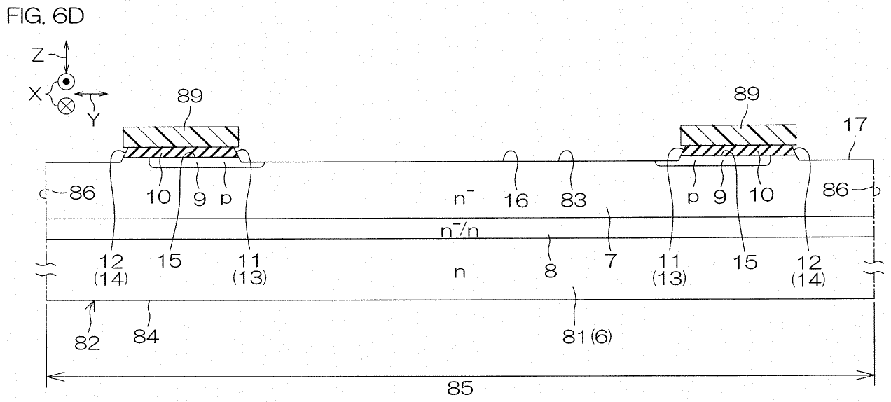

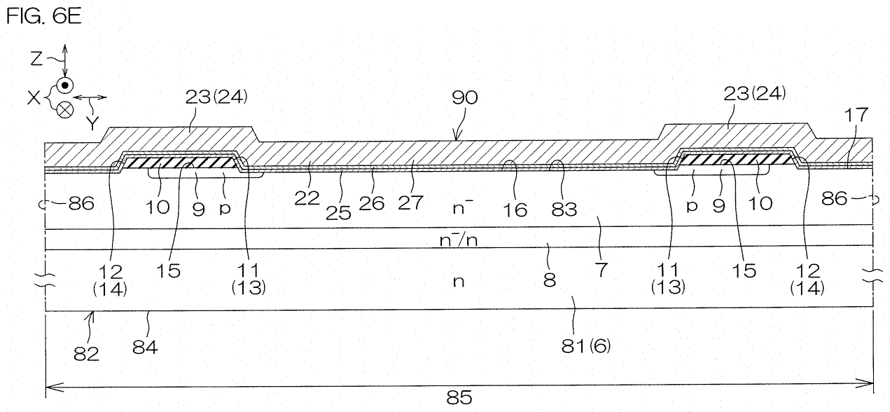

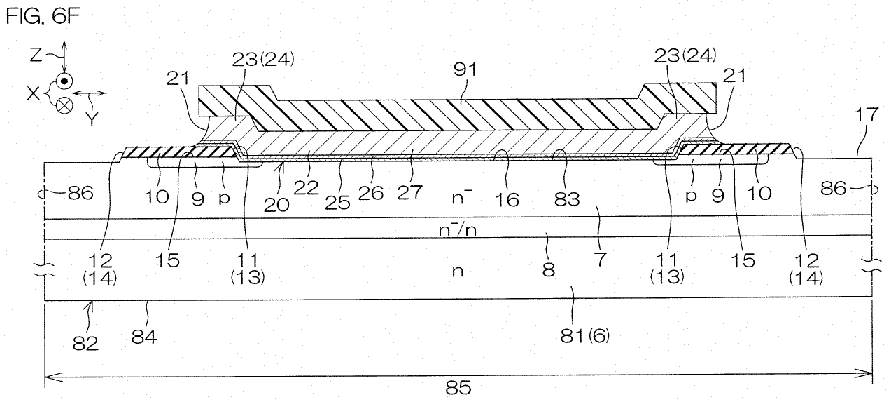

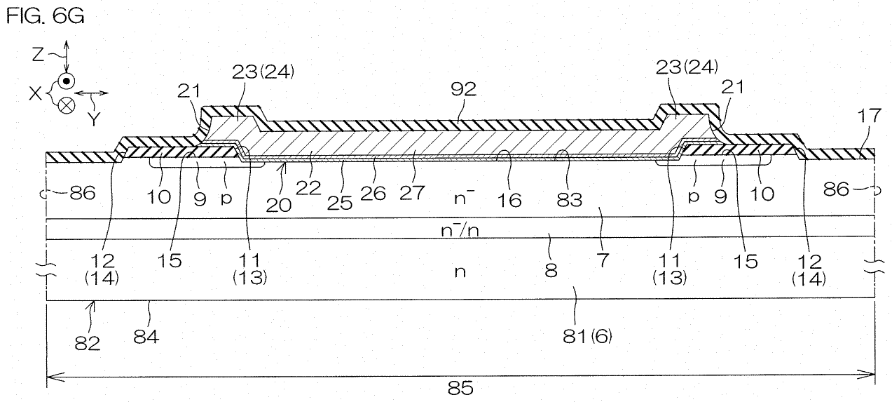

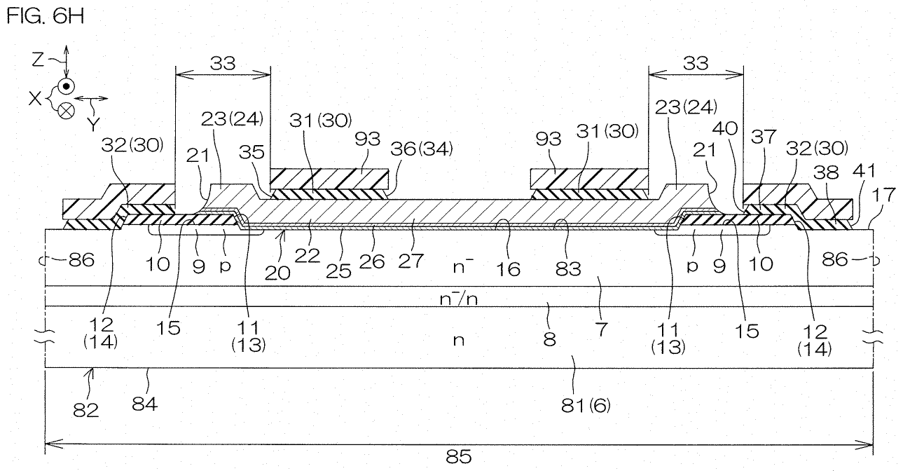

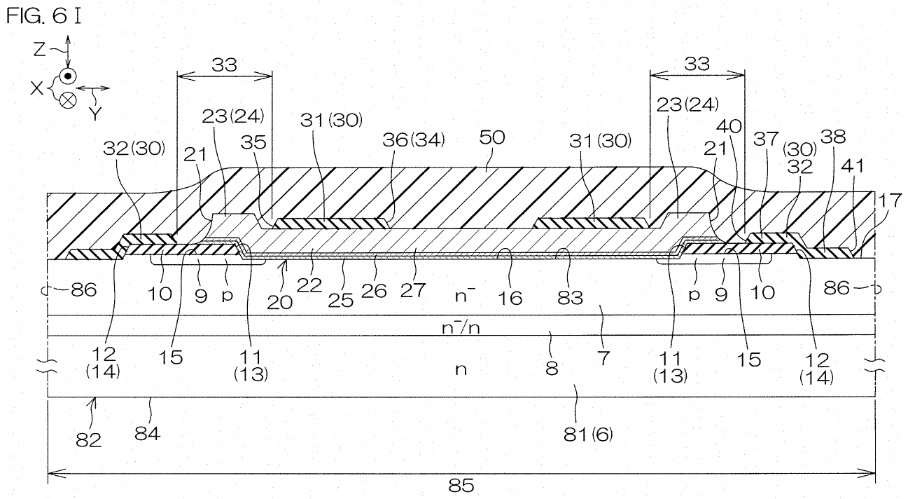

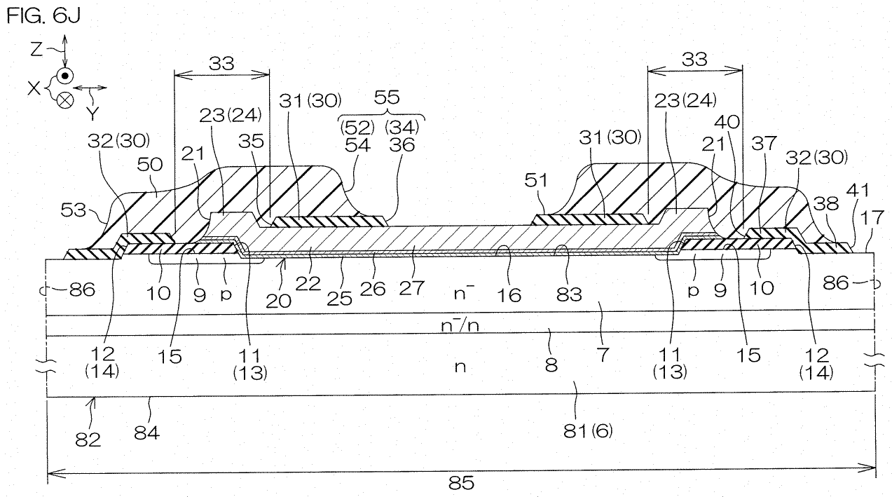

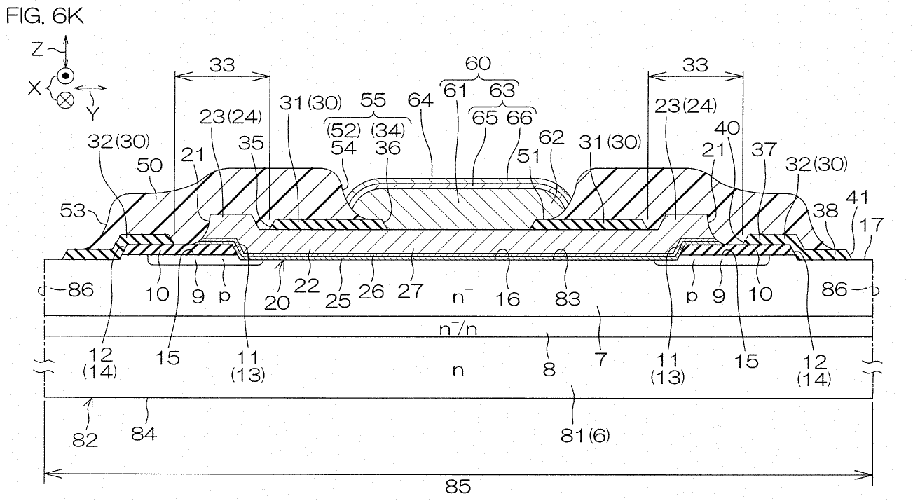

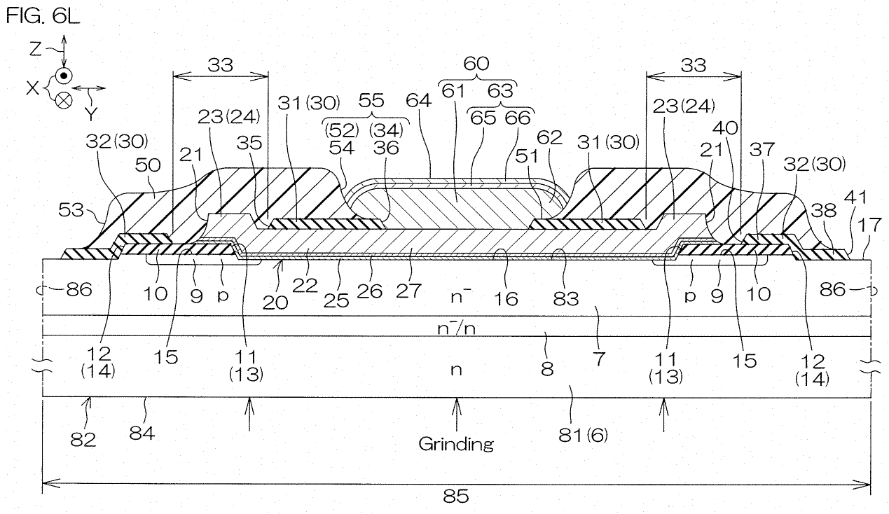

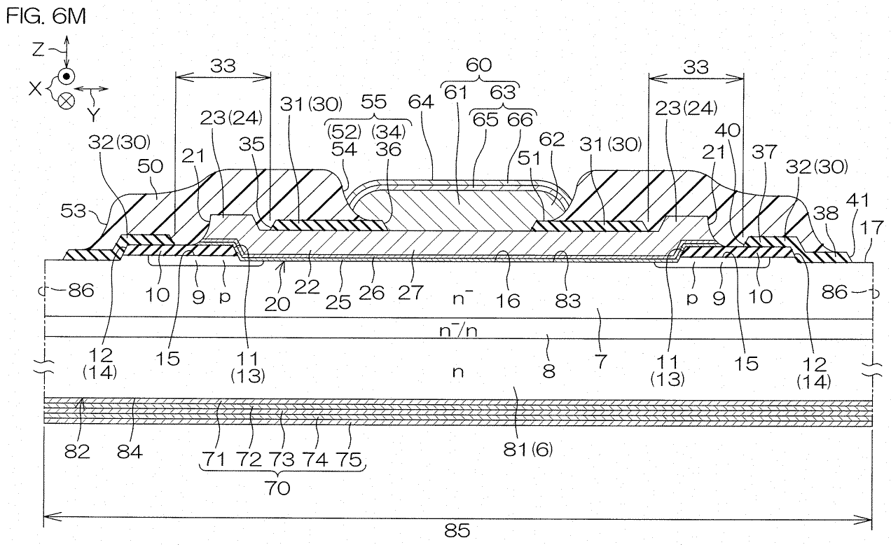

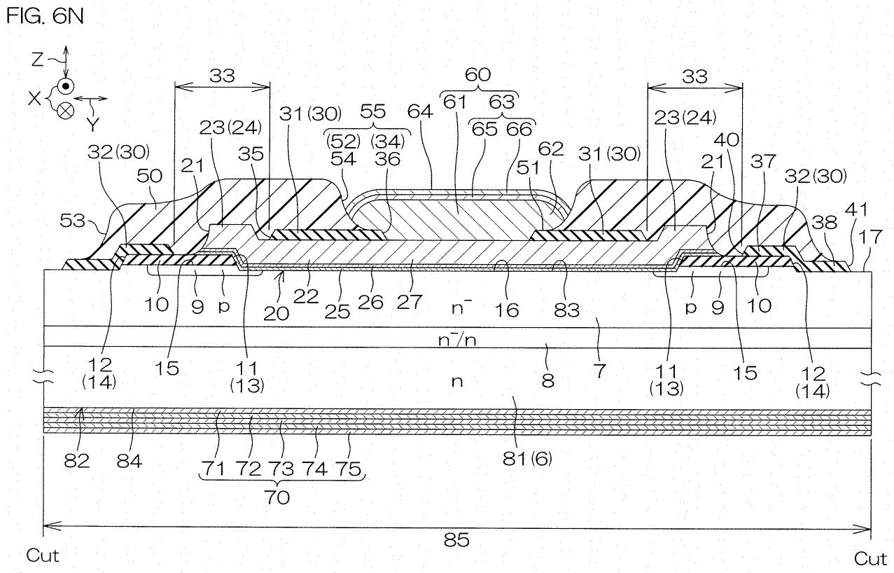

FIG. 6A to FIG. 6N are sectional views for describing an example of a method for manufacturing the SiC semiconductor device 1 shown in FIG. 1.

Referring to FIG. 6A, an SiC wafer 81 (wafer/semiconductor wafer) that is to be a base of the first semiconductor region 6 is prepared. Next, by an epitaxial growth method, crystal growth of a semiconductor crystal (SiC in this embodiment) is performed from one surface of the SiC wafer 81. The third semiconductor region 8 having a predetermined n-type impurity concentration and the second semiconductor region 7 having a predetermined n-type impurity concentration are thereby formed in that order on the SiC wafer 81. In this embodiment, the third semiconductor region 8 and the second semiconductor region 7 are each constituted of an SiC epitaxial layer.

In the following, a wafer structure that includes the first semiconductor region 6 (SiC wafer 81), the third semiconductor region 8, and the second semiconductor region 7 shall be referred to as an SiC epi-wafer 82. The SiC epi-wafer 82 has a first wafer main surface 83 at one side and a second wafer main surface 84 at another side. The first wafer main surface 83 and the second wafer main surface 84 respectively correspond to the first main surface 3 and the second main surface 4 of the SiC chip 2.

Next, a plurality of device regions 85 and intended cutting lines 86 that demarcate the plurality of device regions 85 are set to the first wafer main surface 83. The plurality of device regions 85 are, for example, set in a matrix at intervals in the first direction X and the second direction Y in plan view. The intended cutting lines 86 are set in a lattice in accordance with the array of plurality of device regions 85 in plan view. In FIG. 6A, a single device region 85 is shown and the intended cutting lines 86 are indicated by alternate long and short dashed lines (the same applies to FIG. 6B to FIG. 6N).

Next, referring to FIG. 6B, a first base insulating film 87 that is to be a base of the first inorganic insulating film 10 is formed on the first wafer main surface 83. In this embodiment, the first base insulating film 87 is constituted of a silicon oxide film. The first base insulating film 87 may be formed by a CVD (chemical vapor deposition) method and/or a thermal oxidation treatment method. In this embodiment, the first base insulating film 87 is formed by the thermal oxidation method.

That is, the first base insulating film 87 is constituted of a field oxide film that includes an oxide of the SiC epi-wafer 82 (specifically, the second semiconductor region 7). The first base insulating film 87 grows while absorbing the n-type impurity in a vicinity of the first wafer main surface 83. The first base insulating film 87 thus includes the n-type impurity of the second semiconductor region 7.

Next, referring to FIG. 6C, a first resist mask 88 having a predetermined pattern is formed on the first base insulating film 87. The first resist mask 88 has an opening that exposes a region of the first wafer main surface 83 in which the guard region 9 is to be formed. Next, the p-type impurity is introduced into a surface layer portion of the first wafer main surface 83 by an ion implantation method via the first resist mask 88. The p-type impurity is introduced into the surface layer portion of the first wafer main surface 83 via the first base insulating film 87. The guard region 9 is thereby formed. After the guard region 9 is formed, the first resist mask 88 is removed.

Next, referring to FIG. 6D, a second resist mask 89 having a predetermined pattern is formed on the first base insulating film 87. The second resist mask 89 covers a region of the first base insulating film 87 in which the first inorganic insulating film 10 is to be formed and has an opening that exposes other regions. Next, unnecessary portions of the first base insulating film 87 are removed by an etching method via the second resist mask 89.

The etching method may be a wet etching method and/or a dry etching method. The first base insulating film 87 is removed until the first wafer main surface 83 is exposed. The first inorganic insulating film 10 that has the contact opening 13 and the notch opening 14 and demarcates the hidden surface 15, the active surface 16, and the outer surface 17 in the first wafer main surface 83 is thereby formed.

In this step, portions of the first wafer main surface 83 that are exposed from the first inorganic insulating film 10 are also removed partially. That is, the surface layer portion of the active surface 16 and the surface layer portion of the outer surface 17 are removed partially. The etching method may be a wet etching method and/or a dry etching method. The active surface 16 and the outer surface 17 that are depressed toward the bottom portion side of the second semiconductor region 7 with respect to the hidden surface 15 are thereby formed.

Next, referring to FIG. 6E, a base electrode film 90 that is to be a base of the first main surface electrode 20 is formed on the first wafer main surface 83. The base electrode film 90 is formed on the first wafer main surface 83 such as to cover an entire area of the first inorganic insulating film 10. The base electrode film 90 forms a Schottky junction with the active surface 16 that is exposed from the contact opening 13.

The base electrode film 90 has a laminated structure that includes the first electrode film 25, the second electrode film 26, and the third electrode film 27 that are laminated in that order from the first wafer main surface 83 side. The first electrode film 25 is formed of any of various metals that forms a Schottky junction with the first wafer main surface 83. In this embodiment, the first electrode film 25 is constituted of a titanium film. The second electrode film 26 is constituted of a Ti-based metal film (a titanium nitride film in this embodiment).

The third electrode film 27 is constituted of a Cu-based metal film or an Al-based metal film (an AlCu alloy film in this embodiment). The first electrode film 25, the second electrode film 26, and the third electrode film 27 may be formed by at least one method among a sputtering method, a vapor deposition method, and a plating method. In this embodiment, the first electrode film 25, the second electrode film 26, and the third electrode film 27 are respectively formed by the sputtering method.

Next, referring to FIG. 6F, a third resist mask 91 having a predetermined pattern is formed on the base electrode film 90. The third resist mask 91 covers a region of the base electrode film 90 in which the first main surface electrode 20 is to be formed and has an opening that exposes other regions. Next, unnecessary portions of the base electrode film 90 are removed by an etching method via the third resist mask 91. The etching method may be a wet etching method and/or a dry etching method. The first main surface electrode 20 is thereby formed. After the first main surface electrode 20 is formed, the third resist mask 91 is removed.

Next, referring to FIG. 6G, a second base insulating film 92 that is to be a base of the second inorganic insulating film 30 is formed on the first wafer main surface 83 such as to cover the first inorganic insulating film 10 and the first main surface electrode 20. In this embodiment, the second base insulating film 92 is constituted of a silicon nitride film. The second base insulating film 92 may be formed by a CVD method.

Next, referring to FIG. 6H, a fourth resist mask 93 having a predetermined pattern is formed on the second base insulating film 92. The fourth resist mask 93 covers regions of the second base insulating film 92 in which the second inorganic insulating film 30 is to be formed and has an opening that exposes other regions. Specifically, the fourth resist mask 93 covers portions of the second base insulating film 92 that are to become the inner covering portion 31 and the outer covering portion 32 of the second inorganic insulating film 30 and exposes portions of the second base insulating film 92 that are to become the removed portion 33 of the second inorganic insulating film 30 and the dicing street 39.

Next, unnecessary portions of the second base insulating film 92 are removed by an etching method via the fourth resist mask 93. The etching method may be a wet etching method and/or a dry etching method. The second inorganic insulating film 30 having the inner covering portion 31, the outer covering portion 32, and the removed portion 33 is thereby formed. The outer covering portion 32 of the second inorganic insulating film 30 demarcates the dicing street 39 that exposes the intended cutting lines 86 on the first wafer main surface 83. After the second inorganic insulating film 30 is formed, the fourth resist mask 93 is removed.

Next, referring to FIG. 6I, the organic insulating film 50 is formed on the first wafer main surface 83 such as to cover the first main surface electrode 20, the first inorganic insulating film 10, and the second inorganic insulating film 30. The organic insulating film 50 is formed by coating a photosensitive resin on the first wafer main surface 83. In this embodiment, the organic insulating film 50 is constituted of a polyimide film.

Next, referring to FIG. 6J, the organic insulating film 50 is exposed using a pattern corresponding to the second opening 54 and the dicing street 39 and thereafter developed. The second opening 54 that exposes the first main surface electrode 20 and the dicing street 39 that extends in a lattice along the intended cutting lines 86 are thereby formed in the organic insulating film 50.

Next, referring to FIG. 6K, the pad electrode 60 is formed on a portion of the first main surface electrode 20 that is exposed from the first opening 36 and the second opening 54. In this embodiment, the pad electrode 60 includes the Ni plating film 61, the Pd plating film 65, and the Au plating film 66 that are laminated in that order from the first main surface electrode 20 side. The Ni plating film 61, the Pd plating film 65, and the Au plating film 66 are respectively formed by an electroplating method or an electroless plating method (by an electroless plating method in this embodiment).

Next, referring to FIG. 6L, the SiC epi-wafer 82 is thinned to a desired thickness by performing grinding on the second wafer main surface 84. The grinding step may also be performed by a CMP (chemical mechanical polishing) method. Grinding marks are thereby formed in the second wafer main surface 84. The grinding step of the second wafer main surface 84 does not necessarily have to be performed and may be omitted as needed.

However, thinning of the first semiconductor region 6 is effective for reducing a resistance value of the SiC chip 2. After the grinding step of the second wafer main surface 84, an annealing treatment may be performed to the second wafer main surface 84. The annealing treatment may be performed by a laser irradiation method. The second wafer main surface 84 (second main surface 4) is thereby made an ohmic surface that has grinding marks and laser irradiation marks.

Next, referring to FIG. 6M, the second main surface electrode 70 is formed on the second wafer main surface 84. The second main surface electrode 70 forms an ohmic contact with the second wafer main surface 84. The second main surface electrode 70 has the laminated structure that includes the Ti film 71, the Ni film 72, the Pd film 73, the Au film 74, and the Ag film 75 that are laminated in that order from the second wafer main surface 84 side. The Ti film 71, the Ni film 72, the Pd film 73, the Au film 74, and the Ag film 75 may be formed by at least one method among a sputtering method, a vapor deposition method, and a plating method (by the sputtering method in this embodiment).

Next, referring to FIG. 6N, the SiC epi-wafer 82 is cut along the intended cutting lines 86. The cutting step of the SiC epi-wafer 82 may include a dicing step using a dicing blade. In this case, the SiC epi-wafer 82 is cut along the intended cutting lines 86 demarcated by the dicing street 39. The dicing blade preferably has a blade width less than the width of the dicing street 39. The first inorganic insulating film 10, the second inorganic insulating film 30, and the organic insulating film 50 are not positioned on the intended cutting lines 86 and thereby avoid the dicing by the dicing blade.

The cutting step of the SiC epi-wafer 82 may include a cleaving step using a laser irradiation method. In this case, laser light is irradiated from a laser light irradiating apparatus (not shown) into an interior of the SiC epi-wafer 82 via the dicing street 39. The laser light is preferably irradiated in pulses into the interior of the SiC epi-wafer 82 from the first wafer main surface 83 side that does not have the second main surface electrode 70. A light converging portion (focal point) of the laser light is set in the interior (thickness direction intermediate portion) of the SiC epi-wafer 82 and an irradiation position of the laser light is moved along the dicing street 39 (specifically, the intended cutting lines 86).

The modified layer extending in a lattice along the dicing street 39 in plan view is thereby formed in the interior of the SiC epi-wafer 82. The modified layer is preferably formed at an interval from the first wafer main surface 83 in the interior of the SiC epi-wafer 82. The modified layer is preferably formed in a portion of the interior of the SiC epi-wafer 82 that is constituted of the first semiconductor region 6 (SiC wafer 81). The modified layer is especially preferably formed in the first semiconductor region 6 (SiC wafer 81) at an interval from the second semiconductor region 7 (SiC epitaxial layer). The modified layer is most preferably not formed in the second semiconductor region 7 (SiC epitaxial layer).

After the step of forming the modified layer, an external force is applied to the SiC epi-wafer 82 and the SiC epi-wafer 82 is cleaved with the modified layer as a starting point. The external force is preferably applied to the SiC epi-wafer 82 from the second wafer main surface 84 side. The second main surface electrode 70 is cleaved at the same time as the cleaving of the SiC epi-wafer 82. The first inorganic insulating film 10, the second inorganic insulating film 30, and the organic insulating film 50 are not positioned on the intended cutting lines 86 and thereby avoid the cleaving. The SiC semiconductor device 1 is manufactured through steps including the above.

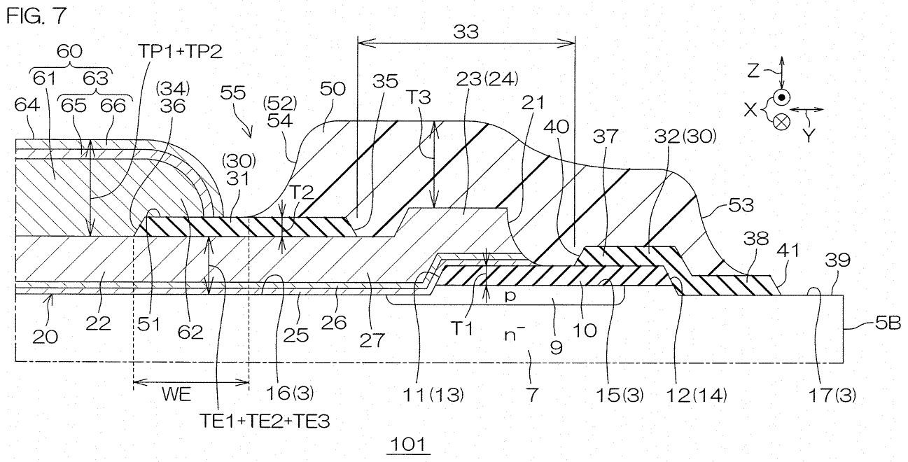

FIG. 7 is a sectional view corresponding to FIG. 4 for describing an SiC semiconductor device 101 according to a second preferred embodiment of the present invention. In the following, structures corresponding to the structures described for the SiC semiconductor device 1 are provided with the same reference symbols and description thereof is omitted.

Referring to FIG. 7, with the SiC semiconductor device 101 according to the second preferred embodiment, the plating covering portion 62 of the Ni plating film 61 covers the edge portion 51 of the inner covering portion 31 at an interval from the third inner wall portion 52 of the organic insulating film 50. The plating covering portion 62 exposes a portion of the edge portion 51 and an entire area of the third inner wall portion 52. On the edge portion 51, the plating covering portion 62 is formed to an arcuate shape directed toward the third inner wall portion 52 with the first inner wall portion 34 as a starting point.

In this embodiment, the first plating thickness TP1 of the Ni plating film 61 is less than the sum of the second insulating thickness T2 of the second inorganic insulating film 30 and the exposed width WE of the second inorganic insulating film 30 (=T2+WE) (T2+WE>TP1). This is one condition for the Ni plating film 61 not to be in contact with the third inner wall portion 52. On the other hand, in this embodiment, the outer plating film 63 covers the edge portion 51 at an interval from the third inner wall portion 52 inside the second opening 54. The outer plating film 63 exposes a portion of the edge portion 51 and the entire area of the third inner wall portion 52.

Even with the SiC semiconductor device 101 described above, the same effects as the effects described for the SiC semiconductor device 1 are exhibited. With this embodiment, an example where the outer plating film 63 that exposes the entire area of the third inner wall portion 52 is formed was described. However, the outer plating film 63 that covers a portion of the third inner wall portion 52 may be formed instead. In this case, either or both of the Pd plating film 65 and the Au plating film 66 may cover a portion of the third inner wall portion 52.

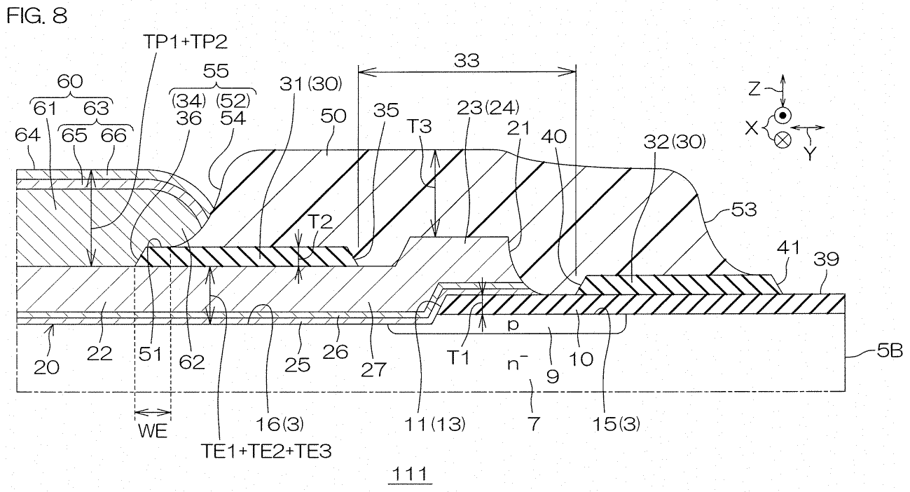

FIG. 8 is a sectional view corresponding to FIG. 4 for describing an SiC semiconductor device 111 according to a third preferred embodiment of the present invention. In the following, structures corresponding to the structures described for the SiC semiconductor device 1 are provided with the same reference symbols and description thereof is omitted.

Referring to FIG. 8, with the SiC semiconductor device 111 according to the third preferred embodiment, the first inorganic insulating film 10 is continuous to the peripheral edge of the first main surface 3 (first to fourth side surfaces 5A to 5D). The first inorganic insulating film 10 thus does not demarcate the outer surface 17 in the first main surface 3. The first inorganic insulating film 10 demarcates just the hidden surface 15 and the active surface 16 in the first main surface 3. In the second inorganic insulating film 30, an entirety of the outer covering portion 32 is formed on the first inorganic insulating film 10.

In this embodiment, the second outer wall portion 41 of the outer covering portion 32 is formed in a region between the outer edge portion of the guard region 9 and the peripheral edge of the first main surface 3 in plan view and exposes a peripheral edge portion of the first inorganic insulating film 10. Thereby, outer covering portion 32 faces the second semiconductor region 7 and the guard region 9 across the first inorganic insulating film 10. Together with the peripheral edge of the first main surface 3, the second outer wall portion 41 demarcates the dicing street 39 that exposes the peripheral edge portion of the first inorganic insulating film 10.

Even with the SiC semiconductor device 111 described above, the same effects as the effects described for the SiC semiconductor device 1 are exhibited.

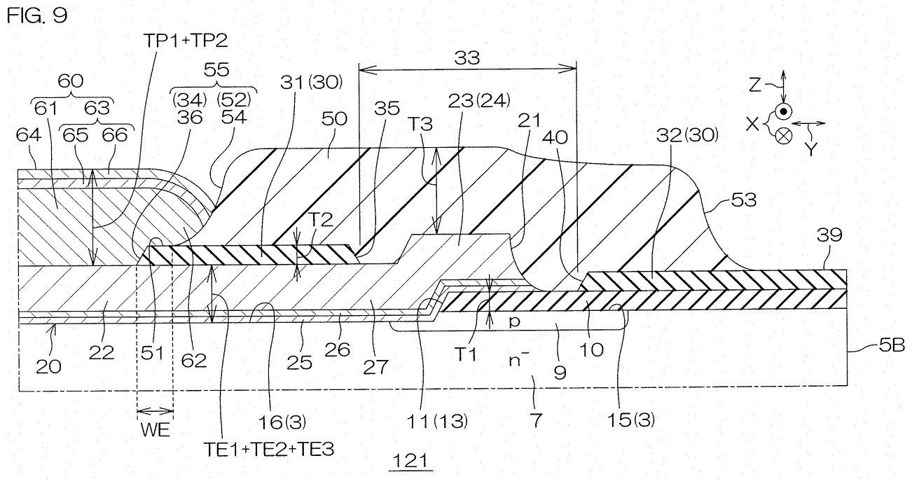

FIG. 9 is a sectional view corresponding to FIG. 4 for describing an SiC semiconductor device 121 according to a fourth preferred embodiment of the present invention. In the following, structures corresponding to the structures described for the SiC semiconductor device 1 are provided with the same reference symbols and description thereof is omitted.

Referring to FIG. 9, with the SiC semiconductor device 121 according to the fourth preferred embodiment, the first inorganic insulating film 10 is continuous to the peripheral edge of the first main surface 3 (first to fourth side surfaces 5A to 5D). The first inorganic insulating film 10 thus does not demarcate the outer surface 17 in the first main surface 3. The first inorganic insulating film 10 demarcates just the hidden surface 15 and the active surface 16 in the first main surface 3.

The second inorganic insulating film 30 is formed on the first inorganic insulating film 10 such as to be continuous to the peripheral edge of the first main surface 3 (first to fourth side surfaces 5A to 5D). Therefore, in this embodiment, the second inorganic insulating film 30 does not demarcate the dicing street 39 together with the peripheral edge of the first main surface 3. In this embodiment, the organic insulating film 50 (third outer wall portion 53) is formed at an interval inward from the peripheral edge of the first main surface 3 in plan view and demarcates the dicing street 39 from which the second inorganic insulating film 30 is exposed.

Even with the SiC semiconductor device 121 described above, the same effects as the effects described for the SiC semiconductor device 1 are exhibited.

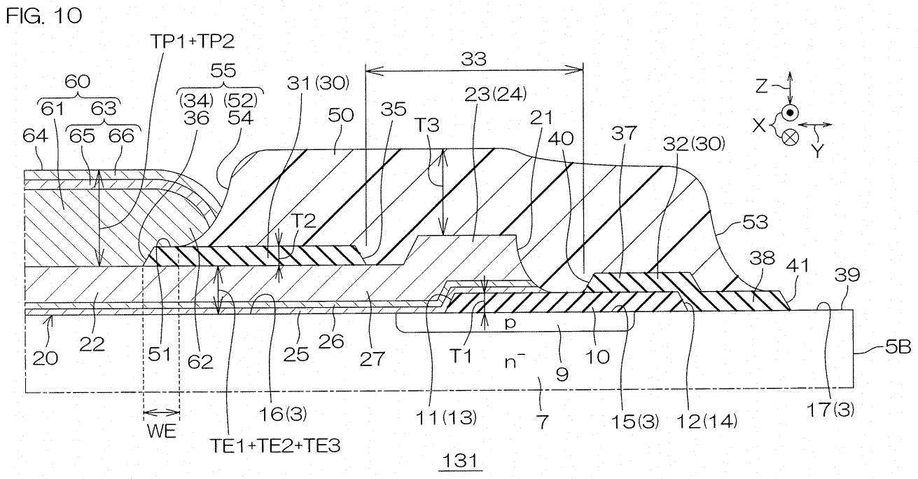

FIG. 10 is a sectional view corresponding to FIG. 4 for describing an SiC semiconductor device 131 according to a fifth preferred embodiment of the present invention. In the following, structures corresponding to the structures described for the SiC semiconductor device 1 are provided with the same reference symbols and description thereof is omitted.

Referring to FIG. 10, with the SiC semiconductor device 131 according to the fifth preferred embodiment, the active surface 16 and the outer surface 17 are positioned on substantially the same plane as the hidden surface 15. The hidden surface 15, the active surface 16, and the outer surface 17 having such a configuration are, for example, formed by forming the first base insulating film 87 by a CVD method in the forming step of the first base insulating film 87 described above (see FIG. 6B). In this case, oxidation of the first wafer main surface 83 is suppressed and therefore, the first wafer main surface 83 can be suppressed from being removed partially in the removing step of the first base insulating film 87 described above (see FIG. 6D).

Even with the SiC semiconductor device 131 described above, the same effects as the effects described for the SiC semiconductor device 1 are exhibited. The configuration where the active surface 16 and the outer surface 17 are positioned on substantially the same plane as the hidden surface 15 can also be applied to the second to fourth preferred embodiments besides the first preferred embodiment.

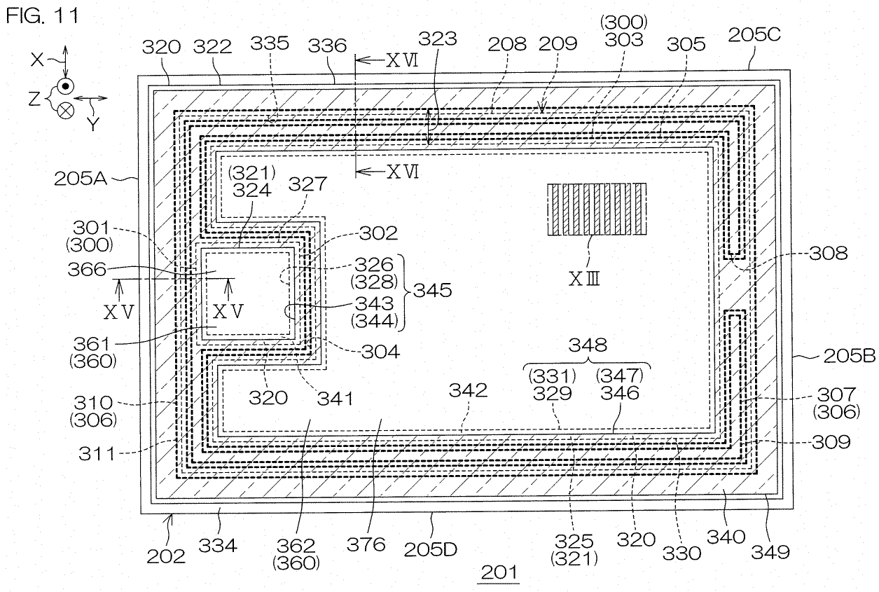

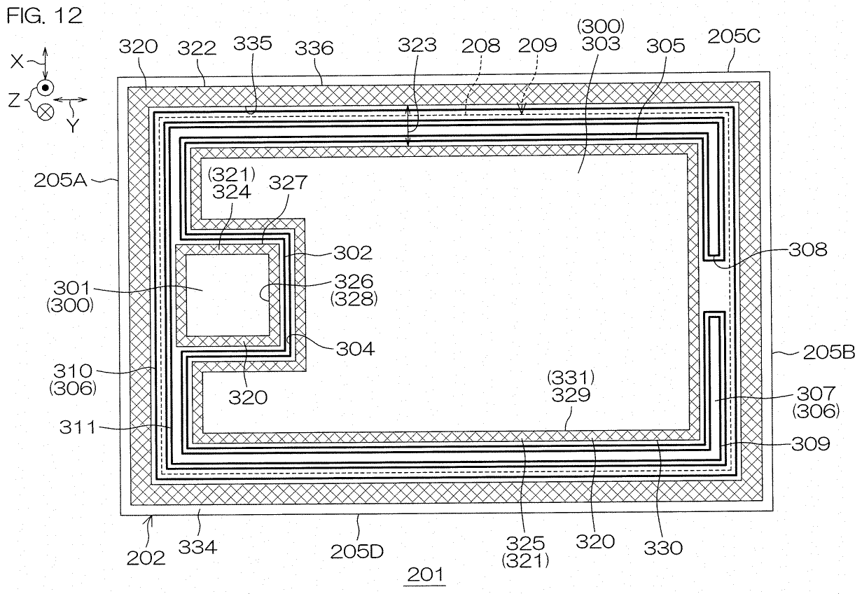

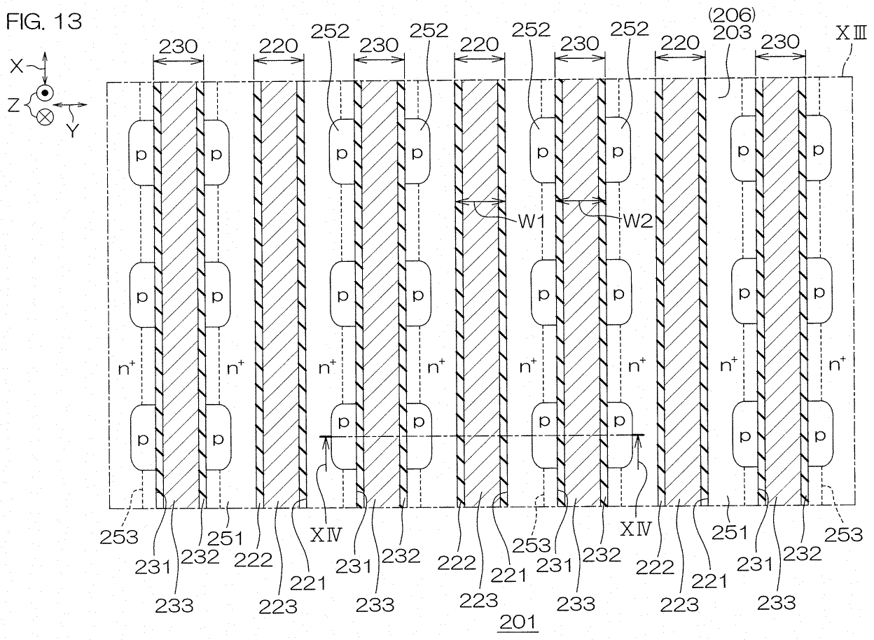

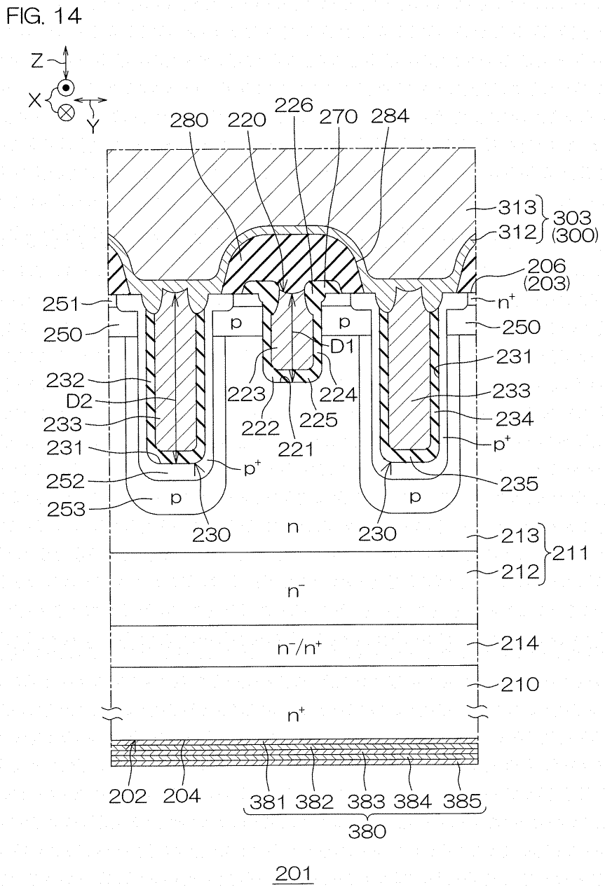

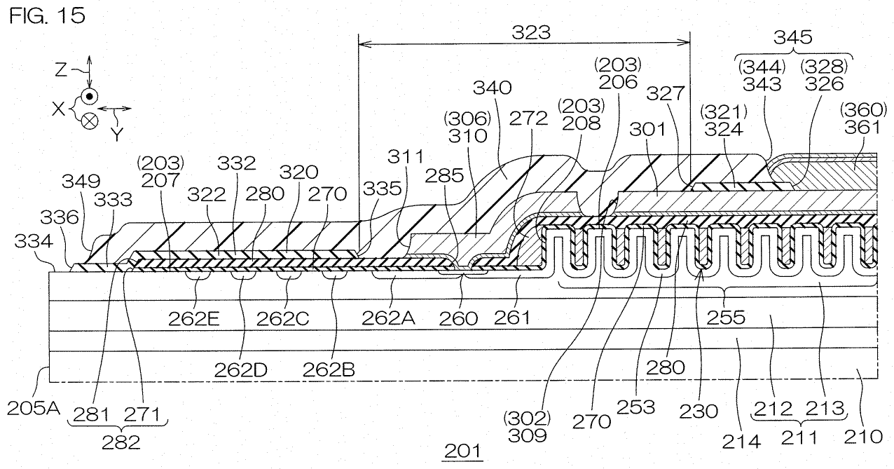

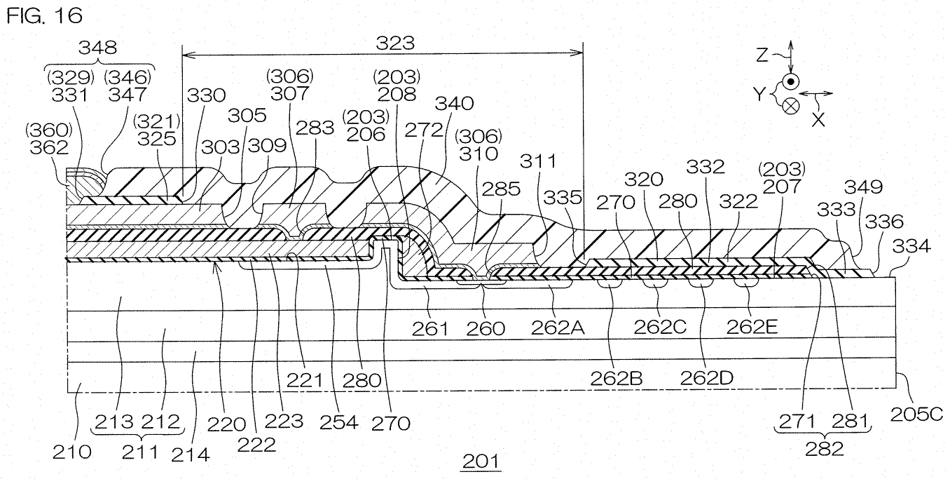

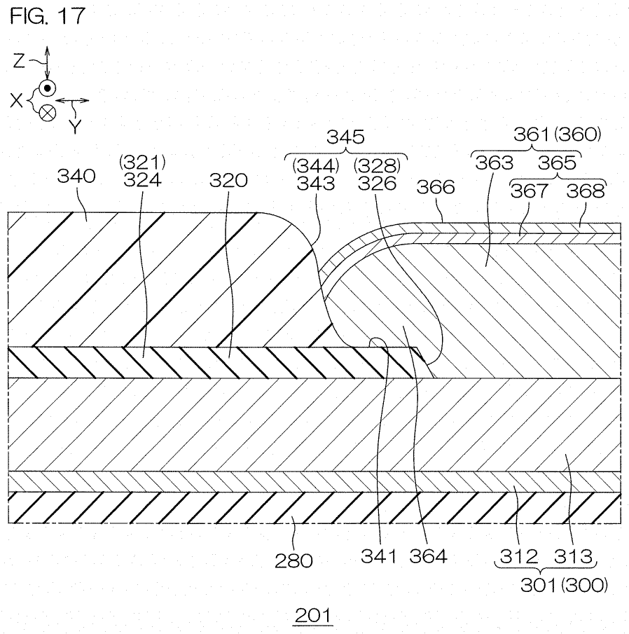

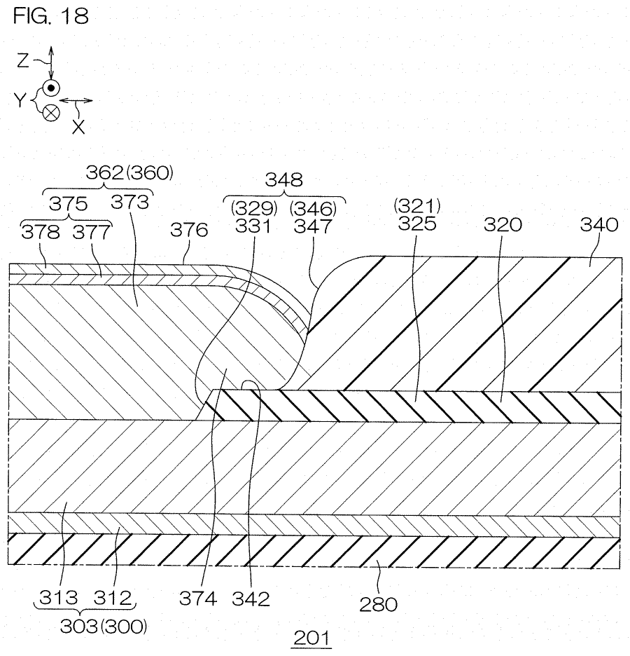

FIG. 11 is a plain view of an SiC semiconductor device 201 according to a sixth preferred embodiment of the present invention. FIG. 12 is a plan view of the internal structure of the SiC semiconductor device 201 shown in FIG. 11 and shown together with a second inorganic insulating film 320 according to a first configuration example. FIG. 13 is an enlarged view of a region XIII shown in FIG. 11. FIG. 14 is a sectional view taken along line XIV-XIV shown in FIG. 13. FIG. 15 is a sectional view taken along line XV-XV shown in FIG. 11. FIG. 16 is a sectional view taken along line XVI-XVI shown in FIG. 11. FIG. 17 is an enlarged sectional view of a principal portion of the structure shown in FIG. 15. FIG. 18 is an enlarged sectional view of a principal portion of the structure shown in FIG. 16.

Referring to FIG. 11 to FIG. 18, in this embodiment, the SiC semiconductor device 201 is an electronic component that includes an SiC chip 202 (chip/semiconductor chip) constituted of an SiC monocrystal that is a hexagonal crystal. Also, in this embodiment, the SiC semiconductor device 201 is a semiconductor switching device that includes an SiC-MISFET (metal insulator semiconductor field effect transistor). The SiC monocrystal that is a hexagonal crystal has a plurality of polytypes including a 2H (hexagonal)-SiC monocrystal, a 4H-SiC monocrystal, a 6H-SiC monocrystal, etc. Although with this embodiment, an example where the SiC chip 202 is constituted of a 4H-SiC monocrystal is illustrated, this does not exclude other polytypes.

The SiC chip 202 is formed to a rectangular parallelepiped shape. The SiC chip 202 has a first main surface 203 at one side, a second main surface 204 at another side, and first to fourth side surfaces 205A to 205D connecting the first main surface 203 and the second main surface 204. The first main surface 203 is a device surface on which a functional device is formed. The second main surface 204 is a non-device surface on which a functional device is not formed. The first main surface 203 and the second main surface 204 are formed to quadrilateral shapes (specifically, rectangular shapes) in a plan view as viewed in a normal direction Z thereto (hereinafter referred to simply as “plan view”).

The first main surface 203 and the second main surface 204 are arranged along c-planes of the SiC monocrystal. The c-planes include a silicon plane ((0001) plane) and a carbon plane ((000-1) plane) of the SiC monocrystal. Preferably, the first main surface 203 is arranged along the silicon plane and the second main surface 204 is arranged along the carbon plane. The first main surface 203 and the second main surface 204 may have an off angle inclined at a predetermined angle in an off direction with respect to the c-planes. The off direction is preferably an a-axis direction ([11-20] direction) of the SiC monocrystal. The off angle may exceed 0° and be not more than 10°. The off angle is preferably not less than 5°. The off angle is especially preferably not less than 2° and not more than 4.5°.

The second main surface 204 may be constituted of a rough surface having either or both of grinding marks and annealing marks (specifically, laser irradiation marks). The annealing marks may include amorphized SiC and/or SiC (specifically, Si) that has been silicided (alloyed) with a metal. The second main surface 204 is preferably constituted of an ohmic surface having at least annealing marks.

The first to fourth side surfaces 205A to 205D form a peripheral edge of the first main surface 203 and a peripheral edge of the second main surface 204. The first side surface 205A and the second side surface 205B extend in a first direction X along the first main surface 203 and face each other in a second direction Y intersecting (specifically, orthogonal to) the first direction X. The first side surface 205A and the second side surface 205B form short sides of the SiC chip 202. The third side surface 205C and the fourth side surface 205D extend in the second direction Y and face each other in the first direction X. The third side surface 205C and the fourth side surface 205D form long sides of the SiC chip 202.

In this embodiment, the first direction X is an m-axis direction ([1-100] direction) of the SiC monocrystal and the second direction Y is the a-axis direction of the SiC monocrystal. That is, the first side surface 205A and the second side surface 205B are formed by a-planes of the SiC monocrystal and the third side surface 205C and the fourth side surface 205D are formed by m-planes of the SiC monocrystal.

The first to fourth side surfaces 205A to 205D may each be constituted of aground surface that have grinding marks formed by dicing by a dicing blade or may each be constituted of a cleavage surface that has a modified layer formed by laser light irradiation. Specifically, the modified layer is constituted of a region in which a portion of a crystal structure of the SiC chip 202 has been modified to be of altered property. That is, the modified layer is constituted of a region in which density, refractive index, mechanical strength (crystal strength), or other physical characteristic has been modified to a property differing from that of the SiC chip 202. The modified layer may include at least one layer among a noncrystalline layer (amorphous layer), a melt rehardened layer, a defect layer, a dielectric breakdown layer, or a refractive index change layer.

If the first to fourth side surfaces 205A to 205D are each constituted of a cleavage surface, the first side surface 205A and the second side surface 205B may each form an inclined surface having an inclination angle resulting from the off angle. The inclination angle resulting from the off angle is an angle with respect to the normal direction Z with the normal direction Z being set to 0°. The first side surface 205A and the second side surface 205B may form inclined surfaces that extend along a c-axis direction ([0001] direction) of the SiC monocrystal with respect to the normal direction Z.

The inclination angle resulting from the off angle is substantially equal to the off angle. The inclination angle resulting from the off angle may exceed 0° and be not more than 10° (preferably not less than 2° and not more than 4.5°). The third side surface 205C and the fourth side surface 205D extend along the off direction (a-axis direction) and therefore do not have an inclination angle resulting from the off angle. The third side surface 205C and the fourth side surface 205D extend planarly in the second direction Y (a-axis direction) and the normal direction Z. Specifically, the third side surface 205C and the fourth side surface 205D are formed substantially perpendicular to the first main surface 203 and the second main surface 204.

Referring to FIG. 15 and FIG. 16, in this embodiment, the first main surface 203 has an active surface 206, an outer surface 207, and a boundary side-surface 208. The active surface 206, the outer surface 207, and the boundary side-surface 208 demarcate an active mesa 209 in the first main surface 203.

The active surface 206 is a surface at which the MISFET is formed as an example of a functional device. The active surface 206 is formed at an interval inward from the peripheral edge of the first main surface 203 (first to fourth side surfaces 205A to 205D). Specifically, the active surface 206 is formed to a quadrilateral shape (specifically, a rectangular shape extending in the second direction Y) that has four sides parallel to the peripheral edge of the first main surface 203 in plan view. The active surface 206 has a flat surface that extends in the first direction X and the second direction Y.

The outer surface 207 is positioned outside the active surface 206 and is formed as a band extending along the active surface 206 in plan view. Specifically, the outer surface 207 is formed to an annular shape (specifically, a quadrilateral annular shape) that surrounds the active surface 206 in plan view. The outer surface 207 is depressed in a thickness direction of the SiC chip 202 (toward the second main surface 204 side) with respect to the active surface 206 and is positioned at the second main surface 204 side with respect to the active surface 206.

The outer surface 207 has a flat surface that extends in the first direction X and the second direction Y and is in communication with the peripheral edge of the first main surface 203 (first to fourth side surfaces 205A to 205D). The outer surface 207 extends substantially parallel to the active surface 206. A depth of the outer surface 207 with respect to the active surface 206 in the normal direction Z may be not less than 0.5 μm and not more than 10 μm. The depth of the outer surface 207 is preferably not more than 5 μm.

The boundary side-surface 208 extends in the normal direction Z and connects the active surface 206 and the outer surface 207. The boundary side-surface 208 has a quadrilateral shape (specifically, a rectangular shape) that has four sides parallel to the peripheral edge of the first main surface 203 in plan view. That is, the boundary side-surface 208 is formed by a-planes and m-planes of the SiC polycrystal.

The boundary side-surface 208 may be formed substantially perpendicular to the active surface 206 and the outer surface 207. In this case, the active mesa 209 of a quadrilateral prism shape is demarcated in the first main surface 203 by the active surface 206, the outer surface 207, and the boundary side-surface 208. The boundary side-surface 208 may be inclined obliquely downward from the active surface 206 toward the outer surface 207.

In this case, the active mesa 209 of a truncated quadrilateral pyramid shape is demarcated in the first main surface 203 by the active surface 206, the outer surface 207, and the boundary side-surface 208. An inclination angle of the boundary side-surface 208 may exceed 90° and be not more than 135°. The inclination angle of the boundary side-surface 208 is an angle that the boundary side-surface 208 forms with the active surface 206 inside the SiC chip 202. The inclination angle of the boundary side-surface 208 is preferably not more than 95°.

The SiC semiconductor device 201 includes a first semiconductor region 210 of an n-type (first conductivity type) that is formed in a surface layer portion of the second main surface 204 of the SiC chip 202. The first semiconductor region 210 has an n-type impurity concentration that is substantially fixed in a thickness direction. The n-type impurity concentration of the first semiconductor region 210 may be not less than 1×10¹⁸ cm⁻³ and not more than 1×10²¹ cm⁻³. The first semiconductor region 210 forms a drain of the MISFET. The first semiconductor region 210 may be referred to as a ^{drain} region.

The first semiconductor region 210 is formed in the surface layer portion of the second main surface 204 at an interval toward the second main surface 204 side from the outer surface 207. The first semiconductor region 210 is formed across an entire area of the surface layer portion of the second main surface 204 and is exposed from the second main surface 204 and the first to fourth side surfaces 205A to 205D. That is, the first semiconductor region 210 has the second main surface 204 and portions of the first to fourth side surfaces 205A to 205D.

A thickness of the first semiconductor region 210 may be not less than 5 μm and not more than 300 μm. The thickness of the first semiconductor region 210 is typically not less than 50 μm and not more than 250 μm. The thickness of the first semiconductor region 210 is adjusted by grinding of the second main surface 204. In this embodiment, the first semiconductor region 210 is formed of a semiconductor substrate (SiC substrate) of the n-type.

The SiC semiconductor device 201 includes a second semiconductor region 211 of the n-type that is formed in a surface layer portion of the first main surface 203 of the SiC chip 202. The second semiconductor region 211 has an n-type impurity concentration that is less than the n-type impurity concentration of the first semiconductor region 210. The n-type impurity concentration of the second semiconductor region 211 may be not less than 1×10¹ cm⁻³ and not more than 1×10¹⁸ cm⁻³. The second semiconductor region 211 is electrically connected to the first semiconductor region 210 and forms the drain of the MISFET together with the first semiconductor region 210. The second semiconductor region 211 may be referred to as a drift region.

The second semiconductor region 211 is formed across an entire area of the surface layer portion of the first main surface 203 and is exposed from the first main surface 203 and the first to fourth side surfaces 205A to 205D. Specifically, the second semiconductor region 211 is exposed from the active surface 206, the outer surface 207, and the boundary side-surface 208. That is, the second semiconductor region 211 has the first main surface 203 and portions of the first to fourth side surfaces 205A to 205D. A thickness of the second semiconductor region 211 may be not less than 5 μm and not more than 20 μm. The thickness of the second semiconductor region 211 is a thickness on the basis of the active surface 206. In this embodiment, the second semiconductor region 211 is formed of an epitaxial layer (SiC epitaxial layer) of the n-type.

The second semiconductor region 211 preferably has a concentration gradient with which the n-type impurity concentration increases (specifically, increases gradually) toward the first main surface 203 from the first semiconductor region 210 side. That is, the second semiconductor region 211 preferably has a first concentration region 212 (low concentration region) of comparatively low concentration that is positioned at the first semiconductor region 210 side and a second concentration region 213 (high concentration region) that is positioned at the first main surface 203 side and is of higher concentration than the first concentration region 212.

The first concentration region 212 is positioned at the first semiconductor region 210 side with respect to the outer surface 207. The second concentration region 213 is positioned at the first main surface 203 side with respect to the first concentration region 212 and is exposed from the active surface 206, the outer surface 207, and the boundary side-surface 208. The n-type impurity concentration of the first concentration region 212 may be not less than 1×10¹⁵ cm⁻³ and not more than 1×10¹⁷ cm⁻³. The n-type impurity concentration of the second concentration region 213 may be not less than 1×10¹⁶ cm⁻³ and not more than 1×10¹⁸ cm⁻³.

The SiC semiconductor device 201 includes a third semiconductor region 214 (concentration transition region) of the n-type that is interposed between the first semiconductor region 210 and the second semiconductor region 211 in the SiC chip 202. The third semiconductor region 214 has a concentration gradient with which an n-type impurity concentration decreases (specifically, decreases gradually) from the n-type impurity concentration of the first semiconductor region 210 toward the n-type impurity concentration of the second semiconductor region 211. The third semiconductor region 214 is electrically connected to the first semiconductor region 210 and the second semiconductor region 211 and forms the drain of the MISFET together with the first semiconductor region 210 and the second semiconductor region 211. The third semiconductor region 214 may be referred to as a buffer region.

The third semiconductor region 214 is interposed over an entire area between the first semiconductor region 210 and the second semiconductor region 211 and is exposed from the first to fourth side surfaces 205A to 205D. That is, the third semiconductor region 214 has portions of the first to fourth side surfaces 205A to 205D. A thickness of the third semiconductor region 214 may be not less than 1 μm and not more than 10 μm. In this embodiment, the third semiconductor region 214 is formed of an epitaxial layer (SiC epitaxial layer) of the n-type.

Referring to FIG. 13 and FIG. 14, the SiC semiconductor device 201 includes the MISFET of a trench insulated gate type that is formed in the active surface 206. Specifically, the SiC semiconductor device 201 includes a plurality of first trench structures 220 that are formed in the active surface 206. The first trench structures 220 may be referred to as trench gate structures. The plurality of first trench structures 220 form a gate of the MISFET.

The plurality of first trench structures 220 are formed in the active surface 206 at intervals inward from the boundary side-surface 208. The plurality of first trench structures 220 are respectively formed as bands (rectangular shapes) extending in the first direction X in plan view and are formed at intervals in the second direction Y. The plurality of first trench structures 220 are thereby formed as stripes extending in the first direction X in plan view.

The plurality of first trench structures 220 preferably extend in the first direction X such as to traverse a line passing through a central portion of the active surface 206 in the second direction Y in plan view. A distance between two adjacent first trench structures 220 may be not less than 0.4 μm and not more than 5 μm. The distance between two adjacent first trench structures 220 is preferably not less than 0.8 μm and not more than 3 μm.

Each first trench structure 220 includes aside wall and a bottom wall. Portions of the side wall of each first trench structure 220 that form long sides are formed by a-planes of the SiC monocrystal. Portions of the side wall of each first trench structure 220 that form short sides are formed by m-planes of the SiC monocrystal. The bottom wall of each first trench structure 220 is formed by a c-plane of the SiC monocrystal. The bottom wall of each first trench structure 220 is preferably formed to a shape curved toward the second main surface 204. Obviously, the bottom wall of each first trench structure 220 may have a flat surface parallel to the active surface 206.

Each first trench structure 220 is formed at an interval toward the active surface 206 side from a bottom portion of the second semiconductor region 211 and faces the first semiconductor region 210 (third semiconductor region 214) across a portion of the second semiconductor region 211. That is, the side wall and the bottom wall of each first trench structure 220 are in contact with the second semiconductor region 211. Each first trench structure 220 is formed at an interval toward the active surface 206 side from a bottom portion of the second concentration region 213.

Further, in the normal direction Z, each first trench structure 220 is formed at an interval toward the active surface 206 side from a depth position of the outer surface 207. That is, each first trench structure 220 is formed in the second concentration region 213 and faces the first concentration region 212 across a portion of the second concentration region 213. Each first trench structure 220 may be formed to a vertical shape having a substantially fixed opening width. Each first trench structure 220 may be formed to a convergent shape having an opening width that narrows toward the bottom wall.

Each first trench structure 220 has a first width W1 and a first depth D1. The first width W1 is a width in a direction (that is, the second direction Y) orthogonal to the direction in which each first trench structure 220 extends. The first width W1 may be not less than 0.1 μm and not more than 3 μm. The first width W1 is preferably not less than 0.5 μm and not more than 1.5 μm.

The first depth D1 may be not less than 0.1 μm and not more than 3 μm. The first depth D1 is preferably not less than 0.5 μm and not more than 2 μm. An aspect ratio D1/W1 of each first trench structure 220 is preferably not less than 1 and not more than 5. The aspect ratio D1/W1 is especially preferably not less than 1.5. The aspect ratio D1/W1 is a ratio of the first depth D1 with respect to the first width W1.

The plurality of first trench structures 220 each include a gate trench 221, a gate insulating film 222, and a gate electrode 223. In the following, a single first trench structure 220 shall be described. The gate trench 221 forms the side wall and the bottom wall of the first trench structure 220. The side wall and the bottom wall form a wall surface (inner wall and outer wall) of the gate trench 221.

An opening edge portion of the gate trench 221 is inclined obliquely downward from the active surface 206 toward the gate trench 221. The opening edge portion is a connection portion of the active surface 206 and the side wall of the gate trench 221. In this embodiment, the opening edge portion is formed to a curved shape that is depressed toward the SiC chip 202. The opening edge portion may be formed to a shape that is convexly curved toward the gate trench 221.

The gate insulating film 222 is formed as a film on the inner wall of the gate trench 221 and demarcates a recess space inside the gate trench 221. The gate insulating film 222 includes at least one among a silicon oxide film, a silicon nitride film, and a silicon oxynitride film. In this embodiment, the gate insulating film 222 has a single layer structure constituted of a silicon oxide film.

The gate insulating film 222 includes a first portion 224, a second portion 225, and a third portion 226. The first portion 224 covers the side wall of the gate trench 221. The second portion 225 covers the bottom wall of the gate trench 221. The third portion 226 covers the opening edge portion. In this embodiment, the third portion 226 bulges curvingly into the gate trench 221 at the opening edge portion.

A thickness of the first portion 224 may be not less than 10 nm and not more than 100 nm. The second portion 225 may have a thickness that exceeds the thickness of the first portion 224. The thickness of the second portion 225 may be not less than 50 nm and not more than 200 ran. The third portion 226 has a thickness that exceeds the thickness of the first portion 224. The thickness of the third portion 226 may be not less than 50 nm and not more than 200 nm. Obviously, the gate insulating film 222 having a uniform thickness may be formed instead.

The gate electrode 223 is embedded in the gate trench 221 across the gate insulating film 222. A gate potential is applied to the gate electrode 223. The gate electrode 223 is preferably constituted of a conductive polysilicon. In this embodiment, the gate electrode 223 includes an n-type polysilicon that is doped with an n-type impurity. The gate electrode 223 has an electrode surface that is exposed from the gate trench 221. The electrode surface of the gate electrode 223 is formed to a curved shape that is depressed toward the bottom wall of the gate trench 221 and is narrowed by the third portion 226 of the gate insulating film 222.

The SiC semiconductor device 201 includes a plurality of second trench structures 230 that are formed in the active surface 206. The second trench structures 230 may be referred to as trench source structures. The plurality of second trench structures 230 form withstand voltage reinforcing structures of the MISFET. The plurality of second trench structures 230 are each formed in a region of the active surface 206 between two first trench structures 220 that are adjacent.

The plurality of second trench structures 230 are formed in the active surface 206 at intervals inward from the boundary side-surface 208. In plan view, the plurality of second trench structures 230 are respectively formed as bands extending in the first direction X and are formed at intervals in the second direction Y in a mode of sandwiching a single first trench structure 220. The plurality of second trench structures 230 are thereby formed as stripes extending in the first direction X in plan view.

The plurality of second trench structures 230 preferably extend in the first direction X such as to traverse the line passing through the central portion of the active surface 206 in the second direction Y in plan view. A length in the first direction X of each second trench structure 230 is preferably less than the length in the first direction X of each first trench structure 220. A distance between two adjacent second trench structures 230 may be not less than 0.4 μm and not more than 5 μm. The distance between two adjacent second trench structures 230 is preferably not less than 0.8 μm and not more than 3 μm.

Each second trench structure 230 includes a side wall and a bottom wall. Portions of the sidewall of each second trench structure 230 that form long sides are formed by a-planes of the SiC monocrystal. Portions of the side wall of each second trench structure 230 that form short sides are formed by m-planes of the SiC monocrystal. The bottom wall of each second trench structure 230 is formed by a c-plane of the SiC monocrystal. The bottom wall of each second trench structure 230 is preferably formed to a shape curved toward the second main surface 204. Obviously, the bottom wall of each second trench structure 230 may have a flat surface parallel to the active surface 206.

Each second trench structure 230 is formed at an interval toward the active surface 206 side from the bottom portion of the second semiconductor region 211 and faces the first semiconductor region 210 (third semiconductor region 214) across a portion of the second semiconductor region 211. That is, the side wall and the bottom wall of each second trench structure 230 are in contact with the second semiconductor region 211. Specifically, each second trench structure 230 is formed at an interval toward the active surface 206 side from the bottom portion of the second concentration region 213. That is, each second trench structure 230 is formed in the second concentration region 213 and faces the first concentration region 212 across a portion of the second concentration region 213.

In this embodiment, each second trench structure 230 is formed deeper than each first trench structure 220. That is, the bottom wall of each second trench structure 230 is positioned at the bottom portion side of the second semiconductor region 211 (second concentration region 213) with respect to the bottom wall of each first trench structure 220. Specifically, in the normal direction Z, the bottom wall of each second trench structure 230 is formed at a depth position between the outer surface 207 and the bottom wall of each first trench structure 220.

In this case, the bottom wall of each second trench structure 230 is preferably positioned on substantially the same plane as the outer surface 207. That is, each second trench structure 230 is preferably formed to a depth substantially equal to the outer surface 207. Each second trench structure 230 may be formed to a vertical shape having a substantially fixed opening width. Each second trench structure 230 may be formed to a convergent shape having an opening width that narrows toward the bottom wall.

Each second trench structure 230 has a second width W2 and a second depth D2. The second width W2 is a width in a direction (that is, the second direction Y) orthogonal to the direction in which each second trench structure 230 extends. The second width W2 may be not less than 0.1 μm and not more than 3 μm. The second width W2 is preferably not less than 0.5 μm and not more than 1.5 μm. In this embodiment, the second width W2 is substantially equal to the first width W1 of each first trench structure 220. The second width W2 preferably has a value in a range of within ±10% of the value of the first width W1.

The second depth D2 is preferably not less than 1.5 times and not more than 3 times the first depth D1 of the first trench structure 220. The second depth D2 may be not less than 0.5 μm and not more than 10 μm. The second depth D2 is preferably not more than 5 μm. An aspect ratio D2/W2 of each second trench structure 230 is preferably not less than 1 and not more than 5. The aspect ratio D2/W2 is especially preferably not less than 2. The aspect ratio D2/W2 is a ratio of the second depth D2 with respect to the second width W2.

The plurality of second trench structures 230 each include a source trench 231, a source insulating film 232, and a source electrode 233. In the following, a single second trench structure 230 shall be described. The source trench 231 forms the side wall and the bottom wall of the second trench structure 230. The side wall and the bottom wall form a wall surface (inner wall and outer wall) of the source trench 231.

An opening edge portion of the source trench 231 is inclined obliquely downward from the first main surface 203 toward the source trench 231. The opening edge portion is a connection portion of the first main surface 203 and the side wall of the source trench 231. In this embodiment, the opening edge portion is formed to a curved shape that is depressed toward the SiC chip 202. The opening edge portion may be formed to a shape curved toward an inner side of the source trench 231.

The source insulating film 232 is formed as a film on the inner wall of the source trench 231 and demarcates a recess space inside the source trench 231. The source insulating film 232 includes at least one among a silicon oxide film, a silicon nitride film, and a silicon oxynitride film. In this embodiment, the source insulating film 232 has a single layer structure constituted of a silicon oxide film.

The source insulating film 232 includes a first portion 234 and a second portion 235. The first portion 234 covers the side wall of the source trench 231. The second portion 235 covers the bottom wall of the source trench 231. A thickness of the first portion 234 may be not less than 10 nm and not more than 100 nm. The second portion 235 may have a thickness that exceeds the thickness of the first portion 234. The thickness of the second portion 235 may be not less than 50 nm and not more than 200 nm.

The source electrode 233 is embedded in the source trench 231 across the source insulating film 232. A source potential (for example, a reference potential) is applied to the source electrode 233. The source electrode 233 is preferably constituted of the same material as the gate electrode 223. That is, the source electrode 233 is preferably constituted of a conductive polysilicon. In this embodiment, the source electrode 233 includes an n-type polysilicon that is doped with an n-type impurity.

The source electrode 233 has an electrode surface that is exposed from the source trench 231. The electrode surface of the source electrode 233 is formed to a curved shape that is depressed toward the bottom wall of the source trench 231. A portion of the side wall of the source electrode 233 may be exposed from the source insulating film 232 at the opening end of the source trench 231.

The SiC semiconductor device 201 includes a body region 250 of a p-type that is formed in a surface layer portion of the active surface 206. The body region 250 is formed across an entire area of the surface layer portion of the active surface 206. A p-type impurity concentration of the body region 250 may be not less than 1×10¹⁶ cm⁻³ and not more than 1×10¹⁸ cm⁻³.

The body region 250 is formed at the active surface 206 side with respect to the bottom walls of the first trench structures 220. The body region 250 covers the side walls of the first trench structures 220 and the side walls of the second trench structures 230. The body region 250 faces the gate electrodes 223 across the gate insulating films 222.

The SiC semiconductor device 201 includes a plurality of source regions 251 of the n-type that are each formed in a region of the surface layer portion of the body region 250 between a first trench structure 220 and a second trench structure 230 that are adjacent. Each source region 251 has an n-type impurity concentration that exceeds the n-type impurity concentration of the second semiconductor region 211 (specifically, the second concentration region 213). The n-type impurity concentration of each source region 251 may be not less than 1×10¹⁸ cm⁻³ and not more than 1×10²¹ cm⁻³.

Each source region 251 is formed at the active surface 206 side with respect to a bottom portion of the body region 250. Each source region 251 covers the side wall of the first trench structure 220 and faces the gate electrode 223 and a first low resistance layer 241 across the gate insulating film 222. Inside the body region 250, each source region 251 forms a channel of the MISFET with the second semiconductor region 211 (second concentration region 213).

The SiC semiconductor device 201 includes a plurality of contact regions 252 of the p-type that are formed along the plurality of second trench structures 230 in the surface layer portion of the active surface 206. Each contact region 252 has a p-type impurity concentration that exceeds the p-type impurity concentration of the body region 250. The p-type impurity concentration of each contact region 252 may be not less than 1×10¹⁸ cm⁻³ and not more than 1×10²¹ cm⁻³.

The plurality of contact regions 252 are formed in a multiple-to-one correspondence relationship with respect to each second trench structure 230 in plan view. The plurality of contact regions 252 are formed at intervals along each second trench structure 230 in plan view and partially cover each second trench structure 230. The plurality of contact regions 252 are formed at intervals toward the second trench structure 230 side from the first trench structures 220 and expose the first trench structures 220.

Each contact region 252 is formed at an interval toward the active surface 206 side from the bottom portion of the second semiconductor region 211 (second concentration region 213) and face the first semiconductor region 210 (third semiconductor region 214) across a portion of the second semiconductor region 211. Each contact region 252 covers the side wall and the bottom wall of each second trench structure 230 in the second semiconductor region 211 (second concentration region 213).

The SiC semiconductor device 201 includes a plurality of well regions 253 of the p-type that are formed in the surface layer portion of the active surface 206. Each well region 253 has a p-type impurity concentration that is less than the p-type impurity concentration of each contact region 252. The p-type impurity concentration of each well region 253 preferably exceeds the p-type impurity concentration of the body region 250. The p-type impurity concentration of each well region 253 may be not less than 1×10¹⁶ cm⁻³ and not more than 1×10¹⁸ cm⁻³.

The plurality of well regions 253 are formed in a one-to-one correspondence relationship with respect to each second trench structure 230. Each well region 253 is formed as a band that extends along each second trench structure 230 in plan view. Each contact region 252 is formed at an interval toward the second trench structure 230 side from the first trench structure 220 and expose the first trench structure 220.

Each well region 253 is formed at an interval toward the active surface 206 side from the bottom portion of the second semiconductor region 211 (second concentration region 213) and face the first semiconductor region 210 (third semiconductor region 214) across a portion of the second semiconductor region 211. That is, each well region 253 is electrically connected to the second semiconductor region 211 (second concentration region 213). Each well region 253 covers the side wall and the bottom wall of each second trench structure 230.

The plurality of well regions 253 form pn junction portions with the second semiconductor region 211 (second concentration region 213) and spread depletion layers toward the first trench structures 220 (gate trenches 221). The plurality of well regions 253 make the MISFET of the trench insulated gate type approach the structure of a pn junction diode and relaxes an electric field inside the SiC chip 202.

The plurality of well regions 253 are preferably formed such that the depletion layers overlap with the bottom walls of the first trench structures 220. The second concentration region 213 interposed between the plurality of well regions 253 reduce a JFET (junction field effect transistor) resistance. The second concentration region 213 positioned directly below the plurality of well regions 253 reduce a current spreading resistance. In such a structure, the first concentration region 212 increases a withstand voltage of the SiC chip 202.

The SiC semiconductor device 201 includes a plurality of gate well regions 254 of the p-type that are respectively formed in regions of the surface layer portion of the active surface 206 along the wall surfaces at both end portions of the plurality of first trench structures 220. Each gate well region 254 has a p-type impurity concentration that is less than the p-type impurity concentration of each contact region 252. The p-type impurity concentration of each gate well region 254 preferably exceeds the p-type impurity concentration of the body region 250. The p-type impurity concentration of each gate well region 254 may be not less than 1×10¹⁶ cm⁻³ and not more than 1×10¹⁸ cm⁻³. The p-type impurity concentration of each gate well region 254 is preferably substantially equal to the p-type impurity concentration of each well region 253.

Each gate well region 254 is formed as a band that extends along each first trench structure 220 in plan view. Each gate well region 254 is formed at an interval toward the first trench structure 220 side from the second trench structure 230 and exposes portions of the first trench structure 220 along the source regions 251. Each gate well region 254 covers the side wall and the bottom wall of each first trench structure 220.

Each gate well region 254 is formed at an interval toward the first main surface 3 side from the bottom portion of the second semiconductor region 211 (second concentration region 213) and faces the first semiconductor region 210 (third semiconductor region 214) across a portion of the second semiconductor region 211. In this embodiment, each gate well region 254 is formed in the second concentration region 213 and faces the first concentration region 212 across a portion of the second concentration region 213. Each gate well region 254 is connected to the body region 250 at a portion covering the side wall of each first trench structure 220.

Bottom portions of the plurality of gate well regions 254 are positioned at the bottom wall sides of the first trench structures 220 with respect to bottom portions of the plurality of well regions 253. A thickness of a portion of each gate well region 254 that covers the bottom wall of each first trench structure 220 preferably exceeds a thickness of a portion of each gate well region 254 that covers the side wall of each first trench structure 220. The thickness of the portion of each gate well region 254 that covers the side wall of the first trench structure 220 is a thickness in a normal direction to the side wall of the first trench structure 220. The thickness of the portion of each gate well region 254 that covers the bottom wall of the first trench structure 220 is a thickness in a normal direction to the bottom wall of the first trench structure 220.

Portions of the bottom portions of the plurality of gate well regions 254 that cover the bottom walls of the plurality of first trench structures 220 are formed at a substantially fixed depth. The plurality of gate well regions 254 form pn junction portions with the second semiconductor region 211 (second concentration region 213) and spread depletion layers toward the first trench structures 220 and the second trench structures 230. The plurality of gate well regions 254 make the MISFET of the trench insulated gate type approach the structure of a pn junction diode and relaxes the electric field inside the SiC chip 202.

Referring to FIG. 15 and FIG. 16, the SiC semiconductor device 201 includes trench termination structures 255 that are respectively formed at an end portion at the first side surface 205A side and an end portion at the second side surface 205B side of the active surface 206. Each trench termination structure 255 includes a plurality of the second trench structures 230 but does not include a first trench structure 220. Also, the trench termination structure 255 includes a well region 253 but does not include a contact region 252.

In the trench termination structure 255, the plurality of second trench structures 230 are respectively formed as bands extending in the first direction X and are formed at intervals in the second direction Y. In the trench termination structure 255, the source electrode 233 of each second trench structure 230 is formed in an electrically floating state. The well region 253 of the trench termination structure 255 covers the boundary side-surface 208 in addition to the plurality of second trench structures 230.

The SiC semiconductor device 201 includes an outer contact region 260 of the p-type that is formed in a surface layer portion of the outer surface 207. The outer contact region 260 may have a p-type impurity concentration of not less than 1×10¹⁸ cm⁻³ and not more than 1×10²¹ cm⁻³. The outer contact region 260 has a p-type impurity concentration that exceeds the p-type impurity concentration of the body region 250. The p-type impurity concentration of the outer contact region 260 is preferably substantially equal to the p-type impurity concentration of the contact regions 252.

The outer contact region 260 is formed in a region of the outer surface 207 between the boundary side-surface 208 and the peripheral edge of the first main surface 203 (first to fourth side surfaces 205A to 205D). The outer contact region 260 extends as a band along the active surface 206 (boundary side-surface 208). In this embodiment, the outer contact region 260 is formed to an annular shape that surrounds the active surface 206 in plan view. Specifically, the outer contact region 260 is formed to a quadrilateral annular shape that has four sides parallel to the active surface 206 in plan view.

The outer contact region 260 is formed at an interval toward the outer surface 207 from the bottom portion of the second semiconductor region 211. Specifically, the outer contact region 260 is formed at an interval toward the outer surface 207 from the second concentration region 213. An entirety of the outer contact region 260 is positioned at the bottom portion side of the second semiconductor region 211 with respect to the bottom wall of each first trench structure 220. A bottom portion of the outer contact region 260 is positioned at the bottom portion side of the second semiconductor region 211 with respect to the bottom wall of each second trench structure 230.

The bottom portion of the outer contact region 260 is preferably formed at a depth position substantially equal to a bottom portion of each contact region 252. The outer contact region 260 forms a pn junction portion with the second semiconductor region 211 (specifically, the second concentration region 213). A pn junction diode having the outer contact region 260 as an anode and the second semiconductor region 211 as a cathode is thereby formed. The outer contact region 260 may be referred to as an anode region.

The SiC semiconductor device 201 includes an outer well region 261 of the p-type that is formed in the surface layer portion of the outer surface 207. A p-type impurity concentration of the outer well region 261 may be not less than 1×10¹⁶ cm⁻³ and not more than 1×10¹⁸ cm⁻³. The outer well region 261 has a p-type impurity concentration that is less than the p-type impurity concentration of the outer contact region 260. The type impurity concentration of the outer well region 261 is preferably substantially equal to the p-type impurity concentration of the well regions 253.

The outer well region 261 is formed in a region between the boundary side-surface 208 and the outer contact region 260 in plan view. In this embodiment, the outer well region 261 is formed across an entire area of the region between the boundary side-surface 208 and the outer contact region 260 and is connected to the well region 253 in the boundary side-surface 208. The outer well region 261 extends as a band along the active surface 206 (boundary side-surface 208) in plan view. In this embodiment, the outer well region 261 is formed to an endless shape (a quadrilateral annular shape in this embodiment) that surrounds the active surface 206 (boundary side-surface 208) in plan view.

The outer well region 261 is formed deeper than the outer contact region 260. The outer well region 261 is formed at an interval toward the outer surface 207 from the bottom portion of the second semiconductor region 211. Specifically, the outer well region 261 is formed at an interval toward the outer surface 207 from the bottom portion of the second concentration region 213. An entirety of the outer well region 261 is positioned at the bottom portion side of the second semiconductor region 211 with respect to the bottom wall of each first trench structure 220.

A bottom portion of the outer well region 261 is positioned at the bottom portion side of the second semiconductor region 211 with respect to the bottom wall of each second trench structure 230. The bottom portion of the outer well region 261 is preferably formed at a depth position substantially equal to the bottom portion of each well region 253. Together with the outer contact region 260, the outer well region 261 forms a pn junction portion with the second semiconductor region 211 (specifically, the second concentration region 213).

The SiC semiconductor device 201 includes at least one (preferably not less than one and not more than twenty) field region 262 of the p-type that is formed in a region of the surface layer portion of the outer surface 207 between the outer contact region 260 and the peripheral edge of the first main surface 203 (first to fourth side surfaces 205A to 205D). The field region 262 relaxes an electric field in the outer surface 207. The number, width, depth, p-type impurity concentration, etc., of the field region 262 may take on any of various values in accordance with the electric field to be relaxed. The p-type impurity concentration of the field region 262 may be not less than 1×10¹⁵ cm⁻³ and not more than 1×10¹⁸ cm⁻³.

In this embodiment, the SiC semiconductor device 201 includes five field regions 262. The five field regions 262 include a first field region 262A, a second field region 262B, a third field region 262C, a fourth field region 262D, and a fifth field region 262E. The first to fifth field regions 262A to 262E are formed at intervals in that order from the outer contact region 260 side toward a peripheral edge side of the outer surface 207.

Each field region 262 is formed as a band extending along the active surface 206 in plan view. Each field region 262 is formed to an annular shape that surrounds the active surface 206 in plan view. Specifically, each field region 262 is formed to a quadrilateral annular shape that has four sides parallel to the active surface 206 (boundary side-surface 208) in plan view. Each field region 262 may be referred to as an FLR (field limiting ring) region.

Each field region 262 is formed deeper than the outer contact region 260. Each field region 262 is formed at an interval toward the outer surface 207 from the bottom portion of the second semiconductor region 211. Specifically, each field region 262 is formed at an interval toward the outer surface 207 from the bottom portion of the second concentration region 213. An entirety of each field region 262 is positioned at the bottom portion side of the second semiconductor region 211 with respect to the bottom wall of each first trench structure 220. A bottom portion of each field region 262 is positioned at the bottom portion side of the second semiconductor region 211 with respect to the bottom wall of each second trench structure 230.

In this embodiment, the innermost first field region 262A is connected to the outer contact region 260. Together with the outer contact region 260, the innermost first field region 262A forms a pn junction portion with the second semiconductor region 211 (specifically, the second concentration region 213). On the other hand, the second to fifth field regions 262B to 262E are formed in electrically floating states.

Referring to FIG. 14 to FIG. 16, the SiC semiconductor device 201 includes a main surface insulating film 270 that covers the first main surface 203. Specifically, the main surface insulating film 270 is formed as a film along the active surface 206, the outer surface 207, and the boundary side-surface 208. The main surface insulating film 270 includes at least one among a silicon oxide film, a silicon nitride film, and a silicon oxynitride film. In this embodiment, the main surface insulating film 270 has a single layer structure constituted of a silicon oxide film.

In the active surface 206, the main surface insulating film 270 exposes the plurality of second trench structures 230, the plurality of source regions 251, and the plurality of contact regions 252. The main surface insulating film 270 covers the opening edge portions of the plurality of first trench structures 220 and is continuous to the gate insulating film 222 of each first trench structure 220. The main surface insulating film 270 has a first peripheral end wall 271 that is formed at an interval inward from the peripheral edge of the outer surface 207 (first to fourth side surfaces 205A to 205D) and exposes a peripheral edge portion of the outer surface 207. A thickness of the main surface insulating film 270 may be not less than 50 nm and not more than 500 nm.

On the main surface insulating film 270, the SiC semiconductor device 201 includes a side wall structure 272 that covers the boundary side-surface 208. The side wall structure 272 is formed as a level difference moderating structure that moderates a level difference that is formed between the active surface 206 and the outer surface 207. The side wall structure 272 is formed as a band extending along the boundary side-surface 208 in plan view.

Specifically, the side wall structure 272 is formed self-aligningly with respect to the active surface 206 and is formed to an annular shape (specifically, a quadrilateral annular shape) that surrounds the active surface 206 in plan view. The side wall structure 272 has an outer surface that is inclined obliquely downward from the active surface 206 toward the outer surface 207. The outer surface of the side wall structure 272 may be formed to a curved shape that projects toward an opposite side to the boundary side-surface 208 or may be formed to a curved shape that is depressed toward the boundary side-surface 208 side.

The side wall structure 272 includes either or both of a conductor and an insulator. In this embodiment, the side wall structure 272 includes a conductive polysilicon. The side wall structure 272 is preferably constituted of the same conductive material as the gate electrodes 223 and/or the source electrodes 233. The side wall structure 272 may include an n-type polysilicon.

The SiC semiconductor device 201 includes a first inorganic insulating film 280 that is formed as an example of a covered object on the main surface insulating film 270. The first inorganic insulating film 280 may be referred to as an interlayer insulating film. The first inorganic insulating film 280 may have a laminated structure that includes a plurality of insulating films or may have a single layer structure constituted of a single insulating film. The first inorganic insulating film 280 preferably includes at least one among a silicon oxide film, a silicon nitride film, and a silicon oxynitride film. The first inorganic insulating film 280 may have a laminated structure that includes a plurality of silicon oxide films, a laminated structure that includes a plurality of silicon nitride films, or a laminated structure that includes a plurality of silicon oxynitride films.

The first inorganic insulating film 280 may have a laminated structure in which at least two types of films among a silicon oxide film, a silicon nitride film, and a silicon oxynitride film are laminated in any order. The first inorganic insulating film 280 may have a single layer structure constituted of a silicon oxide film, a silicon nitride film, or a silicon oxynitride film. In this embodiment, the first inorganic insulating film 280 has a laminated structure in which a plurality of silicon oxide films are laminated.

Specifically, the first inorganic insulating film 280 has the laminated structure that includes an NSG (nondoped silicate glass) film and a PSG (phosphor silicate glass) film that are laminated in that order from the main surface insulating film 270 side. The NSG film is constituted of a silicon oxide film that is not doped with an impurity. The PSG film is constituted of a silicon oxide film that is doped with phosphorus. A thickness of the NSG film may be not less than 10 nm and not more than 300 nm. A thickness of the PSG film may be not less than 50 nm and not more than 500 nm. The thickness of the first inorganic insulating film 280 preferably exceeds the thickness of the main surface insulating film 270.

The first inorganic insulating film 280 is formed as a film on the main surface insulating film 270 such as to conform to the active surface 206, the outer surface 207, and the boundary side-surface 208 and covers the active surface 206, the outer surface 207, and the boundary side-surface 208 across the main surface insulating film 270. The first inorganic insulating film 280 covers the side wall structure 272 between the active surface 206 and the outer surface 207.

The first inorganic insulating film 280 has a second peripheral end wall 281 that is formed at an interval inward from the peripheral edge of the outer surface 207 (first to fourth side surfaces 205A to 205D) and exposes the peripheral edge portion of the outer surface 207. Together with the first peripheral end wall 271 of the main surface insulating film 270, the second peripheral end wall 281 of the first inorganic insulating film 280 demarcates a notch opening 282 that exposes the peripheral edge portion of the outer surface 207.

In the active surface 206, the first inorganic insulating film 280 has a plurality of gate contact openings 283 that respectively expose the plurality of first trench structures 220. The plurality of gate contact openings 283 expose the plurality of first trench structures 220 in a one-to-one correspondence relationship. Specifically, the plurality of gate contact openings 283 are respectively formed at both end portion sides of the plurality of first trench structures 220 and respectively expose the corresponding gate electrodes 223.

In the active surface 206, the first inorganic insulating film 280 has a plurality of source contact openings 284 that respectively expose the plurality of second trench structures 230. The plurality of source contact openings 284 are formed in a one-to-one correspondence relationship with respect to the plurality of second trench structures 230. The plurality of source contact openings 284 respectively expose the corresponding source electrodes 233, source regions 251, and contact regions 252. Each source contact opening 284 may be formed as a band extending along each second trench structure 230.

In the outer surface 207, the first inorganic insulating film 280 includes at least one outer contact opening 285 that exposes the outer contact region 260. In this embodiment, the first inorganic insulating film 280 includes one outer contact opening 285. The outer contact opening 285 is formed as a band extending along the outer contact region 260 in plan view. The outer contact opening 285 is formed to an annular shape (specifically, a quadrilateral annular shape) that extends along the outer contact region 260.

The SiC semiconductor device 201 includes a plurality of first main surface electrodes 300 that are formed on the first inorganic insulating film 280. The plurality of first main surface electrodes 300 are arranged on the active surface 206. In this embodiment, the plurality of first main surface electrodes 300 are arranged just on the active surface 206 and is not arranged on the outer surface 207.

The plurality of first main surface electrodes 300 include a gate main surface electrode 301 that is arranged on a portion of the first inorganic insulating film 280 that covers the active surface 206. The gate main surface electrode 301 is electrically connected to the plurality of first trench structures 220 (gate electrodes 223) and transmits a gate potential (gate signal) that has been input to the plurality of first trench structures 220 (gate electrodes 223). The gate potential may be not less than 10 V and not more than 50 V (for example, approximately 30 V).

Specifically, the gate main surface electrode 301 is arranged on a peripheral edge portion of the active surface 206 at an interval from the boundary side-surface 208 in plan view. In this embodiment, the gate main surface electrode 301 is arranged in a region of the peripheral edge portion of the active surface 206 that faces a central portion of the first side surface 205A in plan view. The gate main surface electrode 301 faces the trench termination structures 255 across the first inorganic insulating film 280 and is electrically separated from the trench termination structures 255. The gate main surface electrode 301 is formed to a quadrilateral shape having four sides parallel to the active surface 206 in plan view.

The gate main surface electrode 301 has a gate electrode side wall 302 that is positioned on the first inorganic insulating film 280. The gate electrode side wall 302 is formed to a tapered shape that is inclined obliquely downward from a main surface of the gate main surface electrode 301. In this embodiment, the gate electrode side wall 302 is formed to a curved tapered shape that is curved toward the first inorganic insulating film 280. The positioning of the gate main surface electrode 301 is arbitrary. The gate main surface electrode 301 may be arranged on any corner portion of the active surface 206 in plan view.

The plurality of first main surface electrodes 300 include a source main surface electrode 303 that is arranged, at an interval from the gate main surface electrode 301, on a portion of the first inorganic insulating film 280 that covers the active surface 206. The source main surface electrode 303 is electrically connected to the plurality of second trench structures 230 (source electrodes 233) and transmits a source potential that has been input to the plurality of second trench structures 230 (source electrodes 233). The source potential may, for example, be the reference potential (for example, a ground potential).

Specifically, the source main surface electrode 303 is arranged on the active surface 206 at an interval from the boundary side-surface 208 in plan view. In this embodiment, the source main surface electrode 303 is formed to a quadrilateral shape (specifically, a rectangular shape) having four sides parallel to the active surface 206 (boundary side-surface 208) in plan view. Specifically, the source main surface electrode 303 has, at the side along the first side surface 205A, a recess portion 304 that is depressed toward an inner portion such as to conform to the gate main surface electrode 301. The source main surface electrode 303 has a plane area that exceeds a plane area of the gate main surface electrode 301.

The source main surface electrode 303 enters into the plurality of source contact openings 284 from above the first inorganic insulating film 280 and is electrically connected to the plurality of source electrodes 233, the plurality of source regions 251, and the plurality of contact regions 252. The source potential applied to the source main surface electrode 303 is thereby transmitted to the plurality of source electrodes 233, the plurality of source regions 251, and the plurality of contact regions 252. The source main surface electrode 303 faces the trench termination structures 255 across the first inorganic insulating film 280 at the peripheral edge portion of the active surface 206 and is electrically separated from the trench termination structures 255.

The source main surface electrode 303 has a source electrode side wall 305 that is positioned on the first inorganic insulating film 280. The source electrode side wall 305 is formed to a tapered shape that is inclined obliquely downward from a main surface of the source main surface electrode 303. In this embodiment, the source electrode side wall 305 is formed to a curved tapered shape that is curved toward the first inorganic insulating film 280.

The SiC semiconductor device 201 includes a plurality of wiring electrodes 306 that are formed on the first inorganic insulating film 280. On the first inorganic insulating film 280, the plurality of wiring electrodes 306 are routed in an arbitrary region that includes the active surface 206 and the outer surface 207.

The plurality of wiring electrodes 306 include a gate wiring electrode 307 that is led out from the gate main surface electrode 301 onto a portion of the first inorganic insulating film 280 that covers the active surface 206. Specifically, the gate wiring electrode 307 is formed on the active surface 206 and is not formed on the outer surface 207. The gate wiring electrode 307 transmits the gate potential applied to the gate main surface electrode 301 to other regions.

The gate wiring electrode 307 is led out from the gate main surface electrode 301 to a region between the boundary side-surface 208 and the source main surface electrode 303 and is formed as a band extending along the boundary side-surface 208. Specifically, the gate wiring electrode 307 extends as a band along the boundary side-surface 208 such as to face the source main surface electrode 303 from a plurality of directions in plan view. In this embodiment, the gate wiring electrode 307 extends as a band along the boundary side-surface 208 such as to face the source main surface electrode 303 from four directions in plan view. The gate wiring electrode 307 has an opened portion 308 at the second side surface 205B side. The position and size of the opened portion 308 are arbitrary.

The gate wiring electrode 307 intersects (specifically, is orthogonal to) the plurality of first trench structures 220 in plan view. Specifically, the gate wiring electrode 307 intersects (specifically, is orthogonal to) both end portions of the plurality of first trench structures 220 in plan view. The gate wiring electrode 307 enters into the plurality of gate contact openings 283 from above the first inorganic insulating film 280 and is electrically connected to the plurality of gate electrodes 223.

The gate potential applied to the gate main surface electrode 301 is thereby transmitted to the plurality of first trench structures 220 via the gate wiring electrode 307. The gate wiring electrode 307 faces the trench termination structures 255 across the first inorganic insulating film 280 at the peripheral edge portion of the active surface 206 and is electrically separated from the trench termination structures 255.

The gate wiring electrode 307 has a gate wiring side wall 309 that is positioned on the first inorganic insulating film 280. The gate wiring side wall 309 is formed to a tapered shape that is inclined obliquely downward from a main surface of the gate wiring electrode 307. In this embodiment, the gate wiring side wall 309 is formed to a curved tapered shape that is curved toward the first inorganic insulating film 280.

The plurality of wiring electrodes 306 include a source wiring electrode 310 that is led out from the source main surface electrode 303 onto a portion of the first inorganic insulating film 280 that covers the outer surface 207. Specifically, on the active surface 206, the source wiring electrode 310 is led out from the source main surface electrode 303, passed through the opened portion 308 of the gate wiring electrode 307, and led out onto the outer surface 207. The source wiring electrode 310 faces the side wall structure 272 across the first inorganic insulating film 280 at a boundary between the active surface 206 and the outer surface 207. The source wiring electrode 310 transmits the source potential applied to the source main surface electrode 303 from the active surface 206 side to the outer surface 207 side.

At the outer surface 207 side, the source wiring electrode 310 is led out onto the outer contact region 260 and is formed as a band extending along the outer contact region 260. In this embodiment, the source wiring electrode 310 is formed to an annular shape (specifically, a quadrilateral annular shape) that extends along the outer contact region 260 in plan view. That is, the source wiring electrode 310 surrounds the gate main surface electrode 301, the source main surface electrode 303, and the gate wiring electrode 307 collectively in plan view. In this embodiment, the source wiring electrode 310 covers the outer contact region 260 and the side wall structure 272 over entire periphery.

The source wiring electrode 310 enters into the outer contact opening 285 from above the first inorganic insulating film 280 and is electrically connected to the outer contact region 260. The source potential applied to the source main surface electrode 303 is thereby transmitted to the outer contact region 260 via the source wiring electrode 310.

The source wiring electrode 310 has a source wiring side wall 311 that is positioned on the first inorganic insulating film 280. The source wiring side wall 311 is formed to a tapered shape that is inclined obliquely downward from a main surface of the source main surface electrode 303. In this embodiment, the source wiring side wall 311 is formed to a curved tapered shape that is curved toward the first inorganic insulating film 280.

The plurality of first main surface electrodes 300 and the plurality of wiring electrodes 306 each have a laminated structure that includes a first electrode film 312 and a second electrode film 313 that are laminated in that order from the first inorganic insulating film 280 side. The first electrode film 312 is formed as a film along the first inorganic insulating film 280. The first electrode film 312 is constituted of a metal barrier film. In this embodiment, the first electrode film 312 is constituted of a Ti-based metal film. The first electrode film 312 includes at least one type of film among a titanium film and a titanium nitride film.

The first electrode film 312 may have a single layer structure constituted of a titanium film or a titanium nitride film. In this embodiment, the first electrode film 312 has a laminated structure that includes a titanium film and a titanium nitride film that are laminated in that order from the first main surface 203 side. A thickness of the first electrode film 312 may be not less than 10 nm and not more than 500 nm.

The second electrode film 313 is formed as a film along a main surface of the first electrode film 312. The first electrode film 312 is constituted of a Cu-based metal film or an Al-based metal film. The first electrode film 312 may include at least one type of film among a pure Cu film (a Cu film with a purity of not less than 99%), a pure Al film (an Al film with a purity of not less than 99%), an AlCu alloy film, an AlSi alloy film, and an AlSiCu alloy film. In this embodiment, the first electrode film 312 has a single layer structure constituted of an AlCu alloy film. A thickness of the second electrode film 313 may be not less than 0.5 μm and not more than 10 μm. The thickness of the second electrode film 313 is preferably not less than 2.5 μm and not more than 7.5 μm.

The SiC semiconductor device 201 includes a second inorganic insulating film 320. The second inorganic insulating film 320 is constituted of an inorganic insulator having a comparatively high denseness and has a barrier property (blocking property) against water (moisture). For example, an oxide of the first main surface electrodes 300 (in this embodiment, aluminum oxide) degrades electrical characteristics of the first main surface electrodes 300. The oxide of the plurality of first main surface electrodes 300 also becomes a factor that causes partial peeling, cracking, etc., of the first main surface electrodes 300 and other structures through thermal expansion.

The second inorganic insulating film 320 covers either or both of the first inorganic insulating film 280 and the first main surface electrodes 300 to block water (moisture) from the exterior and protects the SiC chip 202 and the first main surface electrodes 300 from oxidation. The second inorganic insulating film 320 may be referred to as a passivation film.

The second inorganic insulating film 320 may have a laminated structure that includes a plurality of insulating films or may have a single layer structure constituted of a single insulating film. The second inorganic insulating film 320 preferably includes at least one among a silicon oxide film, a silicon nitride film, and a silicon oxynitride film. The second inorganic insulating film 320 may have a laminated structure that includes a plurality of silicon oxide films, a laminated structure that includes a plurality of silicon nitride films, or a laminated structure that includes a plurality of silicon oxynitride films.

The second inorganic insulating film 320 may have a laminated structure in which at least two types of films among a silicon oxide film, a silicon nitride film, and a silicon oxynitride film are laminated in any order. The second inorganic insulating film 320 may have a single layer structure constituted of a silicon oxide film, a silicon nitride film, or a silicon oxynitride film. In this embodiment, the second inorganic insulating film 320 has a single layer structure constituted of a silicon nitride film. That is, the second inorganic insulating film 320 is constituted of an insulator differing from the first inorganic insulating film 280.

A thickness of the second inorganic insulating film 320 may be not less than the thickness of the first inorganic insulating film 280. The thickness of the second inorganic insulating film 320 is preferably less than the thickness of the first inorganic insulating film 280. The thickness of the second inorganic insulating film 320 preferably exceeds the thickness of the first electrode film 312. The second insulating thickness T2 is preferably not more than the thickness of the second electrode film 313. The thickness of the second inorganic insulating film 320 is especially preferably less than the thickness of the second electrode film 313. The thickness of the second inorganic insulating film 320 may be not less than 0.05 μm and not more than 5 μm. The thickness of the second inorganic insulating film 320 is preferably not less than 0.1 μm and not more than 2 μm.

In this embodiment, the second inorganic insulating film 320 includes a plurality of inner covering portions 321 (electrode covering portions), an outer covering portion 322 (insulation covering portions), and a removed portion 323. The plurality of inner covering portions 321 cover the plurality of first main surface electrodes 300 respectively such as to expose the electrode side walls of the plurality of first main surface electrodes 300. Specifically, the plurality of inner covering portions 321 include a first inner covering portion 324 (gate inner covering portion) that covers the gate main surface electrode 301 and a second inner covering portion 325 (source inner covering portion) that covers the source main surface electrode 303.

The second inorganic insulating film 320 suffices to have at least one of either of the first inner covering portion 324 and the second inner covering portion 325 and is not necessarily required to include both the first inner covering portion 324 and the second inner covering portion 325. The second inorganic insulating film 320 preferably has at least the second inner covering portion 325 covering the source main surface electrode 303 that is larger in area than the gate main surface electrode 301.

The second inorganic insulating film 320 especially preferably includes both the first inner covering portion 324 and the second inner covering portion 325. Also, the second inorganic insulating film 320 suffices to have at least one of either of the plurality of inner covering portion 321 and the outer covering portion 322 and is not necessarily required to include both the plurality of inner covering portions 321 and the outer covering portion 322. The second inorganic insulating film 320 preferably has at least the plurality of inner covering portions 321. The second inorganic insulating film 320 most preferably includes both the plurality of inner covering portion 321 and the outer covering portion 322.

Referring to FIG. 15, the first inner covering portion 324 of the second inorganic insulating film 320 covers the gate main surface electrode 301 such as to expose the gate electrode side wall 302 on the active surface 206. Specifically, the first inner covering portion 324 covers the gate main surface electrode 301 at an interval from the gate electrode side wall 302 such as to expose a peripheral edge portion of the gate main surface electrode 301. The first inner covering portion 324 also exposes an inner portion of the gate main surface electrode 301.

The first inner covering portion 324 is formed as a band extending along the gate electrode side wall 302 in plan view. In this embodiment, the first inner covering portion 324 is formed to an annular shape that surrounds the inner portion of the gate main surface electrode 301 in plan view. Specifically, the first inner covering portion 324 is formed to an annular shape (specifically, a quadrilateral annular shape) that has four sides parallel to the gate electrode side wall 302 in plan view.

The first inner covering portion 324 has a first inner wall portion 326 at the inner portion side of the gate main surface electrode 301 and a first outer wall portion 327 at the gate electrode side wall 302 side. The first inner wall portion 326 demarcates a first gate opening 328 that exposes the inner portion of the gate main surface electrode 301. In this embodiment, the first inner wall portion 326 (first gate opening 328) is formed to a quadrilateral shape that has four sides parallel to the gate electrode side wall 302 in plan view. The first inner wall portion 326 is formed to a tapered shape that is inclined obliquely downward from a main surface of the second inorganic insulating film 320 toward the inner portion of the gate main surface electrode 301.

The first outer wall portion 327 is formed on the gate main surface electrode 301 at an interval from the gate electrode side wall 302 such as to expose the peripheral edge portion of the gate main surface electrode 301. In this embodiment, the first outer wall portion 327 is formed to a quadrilateral shape that has four sides parallel to the gate electrode side wall 302 in plan view. The first outer wall portion 327 is formed to a tapered shape that is inclined obliquely downward from the main surface of the second inorganic insulating film 320 toward the gate electrode side wall 302 of the gate main surface electrode 301.

Referring to FIG. 16, the second inner covering portion 325 of the second inorganic insulating film 320 covers the source main surface electrode 303 such as to expose the source electrode side wall 305 on the active surface 206. Specifically, the second inner covering portion 325 covers the source main surface electrode 303 at an interval from the source electrode side wall 305 such as to expose a peripheral edge portion of the source main surface electrode 303. The second inner covering portion 325 also exposes an inner portion of the source main surface electrode 303.

The second inner covering portion 325 is formed as a band extending along the source electrode side wall 305 in plan view. In this embodiment, the second inner covering portion 325 is formed to an annular shape that surrounds the inner portion of the source main surface electrode 303 in plan view. The second inner covering portion 325 has a portion that is depressed as a recess toward an inner side of the source main surface electrode 303 such as to conform to the portion of the source electrode side wall 305 that forms the recess portion 304. Thereby, the second inner covering portion 325 is formed to an annular shape (specifically, a polygonal annular shape) that has sides parallel to the source electrode side wall 305 in plan view.

The second inner covering portion 325 has a second inner wall portion 329 at the inner portion side of the source main surface electrode 303 and a second outer wall portion 330 at the source electrode side wall 305 side of the source main surface electrode 303. The second inner wall portion 329 demarcates a first source opening 331 that exposes the inner portion of the source main surface electrode 303. In this embodiment, the second inner wall portion 329 (first source opening 331) is formed to a polygonal shape that has sides parallel to the source electrode side wall 305 in plan view. The second inner wall portion 329 is formed to a tapered shape that is inclined obliquely downward from a main surface of the second inorganic insulating film 320 toward the inner portion of the source main surface electrode 303.

The second outer wall portion 330 is formed on the source main surface electrode 303 at an interval from the source electrode side wall 305 such as to expose the peripheral edge portion of source main surface electrode 303. In this embodiment, the second outer wall portion 330 is formed to a polygonal shape that has sides parallel to the source electrode side wall 305 in plan view. The second outer wall portion 330 is formed to a tapered shape that is inclined obliquely downward from the main surface of the second inorganic insulating film 320 toward the source electrode side wall 305 of the source main surface electrode 303.

Referring to FIG. 15 and FIG. 16, the outer covering portion 322 of the second inorganic insulating film 320 covers the first inorganic insulating film 280 at intervals toward the peripheral edge side of the first main surface 203 from the gate main surface electrode 301 and the source main surface electrode 303 such as to expose the gate electrode side wall 302 and the source electrode side wall 305.

The outer covering portion 322 is formed at an interval toward the peripheral edge of the first main surface 203 from the gate wiring electrode 307 such as to expose the gate wiring side wall 309. The outer covering portion 322 is formed at an interval toward the peripheral edge of the first main surface 203 from the source wiring electrode 310 such as to expose the source wiring side wall 311. The outer covering portion 322 covers the first inorganic insulating film 280 at an interval toward the outer surface 207 from the boundary side-surface 208.

That is, the outer covering portion 322 covers the first inorganic insulating film 280 such as to expose the gate main surface electrode 301 (gate electrode side wall 302), the source main surface electrode 303 (source electrode side wall 305), the gate wiring electrode 307 (gate wiring side wall 309), and the source wiring electrode 310 (source wiring side wall 311) on the outer surface 207.

The outer covering portion 322 is formed as a band extending along the active surface 206 (boundary side-surface 208) in plan view. The outer covering portion 322 is formed to an annular shape that surrounds the active surface 206. Specifically, the outer covering portion 322 is formed to a quadrilateral annular shape having four sides parallel to the active surface 206 in plan view. That is, the outer covering portion 322 surrounds the gate main surface electrode 301, the source main surface electrode 303, the gate wiring electrode 307, and the source wiring electrode 310 collectively in plan view.

The outer covering portion 322 is formed at an interval toward the peripheral edge of the first main surface 203 (first to fourth side surfaces 205A to 205D) from the outer contact region 260 in plan view. The outer covering portion 322 faces at least one field region 262 across the first inorganic insulating film 280.

In this embodiment, the outer covering portion 322 is formed at an interval toward the peripheral edge side of the first main surface 203 from the innermost first field region 262A and faces the second to fifth field regions 262B to 262E across the first inorganic insulating film 280. Obviously, the outer covering portion 322 may face all of the first to fifth field regions 262A to 262E across the first inorganic insulating film 280.

In this embodiment, the outer covering portion 322 traverses the notch opening 282 (first peripheral end wall 271 and second peripheral end wall 281) from above the first inorganic insulating film 280 and is led out onto the outer surface 207 that is exposed from the notch opening 282. Thereby, the outer covering portion 322 includes a first covering portion 332 that covers the first inorganic insulating film 280 and a second covering portion 333 that directly covers the outer surface 207.

The first covering portion 332 extends as a film along the first inorganic insulating film 280 and faces the outer surface 207 across the first inorganic insulating film 280. The first covering portion 332 faces the second semiconductor region 211 and at least one field region 262 (the second to fifth field regions 262B to 262E in this embodiment) across the first inorganic insulating film 280. A main surface of the first covering portion 332 is positioned at the first inorganic insulating film 280 side with respect to the active surface 206. In this embodiment, the main surface of the first covering portion 332 is positioned at the first inorganic insulating film 280 side with respect to a main surface of the source wiring electrode 310.

The second covering portion 333 extends as a film along the outer surface 207 and directly covers the outer surface 207. That is, the second covering portion 333 directly covers the second semiconductor region 211 (second concentration region 213). A main surface of the second covering portion 333 is positioned at the outer surface 207 side with respect to the active surface 206. The main surface of the second covering portion 333 is positioned at the outer surface 207 side with respect to the main surface of the source wiring electrode 310. In this embodiment, the main surface of the second covering portion 333 is positioned between the outer surface 207 and the main surface of the first inorganic insulating film 280.

The second covering portion 333 is formed at an interval toward the first inorganic insulating film 280 side from the peripheral edge of the first main surface 203 (first to fourth side surfaces 205A to 205D) such as to expose the peripheral edge portion of the outer surface 207. Together with the peripheral edge of the first main surface 203, the second covering portion 333 demarcates a dicing street 334 at which the peripheral edge portion of the outer surface 207 is exposed. The dicing street 334 is demarcated in a quadrilateral annular shape that extends along the peripheral edge of the first main surface 203. A width of the dicing street 334 may be not less than 5 μm and not more than 25 μm. The width of the dicing street 334 is a width in a direction orthogonal to a direction in which the dicing street 334 extends.

The outer covering portion 322 has a third inner wall portion 335 at the active surface 206 side and a third outer wall portion 336 at the peripheral edge side of the first main surface 203. The third inner wall portion 335 is formed on the first inorganic insulating film 280 at an interval from the source wiring side wall 311 of the source wiring electrode 310 such as to expose the first inorganic insulating film 280 on the outer surface 207.

In this embodiment, the third inner wall portion 335 is formed to a quadrilateral shape that has four sides parallel to the source wiring electrode 310 (source wiring side wall 311) in plan view and surrounds the gate main surface electrode 301, the source main surface electrode 303, the gate wiring electrode 307, and the source wiring electrode 310 collectively. The third inner wall portion 335 is formed to a tapered shape that is inclined obliquely downward from the main surface of the second inorganic insulating film 320 toward the first inorganic insulating film 280.

The third outer wall portion 336 is formed in a region between the notch opening 282 and the peripheral edge of the first main surface 203 (first to fourth side surfaces 205A to 205D) in plan view and exposes the peripheral edge portion of the outer surface 207. The third outer wall portion 336 is formed to a tapered shape that is inclined obliquely downward from the main surface of the second inorganic insulating film 320 toward the outer surface 207. Together with the peripheral edge of the first main surface 203, the third outer wall portion 336 demarcates the dicing street 334.

The removed portion 323 of the second inorganic insulating film 320 is demarcated between the first inner covering portion 324 (first outer wall portion 327) and the outer covering portion 322 (third inner wall portion 335), between the second inner covering portion 325 (second outer wall portion 330) and the outer covering portion 322 (third inner wall portion 335), and between the first inner covering portion 324 (first outer wall portion 327) and the second inner covering portion 325 (second outer wall portion 330). In this embodiment, the removed portion 323 is formed as a band extending along the boundary side-surface 208, the first outer wall portion 327, and the second outer wall portion 330 in plan view. In this embodiment, the removed portion 323 integrally includes an annular portion that extends along the first outer wall portion 327 and an annular portion that extends along the second outer wall portion 330 (boundary side-surface 208) in plan view.

The removed portion 323 exposes a level difference portion between the active surface 206 and the outer surface 207 (that is, the boundary side-surface 208) over entire periphery and, at the same time, exposes the gate electrode side wall 302, the source electrode side wall 305, the gate wiring side wall 309, and the source wiring side wall 311 along entire peripheries thereof. That is, the removed portion 323 exposes an entire area of the gate wiring electrode 307, an entire area of the source wiring electrode 310, and an entire area of the side wall structure 272 interposed between the gate wiring electrode 307 and the source wiring electrode 310.

With the second inorganic insulating film 320, the first inner covering portion 324 is formed on the gate main surface electrode 301 that is flat, the second inner covering portion 325 is formed on the source main surface electrode 303 that is flat, and the outer covering portion 322 is formed on the first inorganic insulating film 280 that is flat. Therefore, with the second inorganic insulating film 320, level differences due to the gate electrode side wall 302, the source electrode side wall 305, the gate wiring side wall 309, and the source wiring side wall 311 are eliminated by the removed portion 323. Also, with the second inorganic insulating film 320, a level difference due to the active mesa 209 is eliminated by the removed portion 323.

The SiC semiconductor device 201 includes an organic insulating film 340 that selectively covers the second inorganic insulating film 320 and the plurality of first main surface electrodes 300. The organic insulating film 340 has a lower hardness than a hardness of the second inorganic insulating film 320. In other words, the organic insulating film 340 has an elastic modulus that is lower than an elastic modulus of the second inorganic insulating film 320 and functions as a cushioning material (protective film) against an external force. The organic insulating film 340 protects the SiC chip 202, the first main surface electrodes 300, the second inorganic insulating film 320, etc., from the external force.

The organic insulating film 340 preferably includes a photosensitive resin. The photosensitive resin may be of a negative type or a positive type. The organic insulating film 340 may include at least one among a polyimide film, a polyamide film, and a polybenzoxazole film. In this embodiment, the organic insulating film 340 includes a polybenzoxazole film.

A thickness of the organic insulating film 340 may be not less than 1 μm and not more than 50 μm. The thickness of the organic insulating film 340 is preferably not less than 5 μm and not more than 20 μm. The thickness of the organic insulating film 340 preferably exceeds the thickness of the second inorganic insulating film 320. The thickness of the organic insulating film 340 especially preferably exceeds the thickness of the first main surface electrodes 300.

On the active surface 206, the organic insulating film 340 covers the gate electrode side wall 302 of the gate main surface electrode 301. Specifically, the organic insulating film 340 covers the gate electrode side wall 302 along an entire periphery of the gate main surface electrode 301. On the gate electrode side wall 302, the organic insulating film 340 covers the first electrode film 312 and the second electrode film 313. The organic insulating film 340 covers an edge portion of the gate main surface electrode 301.

That is, the organic insulating film 340 extends from the gate electrode side wall 302 toward the first inner covering portion 324 and covers the peripheral edge portion of the gate main surface electrode 301 that is exposed from between the gate electrode side wall 302 and the first inner covering portion 324. The organic insulating film 340 further extends from the peripheral edge portion of the gate main surface electrode 301 toward above the first inner covering portion 324 and covers the first inner covering portion 324.

The organic insulating film 340 covers the first inner covering portion 324 such as to expose the inner portion of the gate main surface electrode 301. Specifically, the organic insulating film 340 covers the first inner covering portion 324 such as to expose the first inner wall portion 326 of the first inner covering portion 324. More specifically, the organic insulating film 340 covers the first inner covering portion 324 at an interval toward the first outer wall portion 327 side from the first inner wall portion 326 and exposes the inner portion of the gate main surface electrode 301 and an edge portion of the first inner covering portion 324 (hereinafter referred to as the “first edge portion 341”).

On the active surface 206, the organic insulating film 340 covers the source electrode side wall 305 of the source main surface electrode 303. Specifically, the organic insulating film 340 covers the source electrode side wall 305 along an entire periphery of the source main surface electrode 303. On the source electrode side wall 305, the organic insulating film 340 covers the first electrode film 312 and the second electrode film 313. The organic insulating film 340 covers an edge portion of the source main surface electrode 303.

That is, the organic insulating film 340 extends from the source electrode side wall 305 toward the second inner covering portion 325 and covers the peripheral edge portion of the source main surface electrode 303 that is exposed from between the source electrode side wall 305 and the second inner covering portion 325. The organic insulating film 340 further extends from the peripheral edge portion of the source main surface electrode 303 toward above the second inner covering portion 325 and covers the second inner covering portion 325.

The organic insulating film 340 covers the second inner covering portion 325 such as to expose the inner portion of the source main surface electrode 303. Specifically, the organic insulating film 340 covers the second inner covering portion 325 such as to expose the second inner wall portion 329 of the second inner covering portion 325. More specifically, the organic insulating film 340 covers the second inner covering portion 325 at an interval toward the second outer wall portion 330 side from the second inner wall portion 329 and exposes the inner portion of the source main surface electrode 303 and an edge portion of the second inner covering portion 325 (hereinafter referred to as the “second edge portion 342”).

On the active surface 206, the organic insulating film 340 covers the gate wiring side wall 309 of the gate wiring electrode 307. Specifically, the organic insulating film 340 covers the gate wiring side wall 309 along an entire periphery of the gate wiring electrode 307. On the gate wiring side wall 309, the organic insulating film 340 covers the first electrode film 312 and the second electrode film 313. The organic insulating film 340 extends from the gate wiring side wall 309 onto the gate wiring electrode 307 and covers the entire area of the gate wiring electrode 307.

The organic insulating film 340 covers an upper side of the peripheral edge portion of the active surface 206, passes over the side wall structure 272, and covers an upper side of the outer surface 207. On the outer surface 207, the organic insulating film 340 covers the source wiring side wall 311 of the source wiring electrode 310. Specifically, the organic insulating film 340 covers the source wiring side wall 311 along an entire periphery of the source wiring electrode 310. On the source wiring side wall 311, the organic insulating film 340 covers the first electrode film 312 and the second electrode film 313. The organic insulating film 340 extends from the source wiring side wall 311 onto the source wiring electrode 310 and covers the entire area of the source wiring electrode 310.

The organic insulating film 340 is led out from the source wiring electrode 310 side onto the outer covering portion 322 of the second inorganic insulating film 320 and covers the outer covering portion 322. The organic insulating film 340 covers the outer covering portion 322 such as to expose the peripheral edge portion of the outer surface 207. Specifically, the organic insulating film 340 covers the outer covering portion 322 such as to expose the third outer wall portion 336 of the outer covering portion 322.

More specifically, the organic insulating film 340 covers the outer covering portion 322 at an interval toward the third inner wall portion 335 side from the third outer wall portion 336 and exposes the peripheral edge portion of the outer surface 207 and a peripheral edge portion of the outer covering portion 322 in plan view. That is, the organic insulating film 340 covers the first covering portion 332 and the second covering portion 333 of the outer covering portion 322 such as to expose the outer surface 207.

The organic insulating film 340 has a fourth inner wall portion 343 at the gate main surface electrode 301 side. The fourth inner wall portion 343 demarcates a second gate opening 344 that exposes the inner portion of the gate main surface electrode 301. The fourth inner wall portion 343 (second gate opening 344) extends along the first inner wall portion 326 (first gate opening 328) of the first inner covering portion 324. In this embodiment, the fourth inner wall portion 343 is formed to a quadrilateral shape that has four sides parallel to the first inner wall portion 326.

Specifically, the fourth inner wall portion 343 is formed on the first inner covering portion 324 at an interval toward the first outer wall portion 327 side from the first inner wall portion 326 and exposes the inner portion of the gate main surface electrode 301 and the first edge portion 341 of the first inner covering portion 324. That is, the second gate opening 344 exposes the inner portion of the gate main surface electrode 301 and the first edge portion 341 of the first inner covering portion 324. An exposed width of the first edge portion 341 may exceed 0 μm and be not more than 10 μm. The exposed width of the first edge portion 341 is preferably not less than 1 μm and not more than 5 μm.

The fourth inner wall portion 343 (second gate opening 344) is in communication with the first inner wall portion 326 (first gate opening 328) and forms a single gate pad opening 345 together with the first inner wall portion 326 (first gate opening 328). The fourth inner wall portion 343 (second gate opening 344) is formed to a tapered shape that is inclined obliquely downward from a main surface of the organic insulating film 340 toward the first inner wall portion 326. In this embodiment, the fourth inner wall portion 343 is formed to a curved tapered shape that is curved toward the first inner covering portion 324.

The organic insulating film 340 has a fifth inner wall portion 346 at the source main surface electrode 303 side. The fifth inner wall portion 346 demarcates a second source opening 347 that exposes the inner portion of the source main surface electrode 303. The fifth inner wall portion 346 (second source opening 347) extends along the second inner wall portion 329 (first source opening 331) of the second inner covering portion 325. In this embodiment, the fifth inner wall portion 346 is formed to a polygonal shape that has sides parallel to the second inner wall portion 329 of the second inner covering portion 325.

Specifically, the fifth inner wall portion 346 is formed on the second inner covering portion 325 at an interval toward the second outer wall portion 330 side from the second inner wall portion 329 of the second inner covering portion 325 and exposes the inner portion of the source main surface electrode 303 and the second edge portion 342 of the second inner covering portion 325. That is, the second source opening 347 exposes the inner portion of the source main surface electrode 303 and the second edge portion 342 of the second inner covering portion 325. An exposed width of the second edge portion 342 may exceed 0 μm and be not more than 10 μm. The exposed width of the second edge portion 342 is preferably not less than 1 μm and not more than 5 μm.

The fifth inner wall portion 346 (second source opening 347) is in communication with the second inner wall portion 329 (first source opening 331) of the second inner covering portion 325 and forms a single source pad opening 348 together with the second inner wall portion 329 (first source opening 331). The fifth inner wall portion 346 (second source opening 347) is formed to a tapered shape that is inclined obliquely downward from the main surface of the organic insulating film 340 toward the second inner wall portion 329. In this embodiment, the fifth inner wall portion 346 is formed to a curved tapered shape that is curved toward the second inner covering portion 325.

The organic insulating film 340 has a fourth outer wall portion 349. The fourth outer wall portion 349 is formed at an interval toward the outer covering portion 322 side from the peripheral edge of the first main surface 203 (first to fourth side surfaces 205A to 205D) such as to expose the outer surface 207. Specifically, the fourth outer wall portion 349 is formed on the third outer wall portion 336 such as to expose the third outer wall portion 336 of the outer covering portion 322. More specifically, the fourth outer wall portion 349 is formed at an interval toward the third inner wall portion 335 side from the third outer wall portion 336 such as to expose the peripheral edge portion of the outer covering portion 322.

The fourth outer wall portion 349 is positioned on the second covering portion 333 of the outer covering portion 322 and faces the outer surface 207 across the outer covering portion 322. Together with the third outer wall portion 336, the fourth outer wall portion 349 demarcates the dicing street 334. In this embodiment, the fourth outer wall portion 349 is formed to a quadrilateral shape that has four sides parallel to the active surface 206 in plan view. The fourth outer wall portion 349 is formed to a tapered shape that is inclined obliquely downward from the main surface of the organic insulating film 340 toward the third outer wall portion 336 of the outer covering portion 322. In this embodiment, the fourth outer wall portion 349 is formed to a curved tapered shape that is curved toward the outer covering portion 322.

Thus, on the active surface 206, the organic insulating film 340 covers the edge portion of the gate main surface electrode 301, the edge portion of the source main surface electrode 303, the entire area of the gate wiring electrode 307, and the plurality of inner covering portions 321 of the second inorganic insulating film 320. On the active surface 206, the organic insulating film 340 covers portions of the first inorganic insulating film 280 that are exposed from the gate main surface electrode 301, the gate wiring electrode 307, and the source main surface electrode 303. The organic insulating film 340 may face the plurality of first trench structures 220 and the plurality of second trench structures 230 across the first inorganic insulating film 280.

The organic insulating film 340 covers the side wall structure 272 between the active surface 206 and the outer surface 207. On the outer surface 207, the organic insulating film 340 covers the entire area of the source wiring electrode 310 and the outer covering portion 322 of the second inorganic insulating film 320. On the outer surface 207, the organic insulating film 340 covers portions of the first inorganic insulating film 280 that are exposed from the source wiring electrode 310 and the second inorganic insulating film 320.

Also, the organic insulating film 340 is formed across the plurality of inner covering portions 321 and the outer covering portion 322 of the second inorganic insulating film 320 and, inside the removed portion 323 between the plurality of inner covering portions 321 and the outer covering portion 322, covers the edge portion of the gate main surface electrode 301, the edge portion of the source main surface electrode 303, the entire area of the gate wiring electrode 307, and the entire area of the source wiring electrode 310.

That is, inside the removed portion 323, the organic insulating film 340 fills the unevenness formed by the first inorganic insulating film 280, the second inorganic insulating film 320, the gate main surface electrode 301, the source main surface electrode 303, the gate wiring electrode 307, and the source wiring electrode 310. Level differences of portions of the organic insulating film 340 that are positioned inside the removed portion 323 are moderated by the side wall structure 272.

Referring to FIG. 17 and FIG. 18, the SiC semiconductor device 201 includes a plurality of pad electrodes 360 that are formed respectively on the plurality of first main surface electrodes 300. The plurality of pad electrodes 360 are terminal electrodes for external connection and are each constituted of a plating film in this embodiment. The plurality of pad electrodes 360 include a gate pad electrode 361 and a source pad electrode 362.

The gate pad electrode 361 is formed on the inner portion of the gate main surface electrode 301 inside the gate pad opening 345. The gate pad electrode 361 includes a first Ni plating film 363. In the normal direction Z, the first Ni plating film 363 is formed at an interval toward the gate main surface electrode 301 side from the main surface of the organic insulating film 340. Inside the first gate opening 328, the first Ni plating film 363 covers the gate main surface electrode 301 and the first inner wall portion 326 of the first inner covering portion 324.

Specifically, the first Ni plating film 363 has a first covering portion 364 that is led out from above the gate main surface electrode 301 onto the first inner covering portion 324 and covers the first edge portion 341 of the first inner covering portion 324 inside the second gate opening 344. On the first inner covering portion 324, the first covering portion 364 is formed to an arcuate shape directed toward the organic insulating film 340 (fourth inner wall portion 343) with the first inner wall portion 326 as a starting point.

In this embodiment, the first covering portion 364 covers the fourth inner wall portion 343 of the organic insulating film 340. The first covering portion 364 covers a region at the second inorganic insulating film 320 side with respect to an intermediate portion of the fourth inner wall portion 343. In other words, the first covering portion 364 covers the fourth inner wall portion 343 such that an exposed area of the fourth inner wall portion 343 exceeds a hidden area of the fourth inner wall portion 343. The first Ni plating film 363 thus fills an entirety of the first gate opening 328 and a portion of the second gate opening 344.

A thickness of the first Ni plating film 363 exceeds the thickness of the second inorganic insulating film 320. The thickness of the first Ni plating film 363 is less than the thickness of the organic insulating film 340. The thickness of the first Ni plating film 363 is a thickness of the first Ni plating film 363 on the basis of the main surface of the gate main surface electrode 301. The thickness of the first Ni plating film 363 exceeds a sum of the thickness of the second inorganic insulating film 320 and the exposed width of the first edge portion 341. This is one condition for the first Ni plating film 363 to be in contact with the fourth inner wall portion 343. The thickness of the first Ni plating film 363 may be not less than 0.1 μm and not more than 15 μm. The thickness of the first Ni plating film 363 is preferably not less than 2 μm and not more than 8 μm.

The gate pad electrode 361 includes a first outer plating film 365 that is constituted of a metal material differing from the first Ni plating film 363 and covers an outer surface of the first Ni plating film 363. The first outer plating film 365 is formed as a film along the outer surface of the first Ni plating film 363. The first outer plating film 365 covers the fourth inner wall portion 343 of the organic insulating film 340.

The first outer plating film 365 has a first terminal surface 366 for external connection. In the normal direction Z, the first terminal surface 366 is positioned at the first Ni plating film 363 side with respect to the main surface of the organic insulating film 340 (opening end of the second gate opening 344). The first outer plating film 365 thereby exposes a portion of the fourth inner wall portion 343. A thickness of the first outer plating film 365 is less than the thickness of the first Ni plating film 363.

In this embodiment, the first outer plating film 365 has a laminated structure that includes a first Pd plating film 367 and a first Au plating film 368 that are laminated in that order from the first Ni plating film 363 side. The first Pd plating film 367 is formed as a film along the outer surface of the first Ni plating film 363. In the normal direction Z, the first Pd plating film 367 covers the first Ni plating film 363 at an interval toward the second inorganic insulating film 320 side from the main surface of the organic insulating film 340. The first Pd plating film 367 covers the fourth inner wall portion 343. A thickness of the first Pd plating film 367 may be not less than 0.01 μm and not more than 1 μm.

The first Au plating film 368 is formed as a film along an outer surface of the first Pd plating film 367. In the normal direction Z, the first Au plating film 368 covers the first Pd plating film 367 at an interval toward the second inorganic insulating film 320 side from the main surface of the organic insulating film 340. The first Au plating film 368 covers the fourth inner wall portion 343. A thickness of the first Au plating film 368 may be not less than 0.01 μm and not more than 1 μm. The first Au plating film 368 preferably has a thickness less than the thickness of the first Pd plating film 367.

The source pad electrode 362 is formed on the inner portion of the source main surface electrode 303 inside the source pad opening 348. The source pad electrode 362 includes a second Ni plating film 373. In the normal direction Z, the second Ni plating film 373 is formed at an interval toward the source main surface electrode 303 side from the main surface of the organic insulating film 340. Inside the first source opening 331, the second Ni plating film 373 covers the source main surface electrode 303 and the second inner wall portion 329 of the second inner covering portion 325.

Specifically, the second Ni plating film 373 has a second covering portion 374 that is led out from above the source main surface electrode 303 onto the second inner covering portion 325 and covers the second edge portion 342 of the second inner covering portion 325 inside the second source opening 347. On the second inner covering portion 325, the second covering portion 374 is formed to an arcuate shape directed toward the organic insulating film 340 (fifth inner wall portion 346) with the second inner wall portion 329 as a starting point.

In this embodiment, the second covering portion 374 covers the fifth inner wall portion 346 of the organic insulating film 340. The second covering portion 374 covers a region at the second inorganic insulating film 320 side with respect to an intermediate portion of the fifth inner wall portion 346. In other words, the second covering portion 374 covers the fifth inner wall portion 346 such that an exposed area of the fifth inner wall portion 346 exceeds a hidden area of the fifth inner wall portion 346. The second Ni plating film 373 thus fills an entirety of the first source opening 331 and a portion of the second source opening 347.

A thickness of the second Ni plating film 373 exceeds the thickness of the second inorganic insulating film 320. The thickness of the second Ni plating film 373 is less than the thickness of the organic insulating film 340. The thickness of the second Ni plating film 373 is a thickness of the second Ni plating film 373 on the basis of the main surface of the source main surface electrode 303. The thickness of the second Ni plating film 373 exceeds a sum of the thickness of the second inorganic insulating film 320 and the exposed width of the second edge portion 342. This is one condition for the second Ni plating film 373 to be in contact with the fifth inner wall portion 346. The thickness of the second Ni plating film 373 may be not less than 0.1 μm and not more than 15 μm. The thickness of the second Ni plating film 373 is preferably not less than 2 μm and not more than 8 μm.

The source pad electrode 362 includes a second outer plating film 375 that is constituted of a metal material differing from the second Ni plating film 373 and covers an outer surface of the second Ni plating film 373. The second outer plating film 375 is formed as a film along the outer surface of the second Ni plating film 373. The second outer plating film 375 covers the fifth inner wall portion 346 of the organic insulating film 340.

The second outer plating film 375 has a source terminal surface 376 for external connection. In the normal direction Z, the source terminal surface 376 is positioned at the second Ni plating film 373 side with respect to the main surface of the organic insulating film 340 (opening end of the second source opening 347). The second outer plating film 375 thereby exposes a portion of the fifth inner wall portion 346. A thickness of the second outer plating film 375 is less than the thickness of the second Ni plating film 373.

In this embodiment, the second outer plating film 375 has a laminated structure that includes a second Pd plating film 377 and a second Au plating film 378 that are laminated in that order from the second Ni plating film 373 side. The second Pd plating film 377 is formed as a film along the outer surface of the second Ni plating film 373. In the normal direction Z, the second Pd plating film 377 covers the second Ni plating film 373 at an interval toward the second inorganic insulating film 320 side from the main surface of the organic insulating film 340. The second Pd plating film 377 covers the fifth inner wall portion 346 inside the second source opening 347. A thickness of the second Pd plating film 377 may be not less than 0.01 μm and not more than 1 μm.

The second Au plating film 378 is formed as a film along an outer surface of the second Pd plating film 377. In the normal direction Z, the second Au plating film 378 covers the second Pd plating film 377 at an interval toward the second inorganic insulating film 320 side from the main surface of the organic insulating film 340. The second Au plating film 378 covers the fifth inner wall portion 346 inside the second source opening 347. A thickness of the second Au plating film 378 may be not less than 0.01 μm and not more than 1 μm. The second Au plating film 378 preferably has a thickness less than the thickness of the second Pd plating film 377.

The SiC semiconductor device 201 includes a second main surface electrode 380 that covers the second main surface 204. The second main surface electrode 380 covers an entire area of the second main surface 204 and is continuous to the peripheral edge of the first main surface 203 (first to fourth side surfaces 205A to 205D). The second main surface electrode 380 is electrically connected to the first semiconductor region 210 (second main surface 204). Specifically, the second main surface electrode 380 forms an ohmic contact with the first semiconductor region 210 (second main surface 204).

In this embodiment, the second main surface electrode 380 includes a Ti film 381, an Ni film 382, a Pd film 383, an Au film 384, and an Ag film 385 that are laminated in that order from the second main surface 204 side. The second main surface electrode 380 suffices to include at least the Ti film 381 and presence/absences of the Ni film 382, the Pd film 383, the Au film 384, and the Ag film 385 are respectively arbitrary. As an example, the second main surface electrode 380 may have a laminated structure that includes the Ti film 381, the Ni film 382, and the Au film 384.

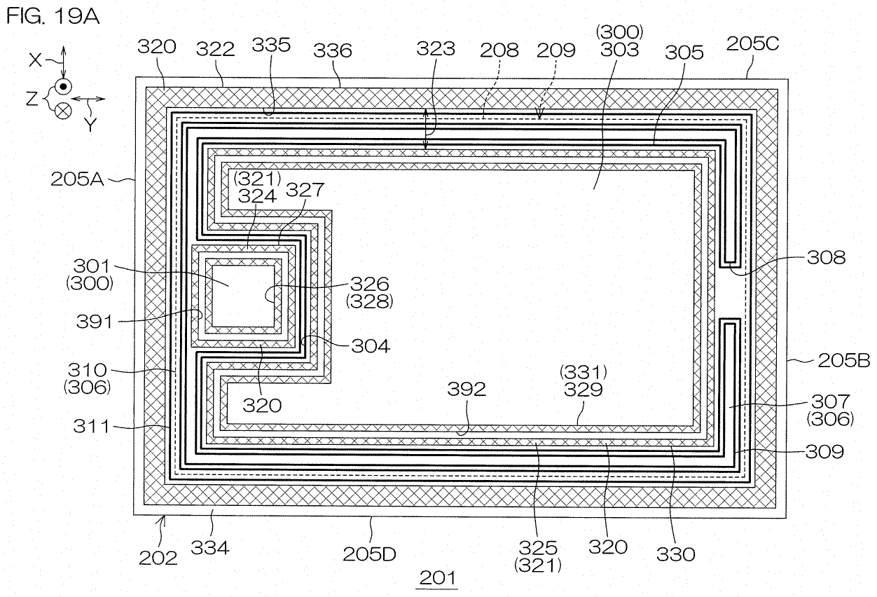

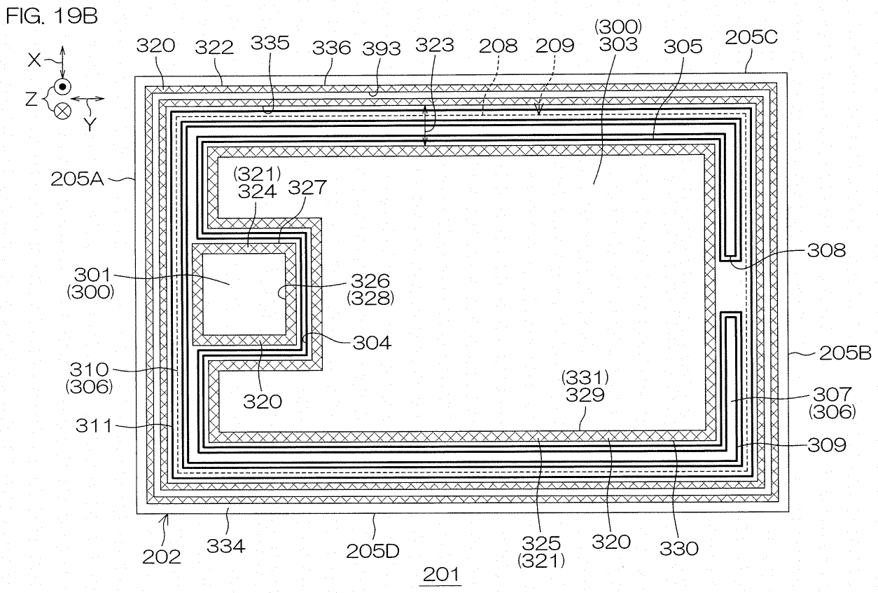

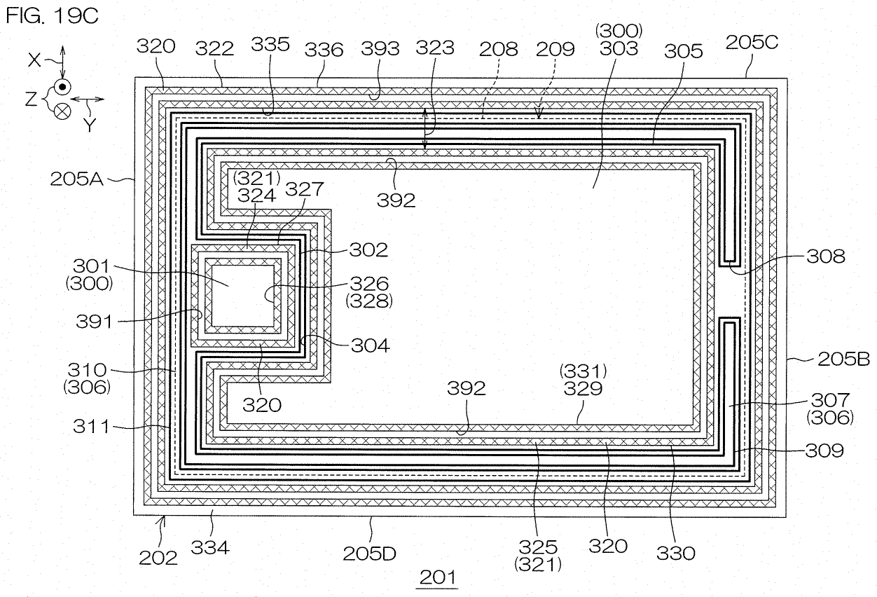

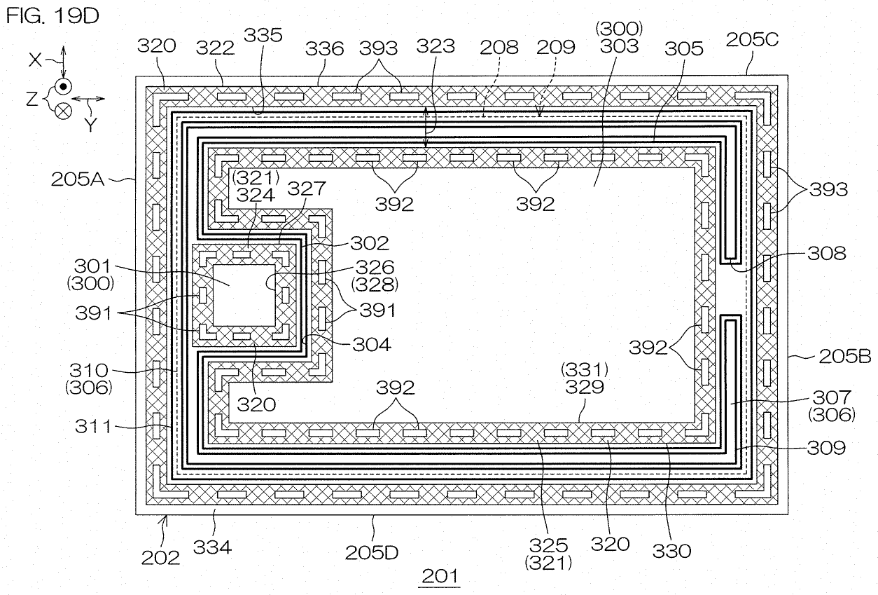

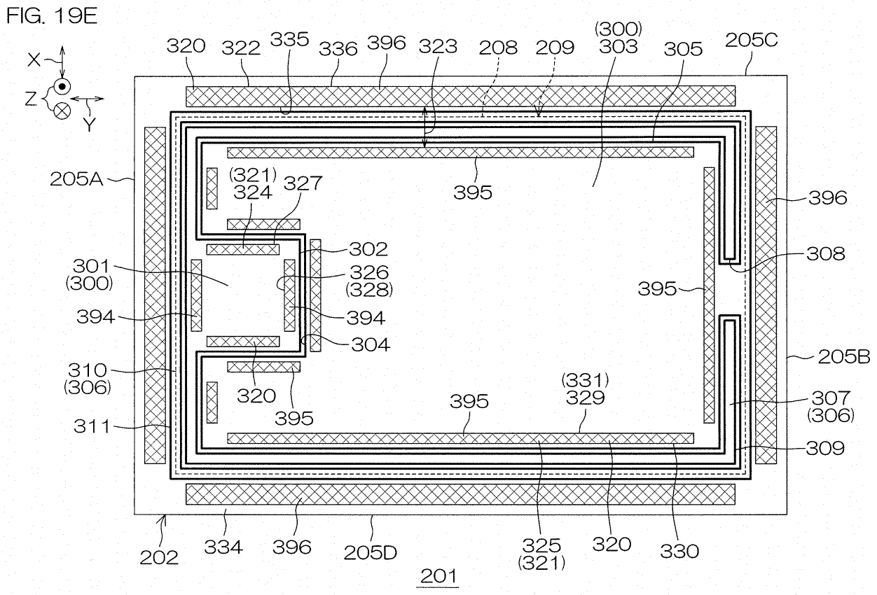

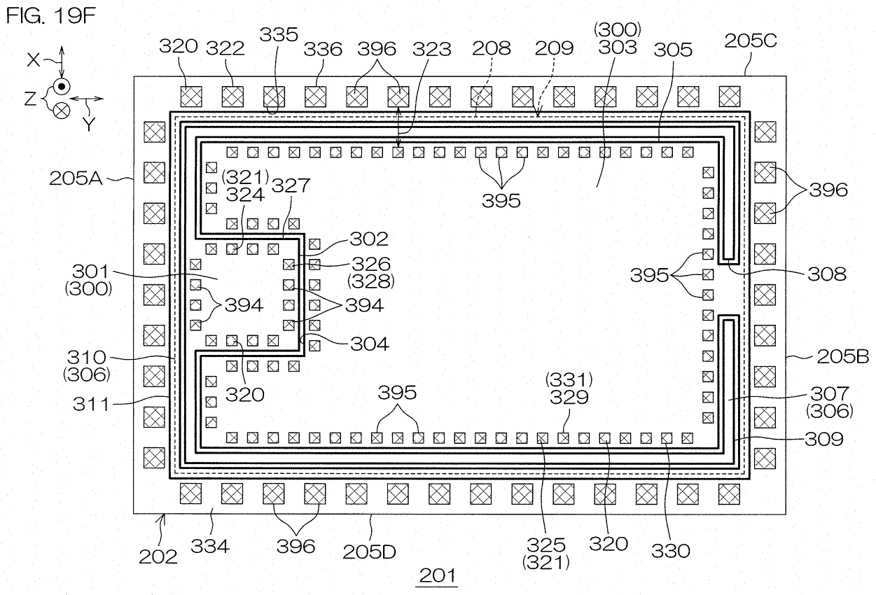

Even with the SiC semiconductor device 201 described above, the same effects as the effects described for the SiC semiconductor device 1 are exhibited. The second inorganic insulating film 320 can take on any of the various forms shown in FIG. 19A to FIG. 19F.

FIG. 19A is a plan view corresponding to FIG. 12 of the internal structure of the SiC semiconductor device 201 shown together with the second inorganic insulating film 320 according to a second configuration example. In the following, structures corresponding to the structures shown in FIG. 11 to FIG. 18 are provided with the same reference symbols and description thereof is omitted.

Referring to FIG. 19A, the first inner covering portion 324 of the second inorganic insulating film 320 has a first inner opening portion 391 that exposes the gate main surface electrode 301. The first inner opening portion 391 is formed in an inner portion of the first inner covering portion 324 at intervals from the first inner wall portion 326 and the first outer wall portion 327. The first inner opening portion 391 is formed as a band extending along the first inner wall portion 326 and the first outer wall portion 327. In this embodiment, the first inner opening portion 391 is formed to an annular shape (specifically, a quadrilateral annular shape) that extends along the first inner wall portion 326 and the first outer wall portion 327.

The second inner covering portion 325 of the second inorganic insulating film 320 has a second inner opening portion 392 that exposes the source main surface electrode 303. The second inner opening portion 392 is formed in an inner portion of the second inner covering portion 325 at intervals from the second inner wall portion 329 and the second outer wall portion 330. The second inner opening portion 392 is formed as a band extending along the second inner wall portion 329 and the second outer wall portion 330. In this embodiment, the second inner opening portion 392 is formed to an annular shape (specifically, a polygonal annular shape) that extends along the second inner wall portion 329 and the second outer wall portion 330.

The organic insulating film 340 enters into the first inner opening portion 391 from above the first inner covering portion 324 and covers a portion of the gate main surface electrode 301 that is exposed from the first inner opening portion 391. The organic insulating film 340 enters into the second inner opening portion 392 from above the second inner covering portion 325 and covers a portion of the source main surface electrode 303 that is exposed from the second inner opening portion 392.

Of the organic insulating film 340, a portion that is positioned inside the first inner opening portion 391 and a portion that is positioned inside the second inner opening portion 392 respectively form anchor portions. Thereby, at portions covering the plurality of first main surface electrodes 300, a contact area of the organic insulating film 340 with respect to the second inorganic insulating film 320 is increased and peeling of the organic insulating film 340 from the second inorganic insulating film 320 can be suppressed.

With this embodiment, an example where the first inner covering portion 324 includes the first inner opening portion 391 and the second inner covering portion 325 includes the second inner opening portion 392 was described. However, a structure where the first inner covering portion 324 includes the first inner opening portion 391 and the second inner covering portion 325 does not include the second inner opening portion 392 may be adopted instead. A structure where, in opposition to the above, the second inner covering portion 325 includes the second inner opening portion 392 while the first inner covering portion 324 does not include the first inner opening portion 391 may be adopted as well.

FIG. 19B is a plan view corresponding to FIG. 12 of the internal structure of the SiC semiconductor device 201 shown together with the second inorganic insulating film 320 according to a third configuration example. In the following, structures corresponding to the structures shown in FIG. 11 to FIG. 18 are provided with the same reference symbols and description thereof is omitted.

Referring to FIG. 19B, the outer covering portion 322 of the second inorganic insulating film 320 has an outer opening portion 393 that exposes the first inorganic insulating film 280. The outer opening portion 393 is formed in an inner portion of the outer covering portion 322 at intervals from the third inner wall portion 335 and the third outer wall portion 336. The outer opening portion 393 is formed as a band extending along the third inner wall portion 335 and the third outer wall portion 336. In this embodiment, the outer opening portion 393 is formed to an annular shape (specifically, a quadrilateral annular shape) that extends along the third inner wall portion 335 and the third outer wall portion 336.

The organic insulating film 340 enters into the outer opening portion 393 from above the outer covering portion 322 and covers a portion of the first inorganic insulating film 280 that is exposed from the outer opening portion 393. A portion of the organic insulating film 340 that is positioned inside the outer opening portion 393 forms an anchor portion. Thereby, in a region outside the plurality of first main surface electrodes 300, the contact area of the organic insulating film 340 with respect to the second inorganic insulating film 320 is increased and peeling of the organic insulating film 340 from the second inorganic insulating film 320 can be suppressed.

FIG. 19C is a plan view corresponding to FIG. 12 of the internal structure of the SiC semiconductor device 201 shown together with the second inorganic insulating film 320 according to a fourth configuration example. In the following, structures corresponding to the structures shown in FIG. 11 to FIG. 18 are provided with the same reference symbols and description thereof is omitted.

Referring to FIG. 19C, the first inner covering portion 324 of the second inorganic insulating film 320 has the first inner opening portion 391 that exposes the gate main surface electrode 301 (see FIG. 19A). The second inner covering portion 325 of the second inorganic insulating film 320 has the second inner opening portion 392 that exposes the source main surface electrode 303 (see FIG. 19A). The outer covering portion 322 of the second inorganic insulating film 320 has the outer opening portion 393 that exposes the first inorganic insulating film 280 (see FIG. 19B).

Of the organic insulating film 340, a portion that is positioned inside the first inner opening portion 391, a portion that is positioned inside the second inner opening portion 392, and a portion that is positioned inside the outer opening portion 393 respectively form anchor portions. Thereby, at the portions covering the plurality of first main surface electrodes 300 and in the region outside the plurality of first main surface electrodes 300, the contact area of the organic insulating film 340 with respect to the second inorganic insulating film 320 is increased and peeling of the organic insulating film 340 from the second inorganic insulating film 320 can be suppressed.

FIG. 19D is a plan view corresponding to FIG. 12 of the internal structure of the SiC semiconductor device 201 shown together with the second inorganic insulating film 320 according to a fifth configuration example. In the following, structures corresponding to the structures shown in FIG. 11 to FIG. 18 are provided with the same reference symbols and description thereof is omitted.

Referring to FIG. 19D, the first covering portion 364 of the second inorganic insulating film 320 has a plurality of the first inner opening portions 391 that expose the gate main surface electrode 301. The plurality of first inner opening portions 391 are respectively formed in the inner portion of the first inner covering portion 324 at intervals from the first inner wall portion 326 and the first outer wall portion 327.

The plurality of first inner opening portions 391 are formed at intervals along the first inner wall portion 326 (first outer wall portion 327). In this embodiment, each first inner opening portion 391 is formed as a band extending along the first inner wall portion 326 in plan view. A planar shape of each first inner opening portion 391 is arbitrary. Each first inner opening portion 391 may be formed to a polygonal shape or a circular shape in plan view.

The second covering portion 374 of the second inorganic insulating film 320 has a plurality of the second inner opening portions 392 that expose the source main surface electrode 303. The plurality of second inner opening portions 392 are respectively formed in the inner portion of the second inner covering portion 325 at intervals from the second inner wall portion 329 and the second outer wall portion 330. The plurality of second inner opening portions 392 are formed at intervals along the second inner wall portion 329 (second outer wall portion 330). In this embodiment, each second inner opening portion 392 is formed as a band extending along the second inner wall portion 329 in plan view. A planar shape of each second inner opening portion 392 is arbitrary. Each second inner opening portion 392 may be formed to a polygonal shape or a circular shape in plan view.

The outer covering portion 322 of the second inorganic insulating film 320 has a plurality of the outer opening portions 393 that expose the first inorganic insulating film 280. The plurality of outer opening portions 393 are respectively formed in the inner portion of the outer covering portion 322 at intervals from the third inner wall portion 335 and the third outer wall portion 336. The plurality of outer opening portions 393 are formed at intervals along the third inner wall portion 335 (third outer wall portion 336). In this embodiment, each outer opening portion 393 is formed as a band extending along the third inner wall portion 335 in plan view. A planar shape of each outer opening portion 393 is arbitrary. Each outer opening portion 393 may be formed to a polygonal shape or a circular shape in plan view.

Of the organic insulating film 340, portions that are positioned inside the plurality of first inner opening portions 391, portions that are positioned inside the plurality of second inner opening portions 392, and portions that are positioned inside the plurality of outer opening portions 393 respectively form anchor portions. Thereby, at the portions covering the plurality of first main surface electrodes 300 and in the region outside the plurality of first main surface electrodes 300, the contact area of the organic insulating film 340 with respect to the second inorganic insulating film 320 is increased and peeling of the organic insulating film 340 from the second inorganic insulating film 320 can be suppressed.

With this embodiment, an example where the second inorganic insulating film 320 has the plurality of first inner opening portions 391, the plurality of second inner opening portions 392, and the plurality of outer opening portions 393 was described. However, the second inorganic insulating film 320 may have just one or two of any of the plurality of first inner opening portions 391, the plurality of second inner opening portions 392, and the plurality of outer opening portions 393.

FIG. 19E is a plan view corresponding to FIG. 12 of the internal structure of the SiC semiconductor device 201 shown together with the second inorganic insulating film 320 according to a sixth configuration example. In the following, structures corresponding to the structures shown in FIG. 11 to FIG. 18 are provided with the same reference symbols and description thereof is omitted.

Referring to FIG. 19E, the first inner covering portion 324 of the second inorganic insulating film 320 is formed on the gate main surface electrode 301 such as to expose corner portions (four corners) of the gate main surface electrode 301. Specifically, the first inner covering portion 324 has a form where corner portions (four corners) of the first inner covering portion 324 according to the first configuration example (see FIG. 12) are eliminated and exposes the corner portions (four corners) of the gate main surface electrode 301. That is, the first inner covering portion 324 includes a plurality of first inner segment portions 394 that are formed at intervals on the gate main surface electrode 301. The respective first inner covering portion 324 are formed in a one-to-one correspondence relationship with respect to respective sides of the gate electrode side wall 302 and extend as bands along the respective sides of the gate electrode side wall 302.

The second inner covering portion 325 of the second inorganic insulating film 320 is formed on the source main surface electrode 303 such as to expose corner portions (four corners) of the source main surface electrode 303. Specifically, the second inner covering portion 325 has a form where corner portions (four corners) of the second inner covering portion 325 according to the first configuration example (see FIG. 12) are eliminated and exposes the corner portions (four corners) of the source main surface electrode 303. That is, the second inner covering portion 325 includes a plurality of second inner segment portions 395 that are formed at intervals on the source main surface electrode 303. The respective second inner segment portions 395 are formed in a one-to-one correspondence relationship with respect to respective sides of the source electrode side wall 305 and extend as bands along the respective sides of the source electrode side wall 305.

The outer covering portion 322 of the second inorganic insulating film 320 is formed on the first inorganic insulating film 280 such as to expose portions of the first inorganic insulating film 280 along the corner portions of the source wiring electrode 310. Specifically, the outer covering portion 322 has a form where corner portions (four corners) of the outer covering portion 322 according to the first configuration example (see FIG. 12) are eliminated and exposes the portions of the first inorganic insulating film 280 along the corner portions (four corners) of the source wiring electrode 310. That is, the outer covering portion 322 includes a plurality of outer segment portions 396 that are formed on the first inorganic insulating film 280. The respective outer segment portions 396 are formed in a one-to-one correspondence relationship with respect to the respective sides of the source wiring electrode 310 and extend as bands along the respective sides of the source wiring electrode 310.

The organic insulating film 340 covers the plurality of first inner segment portions 394 on the gate main surface electrode 301. Also, the organic insulating film 340 covers the corner portions (four corners) of the gate main surface electrode 301. The organic insulating film 340 covers the plurality of second inner segment portions 395 on the source main surface electrode 303. Also, the organic insulating film 340 covers the corner portions (four corners) of the source main surface electrode 303. The organic insulating film 340 covers the plurality of outer segment portions 396 of the outer covering portion 322 on the outer surface 207.

Even according to such a structure, the contact area of the organic insulating film 340 with respect to the second inorganic insulating film 320 is increased and therefore, peeling of the organic insulating film 340 from the second inorganic insulating film 320 can be suppressed. Stresses due to thermal expansion tend to concentrate at the corner portions (four corners) of the gate main surface electrode 301 and at the corner portions (four corners) of the source main surface electrode 303. Therefore, by forming the second inorganic insulating film 320 such as to expose the corner portions (four corners) of the gate main surface electrode 301 and the corner portions (four corners) of the source main surface electrode 303, influences of the stresses of the gate main surface electrode 301 and the source main surface electrode 303 on the second inorganic insulating film 320 can be reduced.

The first inner covering portion 324 may have just one first inner segment portion 394 that is formed to a shape with ends. The second inner covering portion 325 may have just one second inner segment portion 395 that is formed to a shape with ends. The outer covering portion 322 may have just one outer segment portion 396 that is formed to a shape with ends.

Also, the second inner covering portion 325 may have at least one second inner segment portion 395 while the first inner covering portion 324 does not have the first inner segment portion 394. Also, the first inner covering portion 324 may have at least one first inner segment portion 394 while the second inner covering portion 325 does not have the second inner segment portion 395. In these cases, the outer covering portion 322 may have at least one outer segment portion 396 or may not have the outer segment portion 396.

FIG. 19F is a plan view corresponding to FIG. 12 of the internal structure of the SiC semiconductor device 201 shown together with the second inorganic insulating film 320 according to a seventh configuration example. In the following, structures corresponding to the structures shown in FIG. 11 to FIG. 18 are provided with the same reference symbols and description thereof is omitted.

Referring to FIG. 19F, as with the first inner covering portion 324 according to the sixth configuration example, the first inner covering portion 324 of the second inorganic insulating film 320 includes a plurality of the first inner segment portions 394 that expose the corner portions (four corners) of the gate main surface electrode 301. In this embodiment, the plurality of first inner segment portions 394 are formed in a multiple-to-one correspondence relationship with respect to each side of the gate electrode side wall 302 and are formed at intervals along each side of the gate electrode side wall 302. A planar shape of each first inner segment portion 394 is arbitrary. Each first inner segment portion 394 may be formed to a quadrilateral shape, a polygonal shape, a circular shape, etc., in plan view.

As with the second inner covering portion 325 according to the sixth configuration example, the second inner covering portion 325 of the second inorganic insulating film 320 includes a plurality of the second inner segment portions 395 that expose the corner portions (four corners) of the source main surface electrode 303. In this embodiment, the plurality of second inner segment portions 395 are formed in a multiple-to-one correspondence relationship with respect to each side of the source main surface electrode 303 and are formed at intervals along each side of the source main surface electrode 303. A planar shape of each second inner segment portion 395 is arbitrary. Each second inner segment portion 395 may be formed to a quadrilateral shape, a polygonal shape, a circular shape, etc., in plan view.

As with the outer covering portion 322 according to the sixth configuration example, the outer covering portion 322 of the second inorganic insulating film 320 includes a plurality of the outer segment portions 396 that expose the portions of the first inorganic insulating film 280 along the corner portions of the source wiring electrode 310. In this embodiment, the plurality of outer segment portions 396 are formed in a multiple-to-one correspondence relationship with respect to each side of the source wiring electrode 310 and are formed at intervals along each side of the source wiring electrode 310. A planar shape of each outer segment portion 396 is arbitrary. Each outer segment portion 396 may be formed to a quadrilateral shape, a polygonal shape, a circular shape, etc., in plan view.

The second inner covering portion 325 may have a plurality of second inner segment portions 395 while the first inner covering portion 324 does not have the first inner segment portion 394. Also, the first inner covering portion 324 may have a plurality of first inner segment portions 394 while the second inner covering portion 325 does not have the second inner segment portion 395. In these cases, the outer covering portion 322 may have a plurality of outer segment portions 396 or may not have the outer segment portion 396.

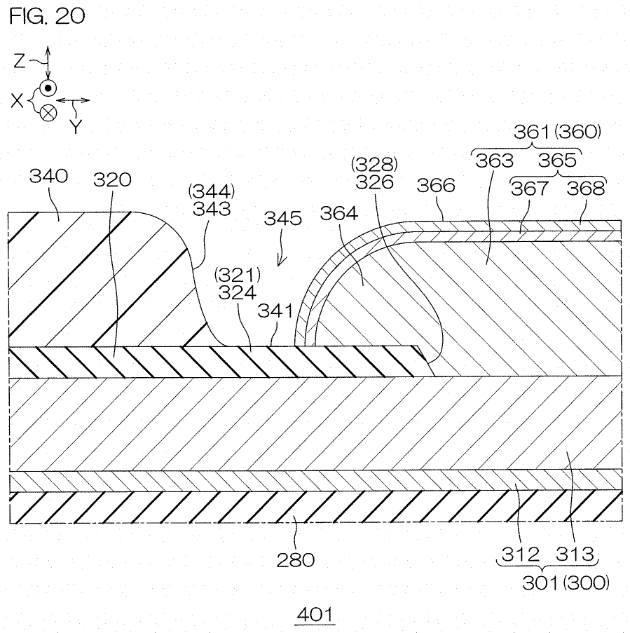

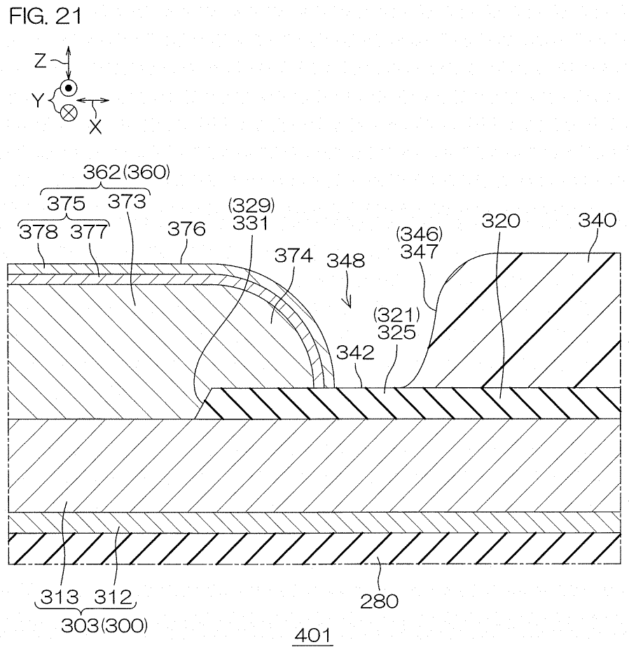

FIG. 20 is a sectional view corresponding to FIG. 17 for describing an SiC semiconductor device 401 according to a seventh preferred embodiment of the present invention. FIG. 21 is a sectional view corresponding to FIG. 18 for describing the SiC semiconductor device 401 shown in FIG. 20. In the following, structures corresponding to the structures described for the SiC semiconductor device 201 are provided with the same reference symbols and description thereof is omitted.

Referring to FIG. 20, with the SiC semiconductor device 401 according to the seventh preferred embodiment, the first covering portion 364 of the first Ni plating film 363 covers the first edge portion 341 of the first inner covering portion 324 at an interval from the fourth inner wall portion 343 of the organic insulating film 340. On the first inner covering portion 324, the first covering portion 364 is formed to an arcuate shape directed toward the fourth inner wall portion 343 with the first inner wall portion 326 as a starting point. In this embodiment, the thickness of the first Ni plating film 363 is less than the sum of the thickness of the second inorganic insulating film 320 and the exposed width of the first edge portion 341.

This is one condition for the first Ni plating film 363 not to be in contact with the fourth inner wall portion 343. On the other hand, in this embodiment, the first outer plating film 365 covers the first edge portion 341 at an interval from the fourth inner wall portion 343. The first outer plating film 365 exposes a portion of the first edge portion 341 and an entire area of the fourth inner wall portion 343.

Referring to FIG. 21, in this embodiment, the second covering portion 374 of the second Ni plating film 373 covers the second edge portion 342 of the second inner covering portion 325 at an interval from the fifth inner wall portion 346 of the organic insulating film 340. On the second inner covering portion 325, the second covering portion 374 is formed to an arcuate shape directed toward the fifth inner wall portion 346 with the second inner wall portion 329 as a starting point. In this embodiment, the thickness of the second Ni plating film 373 is less than the sum of the thickness of the second inorganic insulating film 320 and the exposed width of the second edge portion 342.

This is one condition for the second Ni plating film 373 not to be in contact with the fifth inner wall portion 346. On the other hand, in this embodiment, the second outer plating film 375 covers the second edge portion 342 at an interval from the fifth inner wall portion 346. The second outer plating film 375 exposes a portion of the second edge portion 342 and an entire area of the fifth inner wall portion 346.

Even with the SiC semiconductor device 401 described above, the same effects as the effects described for the SiC semiconductor device 1 are exhibited. Also, with the SiC semiconductor device 401 described above, the same effects as the effects described for the SiC semiconductor device 101 according to the second preferred embodiment are exhibited.

With this embodiment, an example where the first outer plating layer 365 that exposes the entire area of the fourth inner wall portion 343 is formed was described. However, the first outer plating layer 365 that exposes a portion of the fourth inner wall portion 343 may be formed instead. In this case, either or both of the first Pd plating film 367 and the first Au plating film 368 may cover a portion of the fourth inner wall portion 343.

With this embodiment, an example where the second outer plating layer 375 that exposes the entire area of the fifth inner wall portion 346 is formed was described. However, the second outer plating layer 375 that exposes a portion of the fifth inner wall portion 346 may be formed instead. In this case, either or both of the second Pd plating film 377 and the second Au plating film 378 may cover a portion of the fifth inner wall portion 346.

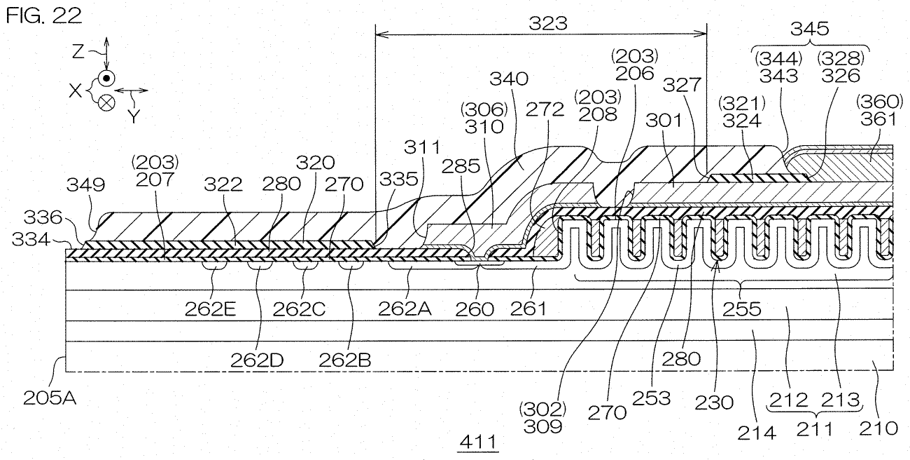

FIG. 22 is a sectional view corresponding to FIG. 15 for describing an SiC semiconductor device 411 according to an eighth preferred embodiment of the present invention. In the following, structures corresponding to the structures described for the SiC semiconductor device 201 are provided with the same reference symbols and description thereof is omitted.

Referring to FIG. 22, with the SiC semiconductor device 411 according to the eighth preferred embodiment, the main surface insulating film 270 and the first inorganic insulating film 280 are continuous to the peripheral edge of the first main surface 203 (first to fourth side surfaces 205A to 205D). Therefore, the main surface insulating film 270 and the first inorganic insulating film 280 do not expose the outer surface 207. In the second inorganic insulating film 320, an entirety of the outer covering portion 322 is formed on the first inorganic insulating film 280. Together with the peripheral edge of the first main surface 203, the third outer wall portion 336 of the outer covering portion 322 demarcates the dicing street 334 that exposes a peripheral edge portion of the first inorganic insulating film 280.

Even with the SiC semiconductor device 411 described above, the same effects as the effects described for the SiC semiconductor device 1 are exhibited.

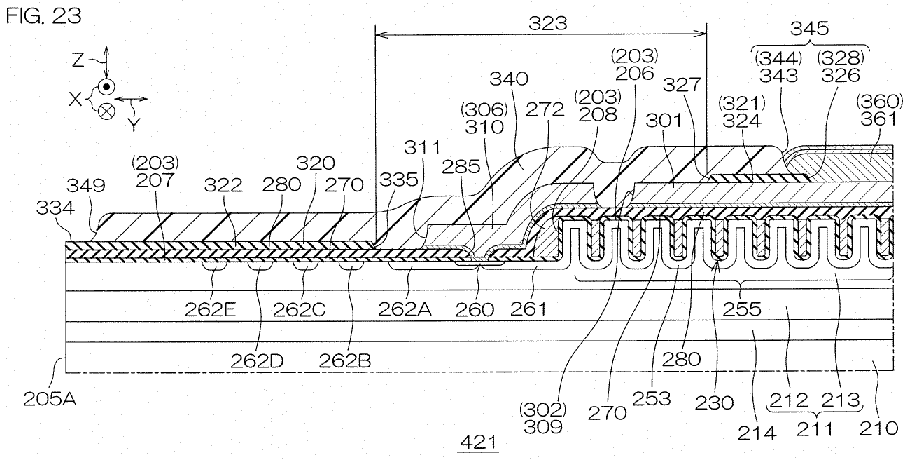

FIG. 23 is a sectional view corresponding to FIG. 15 for describing an SiC semiconductor device 421 according to a ninth preferred embodiment of the present invention. In the following, structures corresponding to the structures described for the SiC semiconductor device 201 are provided with the same reference symbols and description thereof is omitted.

Referring to FIG. 23, with the SiC semiconductor device 421 according to the ninth preferred embodiment, the main surface insulating film 270 and the first inorganic insulating film 280 are continuous to the peripheral edge of the first main surface 203 (first to fourth side surfaces 205A to 205D). Therefore, the main surface insulating film 270 and the first inorganic insulating film 280 do not expose the outer surface 207.

The second inorganic insulating film 320 (outer covering portion 322) is formed on the first inorganic insulating film 280 such as to be continuous to the peripheral edge of the first main surface 203 (first to fourth side surfaces 205A to 205D). Therefore, in this embodiment, the second inorganic insulating film 320 does not demarcate the dicing street 334 together with the peripheral edge of the first main surface 203. In this embodiment, the organic insulating film 340 (fourth outer wall portion 349) is formed at an interval inward from the peripheral edge of the first main surface 203 in plan view and the second inorganic insulating film 320 demarcates the dicing street 334.

Even with the SiC semiconductor device 421 described above, the same effects as the effects described for the SiC semiconductor device 1 are exhibited.

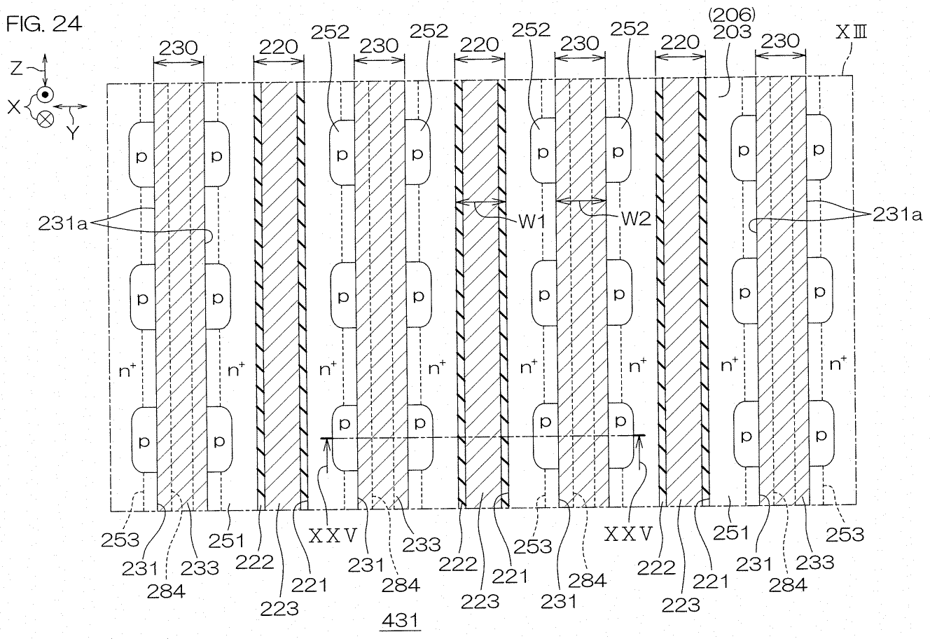

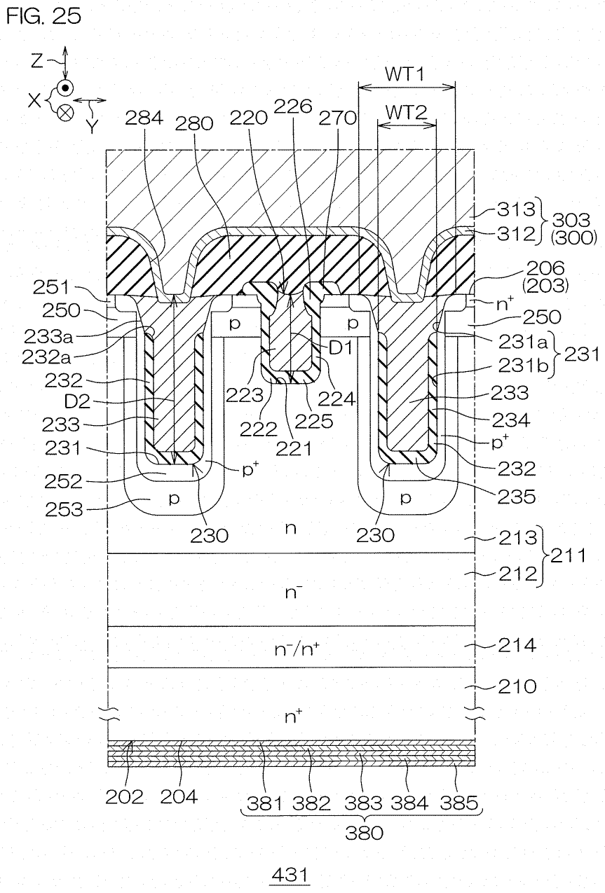

FIG. 24 is an enlarged view corresponding to FIG. 13 for describing an SiC semiconductor device 431 according to a tenth preferred embodiment of the present invention. FIG. 25 is a sectional view taken along line XXV-XXV shown in FIG. 24. In the following, structures corresponding to the structures described for the SiC semiconductor device 201 are provided with the same reference symbols and description thereof is omitted.

Referring to FIG. 24 and FIG. 25, the SiC semiconductor device 431 has second trench structures 230 that are constituted of a structure different from the second trench structures 230 according to the SiC semiconductor device 201. Specifically, each source trench 231 includes a first trench portion 231a at an opening side and a second trench portion 231b at the bottom wall side. The first trench portion 231a has a first trench width WT1 in the second direction Y. The first trench width WT1 is the second width W2 of the second trench structure 230. The first trench portion 231a may be formed to a convergent shape with which the first trench width WT1 narrows toward the bottom wall side.

The first trench portion 231a is preferably formed in a region at the active surface 206 side with respect to the bottom wall of each gate trench 221. That is, a depth of the first trench portion 231a is preferably less than the first depth D1 of each first trench structure 220. Obviously, the first trench portion 231a may be formed deeper than the first trench structure 220.

The second trench portion 231b is in communication with the first trench portion 231a and extends from the first trench portion 231a toward the bottom portion of the second semiconductor region 211. In this embodiment, the second trench portion 231b traverses the bottom wall of the first trench structure 220 in a-plane direction along the first main surface 203. The second trench portion 231b may be formed to a vertical shape having a substantially fixed opening width. The second trench portion 231b may be formed to a convergent shape having an opening width narrows toward the bottom wall.

A depth of the second trench portion 231b on the basis of the first trench portion 231a preferably exceeds the first depth D1 of the first trench structure 220. The second trench portion 231b has a second trench width WT2 that is less than the first trench width WT1 in the second direction Y (WT2<WT1).

The source insulating film 232 is formed as a film on the inner wall of the source trench 231 and demarcates the recess space inside the source trench 231. Specifically, the source insulating film 232 has a window portion 232a that exposes the first trench portion 231a and demarcates the recess space inside the second trench portion 231b.

Specifically, the source insulating film 232 includes the first portion 234 and the second portion 235 described above. The first portion 234 covers the side wall of the source trench 231 (second trench portion 231b) and demarcates the window portion 232a at the opening portion side (first trench portion 231a side) of the source trench 231. The second portion 235 covers the bottom wall of the source trench 231 (second trench portion 231b).

The source electrode 233 is embedded in the source trench 231 across the source insulating film 232. Specifically, the source electrode 233 is embedded in the first trench portion 231a and the second trench portion 231b across the source insulating film 232 and has a contact portion 233a that is in contact with the first trench portion 231a exposed from the window portion 232a.

In this embodiment, the body region 250 covers the first trench portion 231a of the second trench structure 230. The body region 250 is electrically connected to the contact portion 233a of the source electrode 233 that is exposed from the first trench portion 231a. The body region 250 is thereby source grounded inside the SiC chip 202. The body region 250 may cover a portion of the second trench portion 231b and face the source electrode 233 across a portion of the source insulating film 232.

In this embodiment, each source region 251 covers the first trench portion 231a of the second trench structure 230 and is electrically connected to the contact portion 233a of the source electrode 233. Each source region 251 is thereby source grounded inside the SiC chip 202.

In this embodiment, each contact region 252 is formed along the first trench portion 231a and the second trench portion 231b of each second trench structure 230. A portion of each contact region 252 that covers the first trench portion 231a is electrically connected to the contact portion 233a, the body region 250, and the source region 251. That is, each contact region 252 is source grounded inside the SiC chip 202. A portion of each contact region 252 that covers the second trench portion 231b faces the source electrode 233 across the source insulating film 232.

In this embodiment, each well region 253 covers each second trench structure 230 (first trench portion 231a and second trench portion 231b) across a plurality of the contact regions 252. That is, each well region 253 includes portions that directly cover the second trench structure 230 and portions that cover the second trench structure 230 across the contact regions 252.

A portion of each well region 253 that covers the first trench portion 231a is connected to the body region 250. That is, each contact region 252 is source grounded inside the SiC chip 202. Portions of the plurality of well regions 253 that cover the bottom walls of the plurality of second trench structures 230 (second trench portions 231b) are formed at a substantially fixed depth.

In this embodiment, in the active surface 206, the first inorganic insulating film 280 covers the plurality of first trench structures 220, the plurality of source regions 251, the plurality of contact regions 252, and the trench termination structures 255. Specifically, the first inorganic insulating film 280 covers entire areas of the source regions 251 and entire areas of the contact regions 252 in a sectional view along the second direction Y.

Also, the first inorganic insulating film 280 covers entire areas of the source regions 251 and entire areas of the contact regions 252 in plan view. Further, the first inorganic insulating film 280 is led out from above the active surface 206 onto the second trench structures 230 and cover edge portions of the source electrodes 233 (that is, the contact portions 233a). In this embodiment, the first inorganic insulating film 280 covers the edge portions of the source electrodes 233 along entire peripheries of the second trench structures 230.

In this embodiment, the plurality of source contact openings 284 expose the plurality of second trench structures 230 in a one-to-one correspondence relationship. Each source contact opening 284 is formed inside a region surrounded by the side wall of the second trench structure 230 in plan view. Specifically, each source contact opening 284 is formed at an interval inward from the side wall of the second trench structure 230 and exposes just the source electrode 233. Each source contact opening 284 may be formed as a band extending along each second trench structure 230.

In this embodiment, the source main surface electrode 303 enters into the plurality of source contact openings 284 from above the first inorganic insulating film 280 and is electrically connected to just the plurality of source electrodes 233. The source potential is thereby transmitted via the contact portions 233a of the plurality of source electrodes 233 to the body region 250, the plurality of source regions 251, the plurality of contact regions 252, and the plurality of well regions 253.

Other structures are the same as in the SiC semiconductor device 201 described above and description of those structures are omitted. Even with the SiC semiconductor device 431 described above, the same effects as the effects described for the SiC semiconductor device 201 are exhibited. Also, with the SiC semiconductor device 431, each source electrode 233 has the contact portion 233a that is exposed from the side wall of the source trench 231 in a region at the opening side of the source trench 231.

With such a structure, semiconductor regions to be source grounded can be source grounded inside the SiC chip 202 by the contact portions 233a of the source electrodes 233. In this embodiment, the body region 250, the source regions 251, the contact regions 252, and the well regions 253 are electrically connected to the source electrodes 233 inside the SiC chip 202. Such a structure is effective in terms of relaxing an alignment margin of the body region 250, the source regions 251, the contact regions 252, the well regions 253, the source contact openings 284, etc. The structure of the SiC semiconductor device 431 can also be applied to the seventh to ninth preferred embodiments.

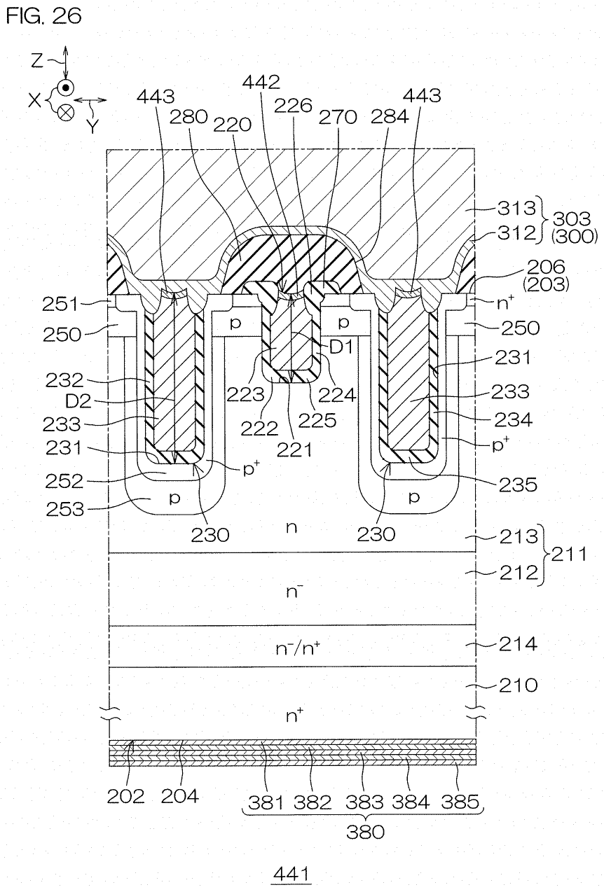

FIG. 26 is a sectional view corresponding to FIG. 14 for describing an SiC semiconductor device 441 according to an eleventh preferred embodiment of the present invention. In the following, structures corresponding to the structures described for the SiC semiconductor device 201 are provided with the same reference symbols and description thereof is omitted.

Referring to FIG. 26, the SiC semiconductor device 441 according to the eleventh preferred embodiment includes the gate electrodes 223 that include a p-type polysilicon doped with a p-type impurity. Specifically, the gate electrodes 223 are constituted of the p-type polysilicon. A p-type impurity concentration of the p-type polysilicon of the gate electrodes 223 may be not less than 1×10¹⁸ cm⁻³ and not more than 1×10²² cm⁻³. A sheet resistance of the gate electrodes 223 may be not less than 10Ω/□ and not more than 500 Ω/□.

The SiC semiconductor device 441 includes the source electrodes 233 that include the same conductive material as the gate electrodes 223. That is, the source electrodes 233 include the p-type polysilicon doped with the p-type impurity. Specifically, the source electrodes 233 are constituted of the p-type polysilicon. A p-type impurity concentration of the p-type polysilicon of the source electrodes 233 may be not less than 1×10¹⁸ cm⁻³ and not more than 1×10²² cm⁻³. A sheet resistance of the source electrodes 233 may be not less than 10Ω/□ and not more than 500 Ω/□.

The SiC semiconductor device 441 includes first low resistance layers 442 that cover the gate electrodes 223. Each first low resistance layer 442 covers the gate electrode 223 inside the gate trench 221. That is, the first low resistance layer 442 forms a portion of the first trench structure 220. Inside the gate trench 221, the first low resistance layer 442 is in contact with the gate insulating film 222. The first low resistance layer 442 is preferably in contact with a corner portion of the gate insulating film 222 (that is, the third portion 226).

The first low resistance layer 442 includes a conductive material having a sheet resistance less than the sheet resistance of the gate electrode 223. The sheet resistance of the first low resistance layer 442 may be not less than 0.01Ω/□ and not more than 10Ω/□. The first low resistance layer 442 preferably has a specific resistance of not less than 10 μΩ·cm and not more than 110 μΩ·cm. In this embodiment, the first low resistance layer 442 is constituted of a polycide layer (specifically, a p-type polycide layer) with which a surface layer portion of the gate electrode 223 is silicided with a metal. That is, the first low resistance layer 442 is formed integral to the gate electrode 223 at the surface layer portion of the gate electrode 223 and forms the electrode surface of the gate electrode 223.

The first low resistance layer 442 may include at least one among TiSi, TiSi₂, NiSi, CoSi, CoSi₂, MoSi₂, and WSi₂. The first low resistance layer 442 preferably includes at least one among NiSi, CoSi₂, and TiSi₂. The first low resistance layer 442 is especially preferably constituted of CoSi₂.

The SiC semiconductor device 441 includes second low resistance layers 443 that cover the source electrodes 233. Each second low resistance layer 443 covers the source electrode 233 inside the source trench 231. That is, the second low resistance layer 443 forms a portion of the second trench structure 230. Inside the source trench 231, the second low resistance layer 443 may be in contact with the source insulating film 232 (that is, the second portion 235).

The second low resistance layer 443 includes a conductive material having a sheet resistance less than the sheet resistance of the source electrode 233. The sheet resistance of the second low resistance layer 443 may be not less than 0.01Ω/□ and not more than 10Ω/□. The second low resistance layer 443 preferably has a specific resistance of not less than 10 μΩ·cm and not more than 110 μΩ·cm. In this embodiment, the second low resistance layer 443 is constituted of a polycide layer (specifically, a p-type polycide layer) with which a surface layer portion of the source electrode 233 is silicided with a metal. That is, the second low resistance layer 443 is formed integral to the source electrode 233 at the surface layer portion of the source electrode 233 and forms the electrode surface of the source electrode 233.

The second low resistance layer 443 may include at least one among TiSi, TiSi₂, NiSi, CoSi, CoSi₂, MoSi₂, and WSi₂. The second low resistance layer 443 preferably includes at least one among NiSi, CoSi₂, and TiSi₂. The second low resistance layer 443 is especially preferably constituted of CoSi₂. The second low resistance layer 443 is preferably constituted of the same material as the first low resistance layer 442. In such a structure, the p-type impurity concentration of the body region 250 is preferably less than the p-type impurity concentration of the gate electrodes 223 and the p-type impurity concentration of the source electrodes 233.

Even with the SiC semiconductor device 441 described above, the same effects as the effects described for the SiC semiconductor device 201 are exhibited. Also, the SiC semiconductor device 441 includes the gate electrodes 223 that include the p-type polysilicon and the first low resistance layers 442 that cover the gate electrodes 223.

By the gate electrodes 223 that include the p-type polysilicon, whereas a sheet resistance inside the gate trenches 221 is increased in comparison to a case of an n-type polysilicon, a gate threshold voltage Vth can be increased by approximately 1 V. By the first low resistance layers 442, a parasitic resistance inside the gate trenches 221 can be decreased while suppressing decrease in the gate threshold voltage Vth. Thus, with the SiC semiconductor device 441, the parasitic resistance inside the gate trenches 221 can be reduced while increasing the gate threshold voltage Vth.

The first low resistance layers 442 and the second low resistance layers 443 according to the SiC semiconductor device 441 can also be applied to the seventh to tenth preferred embodiments. When the first low resistance layers 442 and the second low resistance layers 443 are applied to the SiC semiconductor device 431 according to the tenth preferred embodiment, each second low resistance layer 443 forms, together with the source electrode 233, the contact portion 233a in contact with the first trench portion 231a. That is, the body region 250, the source regions 251, the contact regions 252, the well regions 253, etc., are respectively source grounded to the second low resistance layers 443 inside the SiC chip 202.

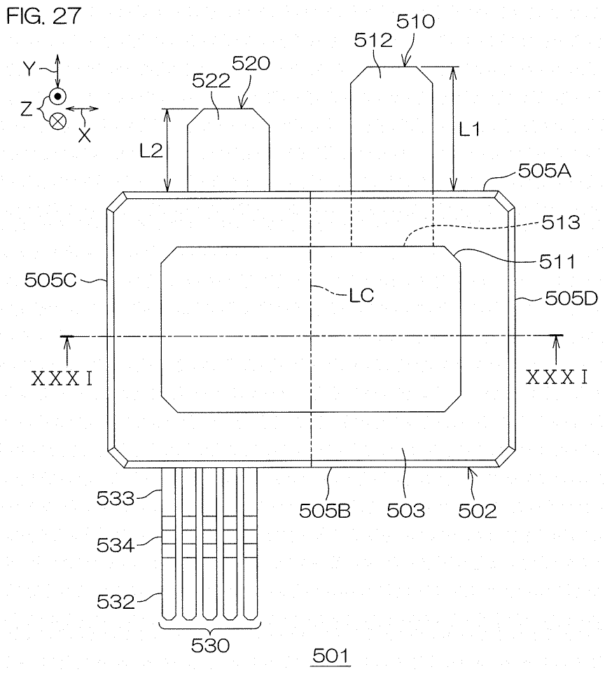

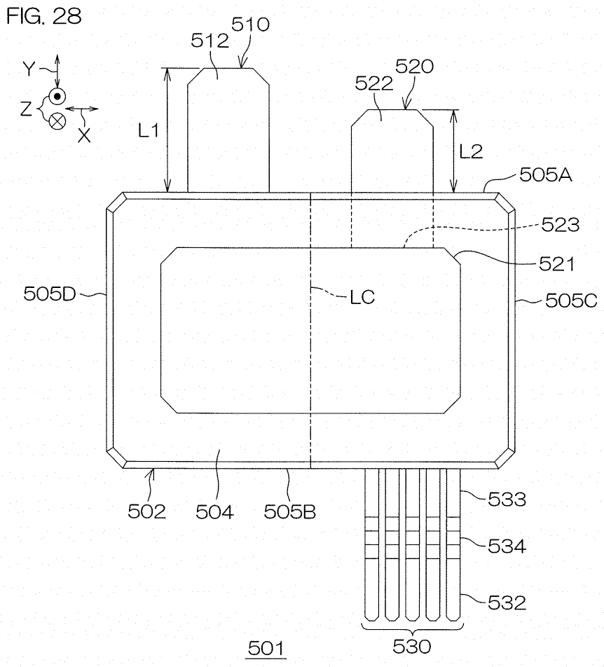

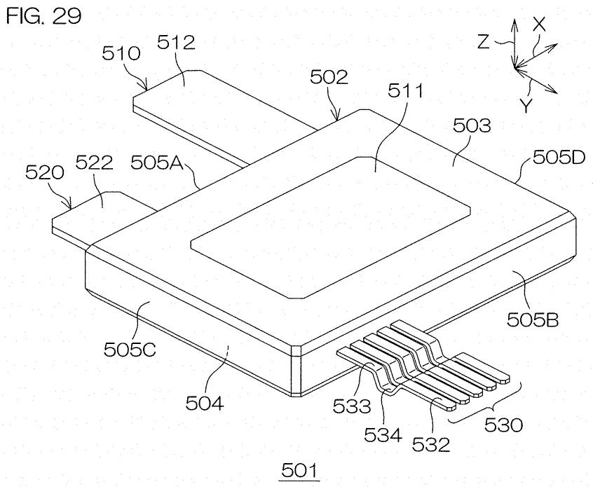

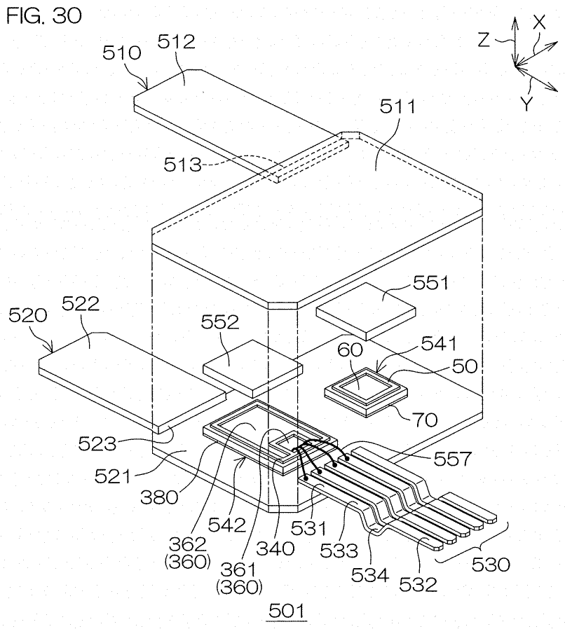

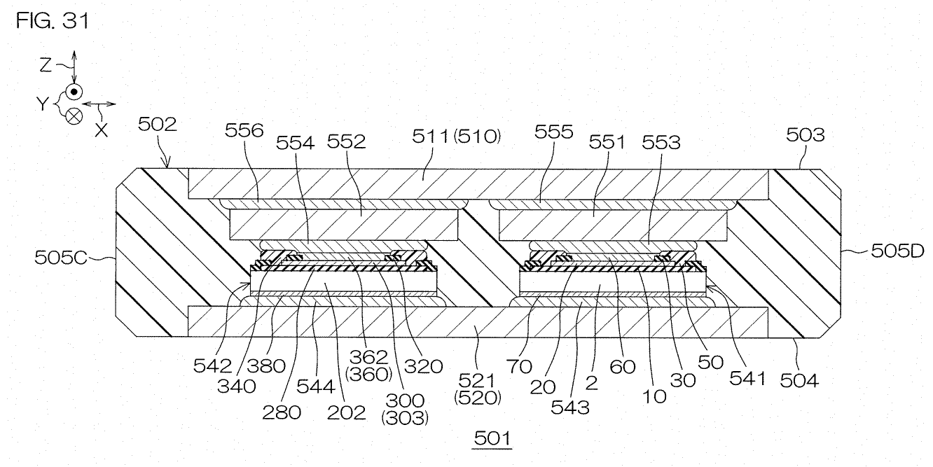

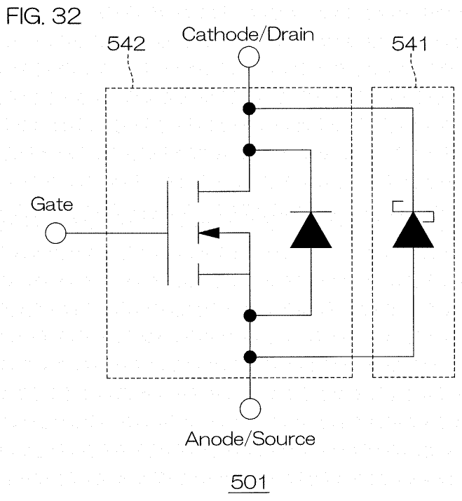

FIG. 27 is a plan view of a semiconductor package 501 as viewed from one side. FIG. 28 is a plan view of the semiconductor package 501 shown in FIG. 27 as viewed from another side. FIG. 29 is a perspective view of the semiconductor package 501 shown in FIG. 27. FIG. 30 is an exploded perspective view of the semiconductor package 501 shown in FIG. 27. FIG. 31 is a sectional view taken along line XXXI-XXXI shown in FIG. 27. FIG. 32 is a circuit diagram of the semiconductor package 501 shown in FIG. 27.

Referring to FIG. 27 to FIG. 32, in this embodiment, the semiconductor package 501 has a form called a power guard package. The semiconductor package 501 includes a package main body 502 that is made of resin. The package main body 502 is constituted of a molded resin that includes a filler (for example, an insulating filler) and a matrix resin. The matrix resin is preferably constituted of an epoxy resin.

The package main body 502 has a first main surface 503 (first surface) at one side, a second main surface 504 (second surface) at another side, and first to fourth side surfaces 505A to 505D that connect the first main surface 503 and the second main surface 504. The first main surface 503 and the second main surface 504 are formed to a quadrilateral shape (a rectangular shape in this embodiment) in a plan view as viewed from the normal direction Z to the surfaces.

The first side surface 505A and the second side surface 505B extend along the first direction X along the first main surface 503 and face each other in the second direction Y intersecting (specifically, orthogonal to) the first direction X. The first side surface 505A and the second side surface 505B form long sides of the package main body 502. The third side surface 505C and the fourth side surface 505D extend along the second direction Y and face each other in the first direction X. The third side surface 505C and the fourth side surface 505D form short sides of the package main body 502.

The semiconductor package 501 includes a first metal plate 510 that is arranged inside the package main body 502. The first metal plate 510 is arranged at the first main surface 503 side of the package main body 502 and integrally includes a first heat dissipating portion 511 and a first terminal portion 512. The first heat dissipating portion 511 is arranged inside the package main body 502 such as to be exposed from the first main surface 503. The first heat dissipating portion 511 has a plane area that is less than a plane area of the first main surface 503 and is exposed from the first main surface 503 at intervals inward from the first to fourth side surfaces 505A to 505D. The first heat dissipating portion 511 is formed to a rectangular shape extending in the first direction X in plan view.

The first terminal portion 512 is led out as a band extending in the second direction Y from the first heat dissipating portion 511 such as to penetrate through the first side surface 505A and extends between an interior and an exterior of the package main body 502. When a central line LC that traverses a central portion of the first side surface 505A (second side surface 505B) in the second direction Y is set, the first heat dissipating portion 511 is arranged at the fourth side surface 505D side with respect to the central line LC.

The first terminal portion 512 has a first length L1 in the second direction Y. A width in the first direction X of the first terminal portion 512 is less than a width in the first direction X of the first heat dissipating portion 511. Inside the package main body 502, the first terminal portion 512 is connected to the first heat dissipating portion 511 via a first bent portion 513 that is bent from the first main surface 503 side to the second main surface 504 side. Thereby, the first terminal portion 512 is exposed from the first side surface 505A at an interval toward the second main surface 504 side from the first main surface 503.

The semiconductor package 501 includes a second metal plate 520 that is arranged inside the package main body 502. The second metal plate 520 integrally includes a second heat dissipating portion 521 and a second terminal portion 522 and is arranged at the second main surface 504 side of the package main body 502 at an interval from the first metal plate 510. The second heat dissipating portion 521 is arranged inside the package main body 502 such as to be exposed from the second main surface 504.

The second heat dissipating portion 521 has a plane area that is less than a plane area of the second main surface 504 and is exposed from the second main surface 504 at intervals inward from the first to fourth side surfaces 505A to 505D. The second heat dissipating portion 521 is formed to a rectangular shape extending in the first direction X in plan view. The second terminal portion 522 is led out as a band extending in the second direction Y from the second heat dissipating portion 521 such as to penetrate through the first side surface 505A and extends between the interior and the exterior of the package main body 502. The second terminal portion 522 is arranged at the third side surface 505C side with respect to the central line LC.

In this embodiment, the second terminal portion 522 has a second length L2 in the second direction Y that differs from the first length L1 of the first terminal portion 512. The first terminal portion 512 and the second terminal portion 522 are identified by the shapes (lengths) thereof. The second length L2 of the second terminal portion 522 may exceed the first length L1 or may be less than the first length L1. Obviously, the second terminal portion 522 that has the second length L2 that is equal to the first length L1 may be formed instead.

A width in the first direction X of the second terminal portion 522 is less than a width in the first direction X of the second heat dissipating portion 521. Inside the package main body 502, the second terminal portion 522 is connected to the second heat dissipating portion 521 via a second bent portion 523 that is bent from the second main surface 504 side to the first main surface 503 side. Thereby, the second terminal portion 522 is exposed from the second side surface 505B at an interval toward the first main surface 503 side from the second main surface 504.

In the normal direction Z, the second terminal portion 522 is led out from a thickness position differing from the first terminal portion 512. In this embodiment, the second terminal portion 522 is formed at an interval toward the second main surface 504 side from the first terminal portion 512. The second terminal portion 522 does not face the first terminal portion 512 in the first direction X.

The semiconductor package 501 includes one or a plurality (five in this embodiment) of control terminals 530 that are arranged inside the package main body 502. The plurality of control terminals 530 are exposed from the second side surface 505B at an opposite side to the first side surface 505A at which the first terminal portion 512 and the second terminal portion 522 are exposed. The plurality of control terminals 530 are arranged at the third side surface 505C side with respect to the central line LC. The plurality of control terminals 530 are arranged on the same rectilinear line as the second terminal portion 522 of the second metal plate 520 in plan view. The positioning of the plurality of control terminals 530 is arbitrary.

The plurality of control terminals 530 are respectively formed as bands extending in the second direction Y. Specifically, the plurality of control terminals 530 each include an inner end portion 531, an outer end portion 532, and a lead portion 533. The inner end portion 531 is arranged inside the package main body 502. The outer end portion 532 is arranged outside the package main body 502.

The lead portion 533 is led out from the interior of the package main body 502 to the exterior of the package main body 502 such as to penetrate through the second side surface 505B and connects the inner end portion 531 and the outer end portion 532 at the interior and the exterior of the package main body 502. The lead portion 533 may have a curved portion 534 that is depressed toward the first main surface 503 and/or the second main surface 504 at a portion positioned outside the package main body 502. Obviously, the lead portion 533 not having the curved portion 534 may be formed instead.

In the normal direction Z, the plurality of control terminals 530 are led out from a thickness position differing from the first heat dissipating portion 511 and the second heat dissipating portion 521. In this embodiment, the plurality of control terminals 530 are arranged in a region between the first heat dissipating portion 511 and the second heat dissipating portion 521 at intervals from the first heat dissipating portion 511 and the second heat dissipating portion 521.

The semiconductor package 501 includes an SBD chip 541 that is arranged inside the package main body 502. The SBD chip 541 is constituted of any one of the SiC semiconductor devices (reference signs omitted) according to the first to fifth preferred embodiments. The SBD chip 541 is arranged in a space inside the package main body 502 that is sandwiched by the first heat dissipating portion 511 and the second heat dissipating portion 521. In this embodiment, the SBD chip 541 is arranged on the second heat dissipating portion 521 in an orientation in which the second main surface electrode 70 is made to face the second heat dissipating portion 521. The SBD chip 541 is arranged at the fourth side surface 505D side of the package main body 502 with respect to the central line LC.

The semiconductor package 501 includes a MISFET chip 542 that is arranged inside the package main body 502 at an interval from the SBD chip 541. The MISFET chip 542 is constituted of any one of the SiC semiconductor devices (reference signs omitted) according to the sixth to eleventh preferred embodiments. The MISFET chip 542 is arranged in a space inside the package main body 502 that is sandwiched by the first heat dissipating portion 511 and the second heat dissipating portion 521. In this embodiment, the MISFET chip 542 is arranged on the second heat dissipating portion 521 in an orientation in which the second main surface electrode 380 is made to face the second heat dissipating portion 521. The MISFET chip 542 is arranged at the third side surface 505C side of the package main body 502 with respect to the central line LC.

The semiconductor package 501 includes a first conductive bonding material 543. The first conductive bonding material 543 is interposed between the second main surface electrode 70 of the SBD chip 541 and the second heat dissipating portion 521 and connects the SBD chip 541 to the second heat dissipating portion 521 thermally, mechanically, and electrically. The first conductive bonding material 543 may include solder or a metal paste.

The semiconductor package 501 includes a second conductive bonding material 544. The second conductive bonding material 544 is interposed between the second main surface electrode 380 of the MISFET chip 542 and the second heat dissipating portion 521 and connects the MISFET chip 542 to the second heat dissipating portion 521 thermally, mechanically, and electrically. The second conductive bonding material 544 may include solder or a metal paste.

The drain of the MISFET chip 542 is thereby electrically connected to the cathode of the SBD chip 541. That is, the second metal plate 520 (second terminal portion 522) functions as a cathode-drain terminal for the SBD chip 541 and the MISFET chip 542.

The semiconductor package 501 includes a first metal spacer 551. The first metal spacer 551 may include a plate shaped member that includes copper. The first metal spacer 551 is interposed between the SBD chip 541 and the first heat dissipating portion 511.

The semiconductor package 501 includes a second metal spacer 552. The first metal spacer 551 may include a plate shaped member that includes copper. The second metal spacer 552 preferably has a thickness that is substantially equal to a thickness of the first metal spacer 551. The second metal spacer 552 is provided at an interval from the first metal spacer 551 and is interposed between the MISFET chip 542 and the first heat dissipating portion 511. Although in this embodiment, the second metal spacer 552 is constituted of a separate member from the first metal spacer 551, the second metal spacer 552 may be formed integral to the first metal spacer 551.

The semiconductor package 501 includes a third conductive bonding material 553. The third conductive bonding material 553 is interposed between the pad electrode 60 of the SBD chip 541 and the first metal spacer 551 and connects the SBD chip 541 to the first metal spacer 551 thermally, mechanically, and electrically. The third conductive bonding material 553 may include solder or a metal paste. The third conductive bonding material 553 is preferably constituted of solder.

The semiconductor package 501 includes a fourth conductive bonding material 554. The fourth conductive bonding material 554 is interposed between the source pad electrode 362 of the MISFET chip 542 and the second metal spacer 552 and connects the MISFET chip 542 to the second metal spacer 552 thermally, mechanically, and electrically. The fourth conductive bonding material 554 may include solder or a metal paste. The fourth conductive bonding material 554 is preferably constituted of solder.

The semiconductor package 501 includes a fifth conductive bonding material 555. The fifth conductive bonding material 555 is interposed between the first heat dissipating portion 511 and the first metal spacer 551 and connects the first metal spacer 551 to the first heat dissipating portion 511 thermally, mechanically, and electrically. The fifth conductive bonding material 555 may include solder or a metal paste.

The semiconductor package 501 includes a sixth conductive bonding material 556. The sixth conductive bonding material 556 is interposed between the first heat dissipating portion 511 and the second metal spacer 552 and connects the second metal spacer 552 to the first heat dissipating portion 511 thermally, mechanically, and electrically. The sixth conductive bonding material 556 may include solder or a metal paste.

The source of the MISFET chip 542 is thereby electrically connected to the anode of the SBD chip 541. That is, the first metal plate 510 (first terminal portion 512) functions as an anode-source terminal for the SBD chip 541 and the MISFET chip 542.

The semiconductor package 501 includes one or a plurality (four in this embodiment) of lead wires 557. The lead wires 557 are also referred to as bonding wires. The lead wires 557 may include at least one of a gold wire, a copper wire, and an aluminum wire. The plurality of lead wires 557 are respectively connected to the inner end portions 531 of the plurality of control terminals 530 and the gate pad electrode 361 of the MISFET chip 542.

The gate of the MISFET chip 542 is thereby electrically connected to the plurality of control terminals 530. That is, the plurality of control terminals 530 respectively function as gate terminals of the MISFET chip 542. The lead wires 557 do not necessarily have to be connected to all of the control terminals 530 and the gate pad electrode 361. Any of the control terminals 530 may be electrically open.

With the semiconductor package 501 described above, the first conductive bonding material 543 is connected to the pad electrode 60 of the SBD chip 541. As described with the first to fifth preferred embodiments, the pad electrode 60 includes the Ni plating film 61. The first conductive bonding material 543 can thereby be connected appropriately to the pad electrode 60. The SBD chip 541 can thus be appropriately connected to the first heat dissipating portion 511 and the second heat dissipating portion 521 thermally, mechanically, and electrically. In particular, by the pad electrode 60 that includes the outer plating film 63, compatibility with respect to the first conductive bonding material 543 can be enhanced.

If the SBD chip 541 does not include the organic insulating film 50, cracking and peeling, etc., may occur in the first main surface electrode 20 and the pad electrode 60, etc., due to the filler included in the package main body 502. This type of problem is referred to as filler attack and is a factor of degradation of reliability of the first main surface electrode 20 and the pad electrode 60, etc. Thus, with the SBD chip 541, the organic insulating film 50 is formed. Thereby, the organic insulating film 50 becomes a cushion with respect to the filler and therefore, the first main surface electrode 20 and the pad electrode 60, etc., can be protected appropriately.

Further, as described with the first to fifth preferred embodiments, the SBD chip 541 has, in the structure including the organic insulating film 50, the structure where the Ni plating film 61 is connected to the edge portion 51 of the second inorganic insulating film 30. Cracking and peeling, etc., of the Ni plating film 61 (outer plating film 63) due to filler attack can thereby also be suppressed appropriately.

Also, with the semiconductor package 501, the second conductive bonding material 544 is connected to the source pad electrode 362 of the MISFET chip 542. As described with the sixth to eleventh preferred embodiments, the source pad electrode 362 includes the second Ni plating film 373. The second conductive bonding material 544 can thereby be connected appropriately to the source pad electrode 362. The MISFET chip 542 can thus be appropriately connected to the first heat dissipating portion 511 and the second heat dissipating portion 521 thermally, mechanically, and electrically. In particular, by the source pad electrode 362 that includes the second outer plating film 375, compatibility with respect to the second conductive bonding material 544 can be enhanced.

If the MISFET chip 542 does not include the organic insulating film 340, cracking and peeling, etc., may occur in the plurality of first main surface electrodes 300 and the source pad electrode 362, etc., of the MISFET chip 542 due to the filler included in the package main body 502. Thus, with the MISFET chip 542, the organic insulating film 340 is formed on the second inorganic insulating film 320. Thereby, the organic insulating film 340 becomes a cushion with respect to the filler and therefore, the plurality of first main surface electrodes 300 and the source pad electrode 362, etc., can be protected appropriately.

Further, as described with the sixth to eleventh preferred embodiments, the MISFET chip 542 has, in the structure including the organic insulating film 340, the structure where the second Ni plating film 373 is connected to the second inner covering portion 325 of the second inorganic insulating film 320. Cracking and peeling, etc., of the second Ni plating film 373 (second outer plating film 375) due to filler attack can thereby also be suppressed appropriately. With the MISFET chip 542, the same effects as the effects at the source pad electrode 362 side are also exhibited at the gate pad electrode 361 side.

With this embodiment, an example where the semiconductor package 501 includes the SBD chip 541 and the MISFET chip 542 was described. However, the semiconductor package 501 that includes just one of either of the SBD chip 541 and the MISFET chip 542 may be adopted instead. Also, the semiconductor package 501 that includes a plurality of the SBD chips 541 and/or a plurality of the MISFET chips 542 may be adopted instead.

The SBD chip 541 is not restricted to the semiconductor package 501 having the power guard form and may be installed in a TO (transistor outline), an SOP (small outline package), a QFN (quad flat non-lead package), a DFP (dual flat package), a DIP (dual inline package), a QFP (quad flat package), an SIP (single inline package), or an SOJ (small outline J-leaded package) or any of various packages related to these.

The MISFET chip 542 is not restricted to the semiconductor package 501 having the power guard form and may be installed in a TO (transistor outline), an SOP (small outline package), a QFN (quad flat non-lead package), a DFP (dual flat package), a DIP (dual inline package), a QFP (quad flat package), an SIP (single inline package), or an SOJ (small outline J-leaded package) or any of various packages related to these.

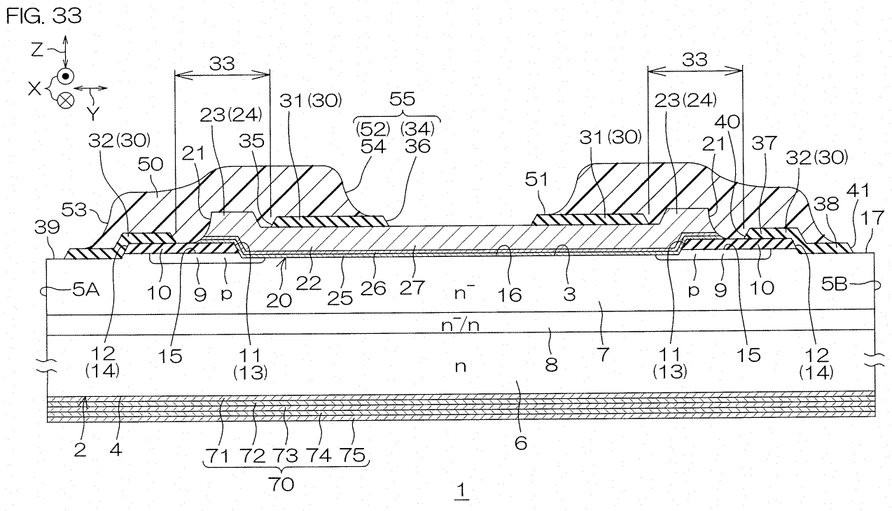

The preferred embodiments of the present invention can be implemented in yet other embodiments. With the first preferred embodiment described above, an example where the pad electrode 60 is formed as the terminal electrode on the first main surface electrode 20 was described. However, the SiC semiconductor device 1 according to the first preferred embodiment may have the form shown in FIG. 33. FIG. 33 is a sectional view corresponding to FIG. 3 for describing a modification example of the SiC semiconductor device 1 according to the first preferred embodiment. In the following, structures corresponding to the structures described for the SiC semiconductor device 1 are provided with the same reference symbols and description thereof is omitted.

Referring to FIG. 33, the SiC semiconductor device 1 according to the modification example does not have the pad electrode 60. In this case, the first main surface electrode 20 functions as the terminal electrode. Such an SiC semiconductor device 1 is manufactured by omitting the step of forming the pad electrode 60 described above (see FIG. 6K). Obviously, the form in which the pad electrode 60 is not present can also be applied to the second to fifth preferred embodiments besides the first preferred embodiment.

In each of the first to fifth preferred embodiments described above, an Si chip constituted of an Si monocrystal may be adopted in place of the SiC chip 2. That is, Si semiconductor devices may be adopted in place of the SiC semiconductor devices (reference signs omitted) according to the first to fifth preferred embodiments described above.

Although with each of the first to fifth preferred embodiments described above, an example where the first direction X is the m-axis direction of the SiC monocrystal and the second direction Y is the a-axis direction of the SiC monocrystal was described, the first direction X may be the a-axis direction of the SiC monocrystal and the second direction Y may be the m-axis direction of the SiC monocrystal instead. That is, the first side surface 5A and the second side surface 5B may be formed by m-planes of the SiC monocrystal and the third side surface 5C and the fourth side surface 5D may be formed by a-planes of the SiC monocrystal instead. In this case, the off direction may be the a-axis direction of the SiC monocrystal. A specific arrangement of this case is obtained by replacing the m-axis direction pertaining to the first direction X with the a-axis direction and replacing the a-axis direction pertaining to the second direction Y with the m-axis direction in the description above and the attached drawings.

Although with each of the first to fifth preferred embodiments described above, an example where the first conductivity type is the n-type and the second conductivity type is the p-type was described, the first conductivity type may be the p-type and the second conductivity type may be the n-type instead. A specific arrangement of this case is obtained by replacing the n-type regions with p-type regions and replacing the p-type regions with n-type regions in the description above and the attached drawings.

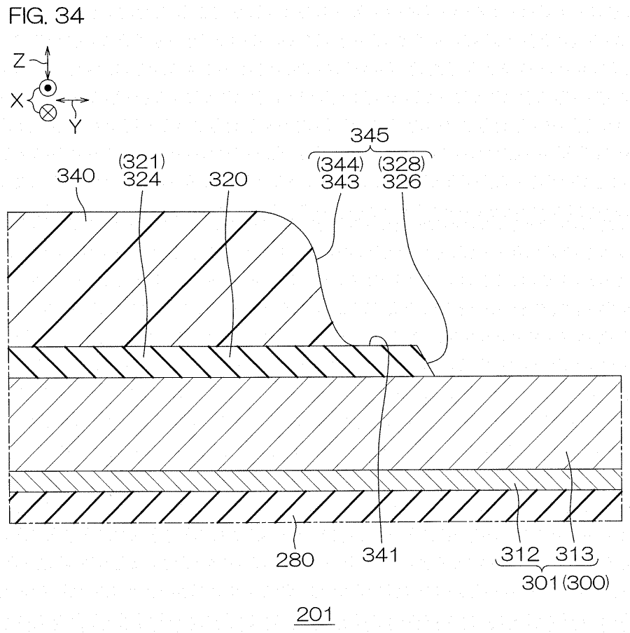

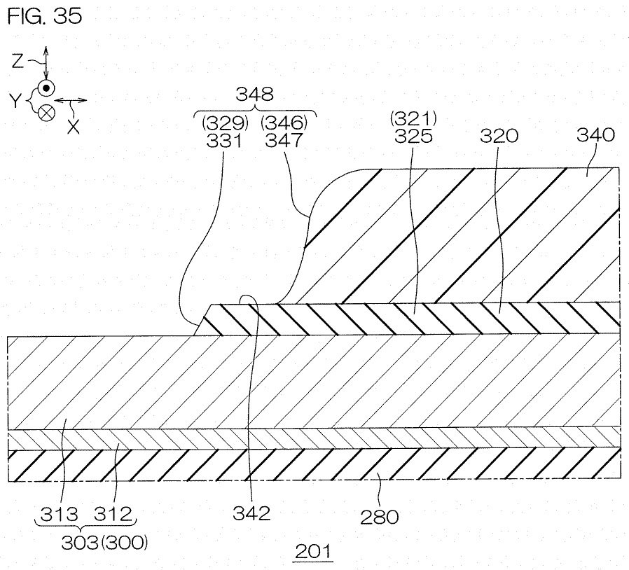

With the sixth preferred embodiment described above, an example where the plurality of pad electrodes 360 (the gate pad electrode 361 and the source pad electrode 362) are respectively formed as the terminal electrodes on the plurality of first main surface electrodes 300 (the gate main surface electrode 301 and the source main surface electrode 303) was described. However, the SiC semiconductor device 201 according to the sixth preferred embodiment may have the form shown in FIG. 34 and FIG. 35 instead. FIG. 34 and FIG. 35 are sectional views corresponding to FIG. 17 and FIG. 18, respectively, for describing a modification example of the SiC semiconductor device 201 according to the sixth preferred embodiment. In the following, structures corresponding to the structures described for the SiC semiconductor device 201 are provided with the same reference symbols and description thereof is omitted.

Referring to FIG. 34 and FIG. 35, the SiC semiconductor device 201 according to the modification example does not have the plurality of pad electrodes 360 (the gate pad electrode 361 and the source pad electrode 362). In this case, the plurality of first main surface electrodes 300 (the gate main surface electrode 301 and the source main surface electrode 303) respectively function as the terminal electrodes. Obviously, the form in which the plurality of pad electrodes 360 are not present can also be applied to the seventh to eleventh preferred embodiments besides the sixth preferred embodiment.

In each of the sixth to eleventh preferred embodiments described above, an Si chip constituted of an Si monocrystal may be adopted in place of the SiC chip 202. That is, Si semiconductor devices may be adopted in place of the SiC semiconductor devices (reference signs omitted) according to the sixth to eleventh preferred embodiments described above.

Although with each of the sixth to eleventh preferred embodiments described above, an example where the first direction X is the m-axis direction of the SiC monocrystal and the second direction Y is the a-axis direction of the SiC monocrystal was described, the first direction X may be the a-axis direction of the SiC monocrystal and the second direction Y may be the m-axis direction of the SiC monocrystal instead. That is, the first side surface 205A and the second side surface 205B (the two short sides of the SiC chip 202) may be formed by m-planes of the SiC monocrystal and the third side surface 205C and the fourth side surface 205D (the two long sides of the SiC chip 202) may be formed by a-planes of the SiC monocrystal instead. In this case, the off direction may be the a-axis direction of the SiC monocrystal. A specific arrangement of this case is obtained by replacing the m-axis direction pertaining to the first direction X with the a-axis direction and replacing the a-axis direction pertaining to the second direction Y with the m-axis direction in the description above and the attached drawings.

Although with each of the sixth to eleventh preferred embodiments described above, an example where the first conductivity type is the n-type and the second conductivity type is the p-type was described, the first conductivity type may be the p-type and the second conductivity type may be the n-type instead. A specific arrangement of this case is obtained by replacing the n-type regions with p-type regions and replacing the p-type regions with n-type regions in the description above and the attached drawings.

In the each of the sixth to eleventh preferred embodiments described above, the first semiconductor region 210 of the p-type (collector layer) may be adopted in place of the first semiconductor region 210 of the n-type (drain layer). With this structure, an IGBT (insulated gate bipolar transistor) can be provided in place of the MISFET. A specific arrangement of this case is obtained by replacing the “source” of the MISFET with an “emitter” of the IGBT and replacing the “drain” of the MISFET with a “collector” of the IGBT in the description above.

Examples of features extracted from the present description and drawings are indicated below. Each of [A1] to [A20], [B1] to [B15], [C1] to [C20], [D1] to [D19], [E1] to [E19], and [F1] to [F20] indicated below provides an electronic component that is capable of improving reliability. Examples of the type of electronic component include semiconductor devices that include Si (Si semiconductor devices) and semiconductor device that include SiC (SiC semiconductor devices).

[A1] An electronic component comprising: a covered object (10, 280); an electrode (20, 300, 301, 303) that covers the covered object (10, 280) and has an electrode side wall (21, 302, 305) on the covered object (10, 280); an inorganic insulating film (30, 320) that has an inner covering portion (31, 321, 324, 325) covering the electrode (20, 300, 301, 303) such as to expose the electrode side wall (21, 302, 305); and an organic insulating film (50, 340) that covers the electrode side wall (21, 302, 305).

An electronic component is used under various environments in accordance with application and is thus required to have durability adapted to various usage environmental conditions. The durability of an electronic component is evaluated, for example, by a high temperature/high humidity bias test. In the high temperature/high humidity bias test, electrical operation of the electronic component is evaluated in a state of being exposed to a high temperature/high humidity environment. Under a high temperature environment, stress due to thermal expansion of the electrode concentrates at a vicinity of the electrode side wall. If the inorganic insulating film covers the electrode side wall, there is a possibility for the inorganic insulating film to peel from the electrode side wall due to the stress of the electrode and reliability to degrade. If peeling of the inorganic insulating film occurs, then, under a high humidity environment, there is a possibility for the electrode, etc., to become oxidized due to water (moisture) entering into a peeled portion of the inorganic insulating film and reliability to degrade further.

Thus, with the electronic component described above, the inorganic insulating film that exposes the electrode side wall is formed. Peeling starting points of the inorganic insulating film due to the stress of the electrode can thereby be reduced. Consequently, peeling of the inorganic insulating film due to the stress of the electrode can be suppressed. The electrode can thus be protected appropriately by the inorganic insulating film. On the other hand, the organic insulating film covers the electrode side wall. The organic insulating film has a low hardness in comparison to the inorganic insulating film. Therefore, even if a stress arises in the electrode, the stress can be absorbed elastically. Peeling of the organic insulating film from the electrode side wall can thereby be suppressed. Consequently, the electrode side wall can be protected by the organic insulating film. The electronic component that can be improved in reliability can thus be provided. With this electronic component, reliability of the electrode and a periphery thereof is especially improved.

[A2] The electronic component according to A1, wherein the organic insulating film (50, 340) covers the inner covering portion (31, 321, 324, 325). With this structure, peeling of the inorganic insulating film from the electrode can be suppressed and therefore, peeling of the organic insulating film due to peeling of the inorganic insulating film can be suppressed. Therefore, by forming the organic insulating film that covers the inner covering portion, the electrode can be protected by both the inorganic insulating film and the organic insulating film.

[A3] The electronic component according to A1 or A2, wherein the inner covering portion (31, 321, 324, 325) exposes a peripheral edge portion of the electrode (20, 300, 301, 303), and the organic insulating film (50, 340) covers the peripheral edge portion of the electrode (20, 300, 301, 303). With this structure, influence of the stress of the electrode on the inner covering portion can be reduced. Also, the peripheral edge portion of the electrode can be protected by the organic insulating film.

[A4] The electronic component according to any one of A1 to A3, wherein the inner covering portion (31, 321, 324, 325) exposes an inner portion of the electrode (20, 300, 301, 303). With this structure, a contact portion of the electrode can be secured.

[A5] The electronic component according to A4, wherein the inner covering portion (31, 321, 324, 325) surrounds the inner portion of the electrode (20, 300, 301, 303). With this structure, the electrode can be protected appropriately by the inorganic insulating film while securing the contact portion.

[A6] The electronic component according to A4 or A5, wherein the organic insulating film (50, 340) exposes an edge portion (54, 343, 347) of the inner covering portion (31, 321, 324, 325) at the inner portion side of the electrode (20, 300, 301, 303).

[A7] The electronic component according to any one of A1 to A6, wherein the inorganic insulating film (30, 320) has an outer covering portion (32, 322) that covers the covered object (10, 280) such as to expose the electrode side wall (21, 302, 305). With this structure, peeling of the inorganic insulating film from the covered object due to the stress of the electrode can be suppressed in a region outside the electrode. The electrode can thereby be protected from the region outside the electrode by the inorganic insulating film.

[A8] The electronic component according to A7, wherein the organic insulating film (50, 340) covers the outer covering portion (32, 322). With this structure, peeling of the inorganic insulating film from the covered object can be suppressed and therefore, peeling of the organic insulating film due to peeling of the inorganic insulating film can be suppressed. Therefore, by forming the organic insulating film that covers the outer covering portion, the electrode can be protected by both the inorganic insulating film and the organic insulating film.

[A9] The electronic component according to A7 or A8, wherein the outer covering portion (32, 322) covers the covered object (10, 280) at an interval from the electrode side wall (21, 302, 305), and the organic insulating film (50, 340) covers a portion of the covered object (10, 280) that is exposed from between the electrode (20, 300, 301, 303) and the outer covering portion (32, 322). With this structure, influence of the stress of the electrode on the outer covering portion can be reduced. Also, the portion of the covered object that is exposed from between the electrode side wall and the outer covering portion can be protected by the organic insulating film.

[A10] The electronic component according to any one of A7 to A9, wherein the outer covering portion (32, 322) surrounds the electrode (20, 300, 301, 303) in plan view. With this structure, the electrode can be protected appropriately by the inorganic insulating film from a region outside the electrode.

[A11] An electronic component comprising: a covered object (10, 280); an electrode (20, 300, 301, 303) that covers the covered object (10, 280) and has an electrode side wall (21, 302, 305) on the covered object (10, 280); an inorganic insulating film (30, 320) that covers the covered object (10, 280) such as to expose the electrode side wall (21, 302, 305); and an organic insulating film (50, 340) that covers the inorganic insulating film (30, 320) and the electrode (20, 300, 301, 303) and covers the electrode side wall (21, 302, 305) between the inorganic insulating film (30, 320) and the electrode (20, 300, 301, 303).

With this structure, the inorganic insulating film that exposes the electrode side wall is formed. Peeling starting points of the inorganic insulating film due to the stress of the electrode can thereby be reduced. Consequently, peeling of the inorganic insulating film due to the stress of the electrode can be suppressed. The electrode can thus be protected appropriately by the inorganic insulating film from the region outside the electrode. On the other hand, the organic insulating film covers the electrode side wall. The organic insulating film has a low hardness in comparison to the inorganic insulating film. Therefore, even if a stress arises in the electrode, the stress can be absorbed elastically.

Peeling of the organic insulating film from the electrode side wall can thereby be suppressed. Also, since peeling of the inorganic insulating film from the covered object can be suppressed, peeling of the organic insulating film due to peeling of the inorganic insulating film can be suppressed. The electrode can thereby be protected by both the inorganic insulating film and the organic insulating film. The electronic component that can be improved in reliability can thus be provided. With this electronic component, reliability of the electrode and the periphery thereof is especially improved.

[A12] The electronic component according to A11, wherein the inorganic insulating film (30, 320) covers the covered object (10, 280) at an interval from the electrode side wall (21, 302, 305), and the organic insulating film (50, 340) covers the covered object (10, 280) between the electrode (20, 300, 301, 303) and the inorganic insulating film (30, 320). With this structure, influence of the stress of the electrode on the inorganic insulating film can be reduced. Also, the portion of the covered object that is exposed from between the electrode side wall and the outer covering portion can be protected appropriately by the organic insulating film.

[A13] The electronic component according to A11 or A12, wherein the inorganic insulating film (30, 320) surrounds the electrode (20, 300, 301, 303) in plan view. With this structure, the electrode can be protected appropriately by the inorganic insulating film from the region outside the electrode.

[A14] An electronic component comprising: an electrode (20, 300, 301, 303) that has an electrode side wall (21, 302, 305); an inorganic insulating film (30, 320) that covers the electrode (20, 300, 301, 303) such as to expose an inner portion of the electrode (20, 300, 301, 303) and the electrode side wall (21, 302, 305); an organic insulating film (50, 340) that covers the electrode side wall (21, 302, 305) and exposes the inner portion of the electrode (20, 300, 301, 303); and a pad electrode (60, 360, 361, 362) that is formed on the inner portion of the electrode (20, 300, 301, 303).

With this structure, the inorganic insulating film that exposes the electrode side wall is formed. Peeling starting points of the inorganic insulating film due to the stress of the electrode can thereby be reduced. Consequently, peeling of the inorganic insulating film due to the stress of the electrode can be suppressed. The electrode can thus be protected appropriately by the inorganic insulating film. On the other hand, the organic insulating film covers the electrode side wall. The organic insulating film has a low hardness in comparison to the inorganic insulating film. Therefore, even if a stress arises in the electrode, the stress can be absorbed elastically. Peeling of the organic insulating film from the electrode side wall can thereby be suppressed. Consequently, the electrode side wall can be protected by the organic insulating film. Also, with this structure, peeling of the pad electrode due to peeling of the inorganic insulating film and the organic insulating film can be suppressed. The electronic component that can be improved in reliability can thus be provided. With the electronic component, reliability of the electrode and the periphery thereof is especially improved.

[A15] The electronic component according to A14, wherein the pad electrode (60, 360, 361, 362) is in contact with the inorganic insulating film (30, 320). With this structure, peeling of the inorganic insulating film can be suppressed and therefore, the pad electrode that is in contact with the inorganic insulating film can be formed appropriately. A connection area of the pad electrode with respect to a base can thereby be increased and therefore, peeling of the pad electrode can be suppressed.

[A16] The electronic component according to A14 or A15, wherein the organic insulating film (50, 340) covers the inorganic insulating film (30, 320) such as to expose an edge portion (54, 343, 347) of the inorganic insulating film (30, 320) at the inner portion side of the electrode (20, 300, 301, 303), and the pad electrode (60, 360, 361, 362) covers the edge portion (54, 343, 347) of the inorganic insulating film (30, 320). With this structure, the connection area of the pad electrode with respect to the base can be increased appropriately and therefore, peeling of the pad electrode can be suppressed appropriately.

[A17] The electronic component according to any one of A14 to A16, wherein the organic insulating film (50, 340) covers the inorganic insulating film (30, 320), and the pad electrode (60, 360, 361, 362) is in contact with the organic insulating film (50, 340). With this structure, peeling of the inorganic insulating film from the electrode can be suppressed and therefore, peeling of the organic insulating film due to peeling of the inorganic insulating film can be suppressed. Therefore, by forming the organic insulating film that has an inner covering portion, the electrode and the pad electrode can be protected by both the inorganic insulating film and the organic insulating film.

[A18] The electronic component according to any one of A14 to A17, wherein the inorganic insulating film (30, 320) covers the electrode (20, 300, 301, 303) at an interval from the electrode side wall (21, 302, 305), and the organic insulating film (50, 340) covers the portion of the electrode (20, 300, 301, 303) that is exposed from between the electrode side wall (21, 302, 305) and the inorganic insulating film (30, 320). With this structure, influence of the stress of the electrode on an outer covering portion can be reduced. Also, the portion of the covered object that is exposed from between the electrode side wall and the outer covering portion can be protected by the organic insulating film.

[A19] The electronic component according to any one of A14 to A18, wherein the inorganic insulating film (30, 320) surrounds the inner portion of the electrode (20, 300, 301, 303) in plan view. With this structure, the electrode can be protected appropriately by the inorganic insulating film while securing a forming portion for the pad electrode.

[A20] The electronic component according to any one of A14 to A19, wherein the pad electrode (60, 360, 361, 362) includes an Ni plating film (61, 363, 373) that is in contact with the inorganic insulating film. The Ni plating film has satisfactory adhesion to the inorganic insulating film. Therefore, by forming the Ni plating film that is in contact with the inorganic insulating film, peeling of the pad electrode can be suppressed appropriately. Reliability can thus be improved.

[B1] An electronic component comprising: a first inorganic insulating film (280); an electrode (300, 301, 303) that covers the first inorganic insulating film (280) and has an electrode side wall (302, 305) on the first inorganic insulating film (280); a wiring electrode (306, 307, 310) that is led out as a line from the electrode (300, 301, 303) onto the first inorganic insulating film (280) and has a wiring side wall (309, 311) on the first inorganic insulating film (280); a second inorganic insulating film (320) that has an inner covering portion (324, 325) that covers the electrode (300, 301, 303) such as to expose the electrode side wall (302, 305) and the wiring side wall (309, 311); and an organic insulating film (340) that covers the electrode side wall (302, 305) and the wiring side wall (309, 311).

[B2] The electronic component according to B1, wherein the second inorganic insulating film (320) exposes an entire area of the wiring electrode (306, 307, 310), and the organic insulating film (340) covers the entire area of the wiring electrode (306, 307, 310).

[B3] The electronic component according to B1 or B2, wherein the organic insulating film (340) covers the inner covering portion (324, 325).

[B4] The electronic component according to any one of B1 to B3, wherein the inner covering portion (324, 325) exposes a peripheral edge portion of the electrode (300, 301, 303), and the organic insulating film (340) covers the peripheral edge portion of the electrode (300, 301, 303).

[B5] The electronic component according to any one of B1 to B4, wherein the inner covering portion (324, 325) exposes an inner portion of the electrode (300, 301, 303).

[B6] The electronic component according to B5, wherein the inner covering portion (324, 325) surrounds the inner portion of the electrode (300, 301, 303).

[B7] The electronic component according to B5 or B6, further comprising: a pad electrode (360, 361, 362) that is formed on the inner portion of the electrode (300, 301, 303).

[B8] The electronic component according to B7, wherein the pad electrode (360, 361, 362) is in contact with the inner covering portion (324, 325).

[B9] The electronic component according to B7 or B8, wherein the organic insulating film (340) covers the inner covering portion (324, 325) such as to expose an edge portion (343, 347) of the inner covering portion (324, 325) at the inner portion side of the electrode (300, 301, 303), and the pad electrode (360, 361, 362) covers the edge portion (343, 347) of the inner covering portion (324, 325).

[B10] The electronic component according to any one of B7 to B9, wherein the pad electrode (360, 361, 362) is in contact with the organic insulating film (340).

[B11] The electronic component according to any one of B7 to B10, wherein the pad electrode (360, 361, 362) includes an Ni plating film (363, 373) that is in contact with the inner covering portion (324, 325).

[B12] The electronic component according to any one of B1 to B11, wherein the second inorganic insulating film (320) has an outer covering portion (322) that covers the first inorganic insulating film (280) such as to expose the electrode side wall (302, 305) and the wiring side wall (309, 311).

[B13] The electronic component according to B12, wherein the organic insulating film (340) covers the outer covering portion (322).

[B14] The electronic component according to B12 or B13, wherein the outer covering portion (322) covers the first inorganic insulating film (280) at an interval from the electrode side wall (302, 305) and the wiring side wall (309, 311).

[B15] The electronic component according to any one of B12 to B14, wherein the outer covering portion (322) surrounds the electrode (300, 301, 303) and the wiring electrode (306, 307, 310) in plan view.

[C1] A semiconductor device comprising: a semiconductor chip (202) that has a main surface (203); a transistor of an insulated gate type that is formed in the main surface (203); a first inorganic insulating film (280) that covers the main surface (203) such as to expose a portion of the transistor; a gate main surface electrode (301) that covers the first inorganic insulating film (280) such as to be electrically connected to the transistor and has a first side wall (302) on the first inorganic insulating film (280); a source main surface electrode (303) that covers the first inorganic insulating film (280) at an interval from the gate main surface electrode (301) such as to be electrically connected to the transistor and has a second side wall (305) on the first inorganic insulating film (280); a second inorganic insulating film (320) that includes a first inner covering portion (324) covering the gate main surface electrode (301) such as to expose the first side wall (302) and a second inner covering portion (325) covering the source main surface electrode (303) such as to expose the second side wall (305); and an organic insulating film (340) that covers the first side wall (302) of the gate main surface electrode (301) and the second side wall (305) of the source main surface electrode (303).

[C2] The semiconductor device according to C1, wherein the organic insulating film (340) covers the first inner covering portion (324) and the second inner covering portion (325).

[C3] The semiconductor device according to C1 or C2, wherein the first inner covering portion (324) exposes a peripheral edge portion of the gate main surface electrode (301), the second inner covering portion (325) exposes a peripheral edge portion of the source main surface electrode (303), and the organic insulating film (340) covers the peripheral edge portion of the gate main surface electrode (301) and the peripheral edge portion of the source main surface electrode (303).

[C4] The semiconductor device according to any one of C1 to C3, wherein the first inner covering portion (324) exposes an inner portion of the gate main surface electrode (301), the second inner covering portion (325) exposes an inner portion of the source main surface electrode (303), and the organic insulating film (340) exposes the inner portion of the gate main surface electrode (301) and the inner portion of the source main surface electrode (303).

[C5] The semiconductor device according to C4, wherein the first inner covering portion (324) surrounds the inner portion of the gate main surface electrode (301), the second inner covering portion (325) surrounds the inner portion of the source main surface electrode (303), and the organic insulating film (340) surrounds the inner portion of the gate main surface electrode (301) and the inner portion of the source main surface electrode (303).

[C6] The semiconductor device according to C4 or C5, further comprising: a gate pad electrode (361) formed on the inner portion of the gate main surface electrode (301); and a source pad electrode (362) formed on the inner portion of the source main surface electrode (303).

[C7] The semiconductor device according to C6, wherein the gate pad electrode (361) is in contact with the first inner covering portion (324), and the source pad electrode (362) is in contact with the second inner covering portion (325).

[C8] The semiconductor device according to C6 or C7, wherein the organic insulating film (340) covers the first inner covering portion (324) such as to expose a first edge portion (341) of the first inner covering portion (324) at the inner portion side of the gate main surface electrode (301) and covers the second inner covering portion (325) such as to expose a second edge portion (342) of the second inner covering portion (325) at the inner portion side of the source main surface electrode (303), the gate pad electrode (361) covers the first edge portion (341) of the first inner covering portion (324), and the source pad electrode (362) covers the second edge portion (342) of the second inner covering portion (325).

[C9] The semiconductor device according to any one of C6 to C8, wherein the gate pad electrode (361) is in contact with the organic insulating film (340), and the source pad electrode (362) is in contact with the organic insulating film (340).

[C10] The semiconductor device according to any one of C6 to C9, wherein the gate pad electrode (361) includes a first Ni plating film (363) that is in contact with the first inner covering portion (324), and the source pad electrode (362) includes a second Ni plating film (373) that is in contact with the second inner covering portion (325).

[C11] The semiconductor device according to any one of C1 to C10, further comprising: a gate wiring electrode (307) that is led out as a line from the gate main surface electrode (301) onto the first inorganic insulating film (280) and has a gate wiring side wall (309) on the first inorganic insulating film (280); and wherein the second inorganic insulating film (320) exposes the gate wiring side wall (309), and the organic insulating film (340) covers the gate wiring side wall (309).

[C12] The semiconductor device according to C11, wherein the organic insulating film (340) covers an entire area of the gate wiring electrode (307).

[C13] The semiconductor device according to C11 or C12, wherein the gate wiring electrode (307) extends as a line such as to face the source main surface electrode (303) from a plurality of directions in plan view.

[C14] The semiconductor device according to any one of C1 to C13, further comprising: a source wiring electrode (310) that is led out as a line from the source main surface electrode (303) onto the first inorganic insulating film (280) and has a source wiring side wall (311) on the first inorganic insulating film (280); and wherein the second inorganic insulating film (320) exposes the source wiring side wall (311), and the organic insulating film (340) covers the source wiring side wall (311).

[C15] The semiconductor device according to C14, wherein the organic insulating film (340) covers an entire area of the source wiring electrode (310).

[C16] The semiconductor device according to C14 or C15, wherein the source wiring electrode (310) surrounds the gate main surface electrode (301) and the source main surface electrode (303) in plan view.

[C17] The semiconductor device according to any one of C1 to C16, wherein the second inorganic insulating film (320) has an outer covering portion (322) that covers the first inorganic insulating film (280) at an interval from the gate main surface electrode (301), and the source main surface electrode (303) such as to expose the first side wall (302) and the second side wall (305).

[C18] The semiconductor device according to C17, wherein the organic insulating film (340) covers the outer covering portion (322).

[C19] The semiconductor device according to C17 or C18, wherein the outer covering portion (322) surrounds the gate main surface electrode (301) and the source main surface electrode (303) in plan view.

[C20] The semiconductor device according to any one of C1 to C19 wherein the transistor is constituted of a trench insulated gate type.

[D1] A semiconductor device comprising: a semiconductor chip (202) having a main surface (203) that include an active surface (206), an outer surface (207) that is depressed in a thickness direction outside the active surface (206), and a boundary side-surface (208) that connects the active surface (206) and the outer surface (207) and in which a mesa (209) is demarcated by the active surface (206), the outer surface (207) and the boundary side-surface (208); a functional device that is formed in the active surface (206); a first inorganic insulating film (280) that covers the active surface (206) such as to expose a portion of the functional device; a main surface electrode (300, 301, 303) that covers the first inorganic insulating film (280) on the active surface (206) such as to be electrically connected to the functional device and has an electrode side wall (302, 305) on the first inorganic insulating film (280); a second inorganic insulating film (320) that has an inner covering portion (324, 325) covering the main surface electrode (300, 301, 303) such as to expose the electrode side wall (302, 305); and an organic insulating film (340) extends from above the active surface (206) onto the outer surface (207) across the boundary side-surface (208) and covers the electrode side wall (302, 305) on the active surface (206).

[D2] The semiconductor device according to D1, wherein the second inorganic insulating film (320) exposes the boundary side-surface (208).

[D3] The semiconductor device according to D1 or D2, wherein the first inorganic insulating film (280) is led out from above the active surface (206) onto the outer surface (207), and the second inorganic insulating film (320) has an outer covering portion (322) that covers the first inorganic insulating film (280) on the outer surface (207) at an interval from the boundary side-surface (208).

[D4] The semiconductor device according to D3, wherein the organic insulating film (340) covers the outer covering portion (322).

[D5] The semiconductor device according to D3 or D4, wherein the outer covering portion (322) surrounds the boundary side-surface (208) in plan view.

[D6] The semiconductor device according to any one of D3 to D5, further comprising: a side wall structure (272) that is formed on the outer surface (207) such as to cover the boundary side-surface (208) and moderates a level difference between the active surface (206) and the outer surface (207); and wherein the first inorganic insulating film (280) is led out from above the active surface (206) onto the outer surface (207) across the side wall structure (272), and the second inorganic insulating film (320) exposes a portion of the first inorganic insulating film (280) that covers the side wall structure (272).

[D7] The semiconductor device according to any one of D1 to D6, further comprising: a wiring electrode (306, 307, 310) that is led out as a line from the main surface electrode (300, 301, 303) onto the first inorganic insulating film (280) and has a wiring side wall (309, 311) on the first inorganic insulating film (280); and wherein the inner covering portion (324, 325) of the second inorganic insulating film (320) covers the main surface electrode (300, 301, 303) such as to expose the electrode side wall (302, 305) and the wiring side wall (309, 311), and the organic insulating film (340) covers the electrode side wall (302, 305) and the wiring side wall (309, 311).

[D8] The semiconductor device according to D7, wherein the second inorganic insulating film (320) exposes an entire area of the wiring electrode (306, 307, 310), and the organic insulating film (340) covers the entire area of the wiring electrode (306, 307, 310).

[D9] The semiconductor device according to D7 or D8, wherein the wiring electrode (306, 307) is routed around on the active surface (206).

[D10] The semiconductor device according to D7 or D8, wherein the wiring electrode (306, 310) is routed around on the outer surface (207) across the boundary side-surface (208).

[D11] The semiconductor device according to any one of D1 to D10, wherein the organic insulating film (340) covers the inner covering portion (324, 325).

[D12] The semiconductor device according to any one of D1 to D11, wherein the inner covering portion (324, 325) exposes a peripheral edge portion of the main surface electrode (300, 301, 303), and the organic insulating film (340) covers the peripheral edge portion of the main surface electrode (300, 301, 303).

[D13] The semiconductor device according to any one of D1 to D12, wherein the inner covering portion (324, 325) exposes an inner portion of the main surface electrode (300, 301, 303).

[D14] The semiconductor device according to D13, wherein the inner covering portion (324, 325) surrounds the inner portion of the main surface electrode (300, 301, 303).

[D15] The semiconductor device according to D13 or D14, further comprising: a pad electrode (360, 361, 362) that is formed on the inner portion of the main surface electrode (300, 301, 303).

[D16] The semiconductor device according to D15, wherein the pad electrode (360, 361, 362) is in contact with the inner covering portion (324, 325).

[D17] The semiconductor device according to D15 or D16, wherein the organic insulating film (340) covers the inner covering portion (324, 325) such as to expose an edge portion (343, 347) of the inner covering portion (324, 325) at the inner portion side of the main surface electrode (300, 301, 303), and the pad electrode (360, 361, 362) covers the edge portion (343, 347) of the inner covering portion (324, 325).

[D18] The semiconductor device according to any one of D15 to D17, wherein the pad electrode (360, 361, 362) is in contact with the organic insulating film (340).

[D19] The semiconductor device according to any one of D15 to D18, wherein the pad electrode (360, 361, 362) includes an Ni plating film (363, 373) that is in contact with the inner covering portion (324, 325).

[E1] An SiC semiconductor device comprising: an SiC chip (2, 202) that has a main surface (3, 203); a first inorganic insulating film (10, 280) that covers the main surface (3, 203); a main surface electrode (20, 300, 301, 303) that covers the first inorganic insulating film (10, 280) and has an electrode side wall (21, 302, 305) on the first inorganic insulating film (10, 280); a second inorganic insulating film (30, 320) that has an inner covering portion (31, 321, 324, 325) that covers the main surface electrode (20, 300, 301, 303) such as to expose the electrode side wall (21, 302, 305); and an organic insulating film (50, 340) that covers the electrode side wall (21, 302, 305).

[E2] The SiC semiconductor device according to E1, wherein the organic insulating film (50, 340) covers the inner covering portion (31, 321, 324, 325).

[E3] The SiC semiconductor device according to E1 or E2, wherein the inner covering portion (31, 321, 324, 325) exposes a peripheral edge portion of the main surface electrode (20, 300, 301, 303), and the organic insulating film (50, 340) covers the peripheral edge portion of the main surface electrode (20, 300, 301, 303).

[E4] The SiC semiconductor device according to any one of E1 to E3, wherein the inner covering portion (31, 321, 324, 325) exposes an inner portion of the main surface electrode (20, 300, 301, 303).

[E5] The SiC semiconductor device according to E4, wherein the inner covering portion (31, 321, 324, 325) surrounds the inner portion of the main surface electrode (20, 300, 301, 303).

[E6] The SiC semiconductor device according to any one of E1 to E5, wherein the organic insulating film (50, 340) covers the inner covering portion (31, 321, 324, 325) partially such as to expose a portion of the inner covering portion (31, 321, 324, 325).

[E7] The SiC semiconductor device according to any one of E1 to E6, wherein the organic insulating film (50, 340) exposes an edge portion (54, 343, 347) of the inner covering portion (31, 321, 324, 325) at the inner portion side of the main surface electrode (20, 300, 301, 303).

[E8] The SiC semiconductor device according to E7, further comprising: a pad electrode (360, 361, 362) that is formed on the main surface electrode (20, 300, 301, 303) such as to cover the edge portion (54, 343, 347) of the inner covering portion (31, 321, 324, 325).

[E9] The SiC semiconductor device according to any one of E1 to E8, wherein the second inorganic insulating film (30, 320) has an outer covering portion (32, 322) that is formed on the first inorganic insulating film (10, 280) such as to expose the electrode side wall (21, 302, 305).

[E10] The SiC semiconductor device according to E9, wherein the outer covering portion (32, 322) is formed on the first inorganic insulating film (10, 280) at an interval from the electrode side wall (21, 302, 305), and the organic insulating film (50, 340) covers a portion of the first inorganic insulating film (10, 280) that is exposed from between the main surface electrode (20, 300, 301, 303) and the outer covering portion (32, 322).

[E11] The SiC semiconductor device according to E9 or E10, wherein the organic insulating film (50, 340) covers the outer covering portion (32, 322).

[E12] The SiC semiconductor device according to E10 or E11, wherein the outer covering portion (32, 322) extends as a band along the electrode side wall (21, 302, 305).

[E13] The SiC semiconductor device according to any one of E9 to E12, wherein the outer covering portion (32, 322) surrounds the main surface electrode (20, 300, 301, 303) in plan view.

[E14] The SiC semiconductor device according to any one of E9 to E13, wherein the SiC chip (2, 202) has a side surface (5A to 5D, 205A to 205D), the first inorganic insulating film (10, 280) is formed at an interval inward from the side surface (5A to 5D, 205A to 205D) such as to expose a peripheral edge portion of the main surface (3, 203), and the outer covering portion (32, 322) covers the peripheral edge portion of the main surface (3, 203) that is exposed from the first inorganic insulating film (10, 280).

[E15] The SiC semiconductor device according to any one of E1 to E14, wherein the second inorganic insulating film (30, 320) is constituted of an insulator differing from the first inorganic insulating film (10, 280).

[E16] The SiC semiconductor device according to E15, wherein the first inorganic insulating film (10, 280) includes a silicon oxide and the second inorganic insulating film (30, 320) includes a silicon nitride.

[E17] The SiC semiconductor device according to any one of E1 to E16, further comprising: a functional device that is formed in the SiC chip (2, 202); and one or a plurality of the main surface electrodes (20, 300, 301, 303) that are electrically connected to the functional device.

[E18] The SiC semiconductor device according to E17, wherein the functional device includes a Schottky barrier diode and the main surface electrode (20) includes a Schottky main surface electrode (20) that covers the first inorganic insulating film (10) and has the electrode side wall (21) on the first inorganic insulating film (10).

[E19] The SiC semiconductor device according to E18, wherein the functional device includes a transistor of an insulated gate type, a plurality of the main surface electrodes (300, 301, 303) include a gate main surface electrode (301) that covers the first inorganic insulating film (280) and has a first electrode side wall (302) on the first inorganic insulating film (280) and a source main surface electrode (303) that covers the first inorganic insulating film (280) at an interval from the gate main surface electrode (301) and has a second electrode side wall (309) on the first inorganic insulating film (280), and the inner covering portion (321, 324, 325) of the second inorganic insulating film (30, 320) includes at least one among a first inner covering portion (324) that covers the gate main surface electrode (301) such as to expose the first electrode side wall (302) and a second inner covering portion (325) that covers the source main surface electrode (303) such as to expose the second electrode side wall (305).

[F1] An SiC semiconductor device comprising: an SiC chip (2, 202); a first inorganic insulating film (10, 280) formed on the SiC chip (2, 202); an electrode (20, 300, 301, 303) that covers the first inorganic insulating film (10, 280) and has an electrode side wall (21, 302, 305) on the first inorganic insulating film (10, 280); a second inorganic insulating film (30, 320) that covers the electrode (20, 300, 301, 303) and the first inorganic insulating film (10, 280) and has a first opening (36, 328, 331) exposing an inner portion of the electrode (20, 300, 301, 303) and a removed portion (33, 323) exposing the electrode side wall (21, 302, 305); an organic insulating film (50, 340) that covers the electrode side wall (21, 302, 305) at the removed portion (33, 323) of the second inorganic insulating film (30, 320) and has a second opening (54, 342, 346) exposing the inner portion of the electrode (20, 300, 301, 303); and a pad electrode (60, 360, 361, 362) that covers the inner portion of the electrode (20, 300, 301, 303).

[F2] The SiC semiconductor device according to F1, wherein the second opening (54, 342, 346) is formed in a region of the second inorganic insulating film (30, 320) between the first opening (36, 328, 331) and the removed portion (33, 323).

[F3] The SiC semiconductor device according to F1 or F2, wherein the pad electrode (60, 360, 361, 362) is in contact with the second inorganic insulating film (30, 320).

[F4] The SiC semiconductor device according to any one of F1 to F3, wherein the second opening (54, 342, 346) is formed in the second inorganic insulating film (30, 320) at an interval from the first opening (36, 328, 331) such as to expose an edge portion (54, 343, 347) of the second inorganic insulating film (30, 320), and the pad electrode (60, 360, 361, 362) covers the edge portion (54, 343, 347) of the second inorganic insulating film (30, 320).

[F5] The SiC semiconductor device according to any one of F1 to F4, wherein the pad electrode (60, 360, 361, 362) is in contact with the organic insulating film (50, 340) inside the second opening (54, 342, 346).

[F6] The SiC semiconductor device according to any one of F1 to F4, wherein the pad electrode (60, 360, 361, 362) exposes the second inorganic insulating film (30, 320) inside the second opening (54, 342, 346).

[F7] The SiC semiconductor device according to any one of F1 to F6, wherein the pad electrode (60, 360, 361, 362) includes an Ni plating film (61, 361, 371).

[F8] The SiC semiconductor device according to F7, wherein the pad electrode (60, 360, 361, 362) includes an outer plating film (63, 363, 373) that covers an outer surface of the Ni plating film (61, 361, 371) and is constituted of a metal differing from the Ni plating film (61, 361, 371).

[F9] The SiC semiconductor device according to any one of F1 to F8, wherein the electrode (20, 300, 301, 303) includes at least one among a pure A1 film, an AlSi alloy film, an AlCu alloy film and an AlSiCu alloy film.

[F10] The SiC semiconductor device according to any one F1 to F9, wherein the second inorganic insulating film (30, 320) has an electrode covering portion (31, 321, 324, 325) that covers the electrode (20, 300, 301, 303) such as to demarcate the first opening (36, 328, 331), an insulation covering portion (32, 322) that covers the first inorganic insulating film (10, 280) in a region outside the electrode (20, 300, 301, 303), and the removed portion (33, 323) that exposes the electrode side wall (21, 302, 305) from between the electrode covering portion (31, 321, 324, 325) and the insulation covering portion (32, 322), and the organic insulating film (50, 340) covers the electrode covering portion (31, 321, 324, 325) and the insulation covering portion (32, 322) and covers the electrode side wall (21, 302, 305) in the removed portion (33, 323) between the electrode covering portion (31, 321, 324, 325) and the insulation covering portion (32, 322).

[F11] The SiC semiconductor device according to F10, wherein the electrode covering portion (31, 321, 324, 325) covers the electrode (20, 300, 301, 303) such as to surround the inner portion of the electrode (20, 300, 301, 303) at an interval from the electrode side wall (21, 302, 305).

[F12] The SiC semiconductor device according to F10 or F11, wherein the insulation covering portion (32, 322) covers the first inorganic insulating film (10, 280) such as to surround the electrode (20, 300, 301, 303) at an interval from the electrode side wall (21, 302, 305).

[F13] The SiC semiconductor device according to any one of F10 to F12, wherein the removed portion (33, 323) exposes the electrode side wall (21, 302, 305) over entire periphery.

[F14] The SiC semiconductor device according to any one of F10 to F13, wherein the first inorganic insulating film (10, 280) is formed at an interval inward from an end portion of the SiC chip (2, 202) such as to expose a peripheral edge portion of the SiC chip (2, 202), and the insulation covering portion (32, 322) covers the peripheral edge portion of the SiC chip (2, 202) that is exposed from the first inorganic insulating film (10, 280).

[F15] The SiC semiconductor device according to any one of F1 to F14, wherein the second inorganic insulating film (30, 320) is constituted of an insulator differing from the first inorganic insulating film (10, 280).

[F16] The SiC semiconductor device according to F15, wherein the first inorganic insulating film (10, 280) includes a silicon oxide, and the second inorganic insulating film (30, 320) includes a silicon nitride.

[F17] The SiC semiconductor device according to any one of F1 to F16, further comprising: a functional device that is formed in the SiC chip (2, 202); and wherein the electrode (20, 300, 301, 303) is electrically connected to the functional device.

[F18] The SiC semiconductor device according to F17, wherein the functional device includes a Schottky barrier diode, and the electrode (20) includes a Schottky electrode (20).

[F19] The SiC semiconductor device according to F17, wherein the functional device includes a transistor of an insulated gate type, and the electrode (20) includes a gate electrode (300, 301) of the transistor.

[F20] The SiC semiconductor device according to F17, wherein the functional device includes a transistor of an insulated gate type, and the electrode (20) includes a source electrode (300, 303) of the transistor.

While preferred embodiments of the present invention have been described in detail, these are merely specific examples used to clarify the technical contents of the present invention and the present invention should not be interpreted as being limited to these specific examples and the scope of the present invention is to be limited by the appended claims.

### REFERENCE SIGNS LIST

1 SiC semiconductor device (electronic component)
10 first inorganic insulating film (covered object)
20 first main surface electrode (electrode)
21 electrode side wall
30 second inorganic insulating film
31 inner covering portion
32 outer covering portion
50 organic insulating film
51 edge portion of inner covering portion
60 pad electrode
61 Ni plating film
101 SiC semiconductor device (electronic component)
111 SiC semiconductor device (electronic component)
121 SiC semiconductor device (electronic component)
131 SiC semiconductor device (electronic component)
141 SiC semiconductor device (electronic component)
201 SiC semiconductor device (electronic component)
280 first inorganic insulating film (covered object)
300 first main surface electrode (electrode)
301 gate main surface electrode (electrode)
302 gate electrode side wall (electrode side wall)
303 source main surface electrode (electrode)
305 source electrode side wall (electrode side wall)
320 second inorganic insulating film
321 inner covering portion
322 outer covering portion
324 first inner covering portion
325 second inner covering portion
340 organic insulating film
341 first edge portion of first inner covering portion
342 second edge portion of second inner covering portion
360 pad electrode
361 gate pad electrode
362 source pad electrode
363 first Ni plating film
373 second Ni plating film
401 SiC semiconductor device (electronic component)
411 SiC semiconductor device (electronic component)
421 SiC semiconductor device (electronic component)
431 SiC semiconductor device (electronic component)
441 SiC semiconductor device (electronic component)

1. An electronic component comprising:
a covered object;
an electrode that covers the covered object and has an electrode side wall on the covered object;
an inorganic insulating film that has an inner covering portion covering the electrode such as to expose the electrode side wall; and
an organic insulating film that covers the electrode side wall.

2. The electronic component according to claim 1, wherein the organic insulating film covers the inner covering portion.

3. The electronic component according to claim 1, wherein the inner covering portion exposes a peripheral edge portion of the electrode and
the organic insulating film covers the peripheral edge portion of the electrode.

4. The electronic component according to claim 1, wherein the inner covering portion exposes an inner portion of the electrode.

5. The electronic component according to claim 4, wherein the inner covering portion surrounds the inner portion of the electrode.

6. The electronic component according to claim 4, wherein the organic insulating film exposes an edge portion of the inner covering portion at the inner portion side of the electrode.

7. The electronic component according to claim 1, wherein the inorganic insulating film has an outer covering portion that covers the covered object such as to expose the electrode side wall.

8. The electronic component according to claim 7, wherein the organic insulating film covers the outer covering portion.

9. The electronic component according to claim 7, wherein the outer covering portion covers the covered object at an interval from the electrode side wall, and
the organic insulating film covers a portion of the covered object that is exposed from between the electrode and the outer covering portion.

10. The electronic component according to claim 7, wherein the outer covering portion surrounds the electrode in plan view.

11. An electronic component comprising:
a covered object;
an electrode that covers the covered object and has an electrode side wall on the covered object;
an inorganic insulating film that covers the covered object such as to expose the electrode side wall; and
an organic insulating film that covers the inorganic insulating film and the electrode and covers the electrode side wall between the inorganic insulating film and the electrode.

12. The electronic component according to claim 11, wherein the inorganic insulating film covers the covered object at an interval from the electrode side wall, and
the organic insulating film covers the covered object between the electrode and the inorganic insulating film.

13. The electronic component according to claim 11, wherein the inorganic insulating film surrounds the electrode in plan view.

14. An electronic component comprising:
an electrode that has an electrode side wall;
an inorganic insulating film that covers the electrode such as to expose an inner portion of the electrode and the electrode side wall of the electrode;
an organic insulating film that exposes the inner portion of the electrode and covers the electrode side wall; and
a pad electrode that is formed on the inner portion of the electrode.

15. The electronic component according to claim 14, wherein the pad electrode is in contact with the inorganic insulating film.

16. The electronic component according to claim 14, wherein the organic insulating film covers the inorganic insulating film such as to expose an edge portion of the inorganic insulating film at the inner portion side of the electrode and the pad electrode covers the edge portion of the inorganic insulating film.

17. The electronic component according to claim 14, wherein the pad electrode is in contact with the organic insulating film.

18. The electronic component according to claim 14, wherein the inorganic insulating film covers the electrode at an interval from the electrode side wall, and
the organic insulating film covers the portion of the electrode that is exposed from between the electrode side wall and the inorganic insulating film.

19. The electronic component according to claim 14, wherein the inorganic insulating film surrounds the inner portion of the electrode in plan view.

20. The electronic component according to claim 14, wherein the pad electrode includes an Ni plating film that is in contact with the inorganic insulating film.
